(19) United States
(12) Patent Application Publication
(10) Pub. No.: US 2026/0086457 A1
(43) Pub. Date: Mar. 26, 2026

(54) RESIST COMPOSITION AND RESIST PATTERN FORMATION METHOD

(71) Applicant: TOKYO OHKA KOGYO CO., LTD., Kawasaki-shi (JP)

(72) Inventors: Kumi NAKAMURA, Kawasaki-shi (JP); Daichi TAKAKI, Kawasaki-shi (JP); Tsuyoshi NAKAMURA, Kawasaki-shi (JP)

(21) Appl. No.: 19/108,564

(22) PCT Filed: Sep. 6, 2023
(86) PCT No.: PCT/JP2023/032586

§ 371 Date: Mar. 4, 2025

(30) Foreign Application Priority Data
Sep. 9, 2022 (JP) 2022-144181

(51) Int. Cl. G03F 7/004; G03F 7/038; G03F 7/039

(52) U.S. Cl. CPC G03F 7/0045; G03F 7/0382; G03F 7/0397; H10P 76/20

(57) ABSTRACT

A resist composition which generates an acid upon exposure and whose solubility with respect to a liquid developer changes by an action of the acid, the resist composition including a base material component whose solubility with respect to a liquid developer changes by an action of the acid, an acid generating agent component which generates an acid upon exposure, a first acid diffusion control component; and a second acid diffusion control component, in which the first acid diffusion control component (D1) includes a compound (d1-1), and the second acid diffusion control component (D2) includes a compound (d2-1).

### TECHNICAL FIELD

The present invention relates to a resist composition and a method for forming a resist pattern.

### BACKGROUND ART

In recent years, in the manufacture of semiconductor elements and liquid crystal display elements, miniaturization of patterns has been more rapidly advanced with the progress of the lithography technique. A common miniaturization technique is wavelength shortening (energy increase) of a light source for exposure.

The resist material is required to have lithography properties such as a sensitivity to a light source for exposure and resolution capable of reproducing a pattern with a fine dimension.

As a resist material satisfying such requirements, in the related art, a chemically amplified resist composition containing a base material component whose solubility with respect to a liquid developer changes by an action of an acid and an acid generating agent component that generates an acid upon exposure has been used.

In forming a resist pattern, the behavior of an acid generated from an acid generating agent component upon exposure is considered to be one factor that greatly influences the lithography properties.

In contrast, a chemically amplified resist composition has been proposed which contains an acid generating agent component and an acid diffusion control agent that controls diffusion of an acid generated from the acid generating agent component upon exposure.

For example, Patent Literature 1 discloses a resist composition containing a resin component whose solubility with respect to a liquid developer changes by an action of an acid, an acid generating agent component, and a photoreactive quencher having an anion moiety with a specific structure as an acid diffusion control agent.

The photoreactive quencher is a component that undergoes an ion exchange reaction with the acid generated from the acid generating agent component to exhibit a quenching effect. By mixing such a photoreactive quencher, diffusion of the acid generated from the acid generating agent component from an exposed portion to an unexposed portion of a resist film can be controlled, and lithography properties can be improved.

### CITATION LIST

### Patent Literature

Patent Literature 1: JP2021-81702A

### SUMMARY OF INVENTION

### Technical Problem

Recently, with further progress in lithography technique and an expansion of application fields, pattern miniaturization is progressing rapidly. Accordingly, when manufacturing semiconductor elements and the like, there is an increasing demand for a higher sensitivity to a light source for exposure as compared with the related art in forming a resist pattern, and lithography properties capable of forming a minute pattern having a pattern width of less than several tens of nm in a good shape.

However, in the related-art resist composition as described in Patent Literature 1, there is still room for improvement in terms of achieving both high sensitivity and lithography properties with a required level.

The present invention has been made in view of the above circumstances, and an object of the present invention is to provide a resist composition capable of forming a resist pattern that achieves both high sensitivity and lithography properties, and a method for forming a resist pattern.

### Solution to Problem

As a result of intensive studies to solve the problems, the present inventors have found a resist composition capable of forming a resist pattern that achieves both high sensitivity and lithography properties by the following constitution, and a method for forming a resist pattern using the resist composition, and has completed the present invention.

That is, the present invention is as follows.

A resist composition according to an embodiment of the present invention is a resist composition that generates an acid upon exposure and whose solubility with respect to a liquid developer changes by an action of the acid, the resist composition including:
a base material component (A) whose solubility with respect to a liquid developer changes by an action of an acid;
an acid generating agent component (B) that generates an acid upon exposure;
a first acid diffusion control component (D1); and
a second acid diffusion control component (D2), in which
the first acid diffusion control component (D1) contains a compound (d1-1) represented by the following general formula (d1-1), and
the second acid diffusion control component (D2) contains a compound (d2-1) represented by the following general formula (d2-1).

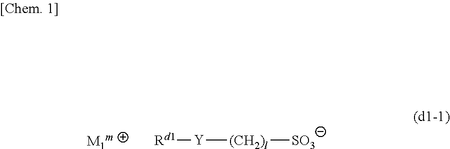

In the general formula (d1-1), R^{d1} represents a cyclic group that may include a substituent or a chain alkyl group that may include a substituent, Y represents a single bond or a divalent linking group containing a heteroatom, 1 represents an integer of 1 or more, m represents an integer of 1 or more, and M₁^{m+} represents an m-valent organic cation.]

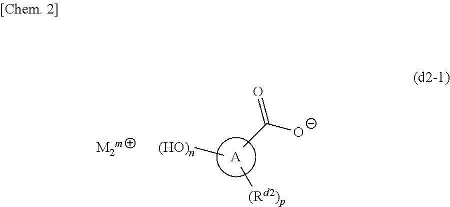

In the general formula (d2-1), ring A represents a monocyclic aromatic hydrocarbon group or a polycyclic aromatic hydrocarbon group, R^{d2} represents a substituent other than a hydroxy group, p represents an integer of 0 to 3, a plurality of R^{d2}'s may be the same as or different from each other when p represents 2 or 3, n represents an integer of 2 or more, m represents an integer of 1 or more, and M₂^{m+} represents an m-valent organic cation.]

A method for forming a resist pattern according to another embodiment of the present invention is a method for forming a resist pattern including: a step of forming a resist film on a support using the resist composition according to the embodiment of the present invention; a step of exposing the resist film; and a step of developing the resist film to form a resist pattern.

### Advantageous Effects of Invention

According to the present invention, a resist composition capable of forming a resist pattern that achieves both high sensitivity and lithography properties and a method for forming a resist pattern can be provided.

### DESCRIPTION OF EMBODIMENTS

Hereinafter, embodiments of the present invention will be described in detail. The present invention is not limited to the embodiment(s) described below.

In the present description and claims, the term “aliphatic” is defined as a relative concept to “aromatic” and means a group, a compound, or the like having no aromaticity.

Unless otherwise specified, the term “alkyl group” includes a linear monovalent saturated hydrocarbon group, a branched monovalent saturated hydrocarbon group, and a cyclic monovalent saturated hydrocarbon group. The same applies to an alkyl group in an alkoxy group.

Unless otherwise specified, the term “alkylene group” includes a linear divalent saturated hydrocarbon group, a branched divalent saturated hydrocarbon group, and a cyclic divalent saturated hydrocarbon group.

Examples of the “halogen atom” include a fluorine atom, a chlorine atom, a bromine atom, and an iodine atom.

The term “structural unit” refers to a monomer unit that constitutes a high molecular weight compound (a resin, a polymer, or a copolymer).

The term “halogenated alkyl group” is a group in which a part or all of hydrogen atoms in an alkyl group are replaced by halogen atoms, and examples of the halogen atom include a fluorine atom, a chlorine atom, a bromine atom, and an iodine atom.

The term “fluorinated alkyl group” or “fluorinated alkylene group” refers to a group in which a part or all of hydrogen atoms in an alkyl group or alkylene group are replaced by fluorine atoms.

The term “structural unit” refers to a monomer unit that constitutes a high molecular weight compound (a resin, a polymer, or a copolymer).

The expression “may include a substituent” includes both a case where a hydrogen atom (—H) is replaced by a monovalent group and a case where a methylene group (—CH₂—) is replaced by a divalent group.

The term “exposure” is intended to include a general concept of irradiation with radiation rays.

The “acid-decomposable group” is a group having an acid-decomposable property in which at least a part of bonds in the structure of the acid-decomposable group can be cleaved by the action of the acid.

Examples of the acid-decomposable group whose polarity increases by the action of the acid include a group that is decomposed by the action of the acid to generate a polar group.

Examples of the polar group include a carboxy group, a hydroxy group, an amino group, and a sulfo group (—SO₃H).

Specific examples of the acid-decomposable group include a group in which the polar group is protected with an acid-dissociable group (for example, a group in which a hydrogen atom of an OH-containing polar group is protected with an acid-dissociable group).

The term “acid-dissociable group” refers to both (i) a group having an acid dissociable property in which a bond between the acid-dissociable group and an atom adjacent to the acid-dissociable group can be cleaved by an action of an acid, and (ii) a group in which a bond between the acid-dissociable group and an atom adjacent to the acid-dissociable group can be cleaved by further causing a decarboxylation reaction after a part of bonds is cleaved by the action of the acid.

The acid-dissociable group constituting the acid-decomposable group needs to be a group having a polarity lower than that of a polar group generated by dissociation of the acid-dissociable group. Accordingly, when the acid-dissociable group is dissociated by the action of the acid, a polar group having a polarity higher than that of the acid-dissociable group is generated, thereby increasing the polarity. As a result, the polarity of an entire component (A1) to be described later increases. When the polarity increases, the solubility with respect to the liquid developer relatively changes, the solubility increases when the liquid developer is an alkaline liquid developer, and the solubility decreases when the liquid developer is an organic liquid developer.

The “base material component” is an organic compound having film formability. The organic compound to be used as the base material component is broadly divided into a non-polymer and a polymer. As the non-polymer, one having a molecular weight of 500 or more and less than 4000 is generally used. Hereinafter, the term “low molecular weight compound” refers to a non-polymer having a molecular weight of 500 or more and less than 4000. As the polymer, one having a molecular weight of 1000 or more is generally used. Hereinafter, the terms “resin”, “high molecular weight compound” and “polymer” refer to a polymer having a molecular weight of 1000 or more. As the molecular weight of the polymer, a mass average molecular weight in terms of polystyrene determined by gel permeation chromatography (GPC) is used.

The term “derived structural unit” refers to a structural unit formed by cleavage of a multiple bond between carbon atoms, for example, ethylenic double bonds.

In the “acrylic ester”, a hydrogen atom bonded to a carbon atom at the α-position may be replaced by a substituent. The substituent (R^{αx}) for replacing the hydrogen atom bonded to the carbon atom at the α-position is an atom or group other than a hydrogen atom. The acrylic ester also includes an itaconic acid diester in which the substituent (R^{αx}) is replaced by a substituent containing an ester bond, and an α-hydroxy acrylic ester in which the substituent (R^{αx}) is replaced by a hydroxyalkyl group or a group modified with a hydroxy group thereof. Unless otherwise specified, the carbon atom at the α-position of the acrylic ester refers to a carbon atom to which a carbonyl group of acrylic acid is bonded.

Hereinafter, an acrylic ester in which the hydrogen atom bonded to the carbon atom at the α-position is replaced by a substituent may be referred to as an α-replaced acrylic ester.

The term “derivative” is a concept including those in which a hydrogen atom of a target compound at the α-position is replaced by another substituent such as an alkyl group or a halogenated alkyl group, and a derivative thereof. Examples of the derivative include those in which a hydrogen atom of a hydroxy group of a target compound in which a hydrogen atom at the α-position may be replaced by a substituent is replaced by an organic group; and those in which a substituent other than a hydroxy group is bonded to a target compound in which a hydrogen atom at the α-position may be replaced by a substituent. Unless otherwise specified, the α-position refers to a first carbon atom adjacent to a functional group.

Examples of the substituent for replacing a hydrogen atom of hydroxystyrene at the α-position include those same as R^{αx}.

In the present description and claims, an asymmetric carbon may exist and hence enantiomers or diastereomers may exist depending on a structure of a chemical formula. In that case, one chemical formula represents all the isomers. The isomers may be used alone or as a mixture.

A chemical structural formula in the present disclosure may be described as a simplified structural formula in which hydrogen atoms are omitted.

In the present disclosure, a numerical range indicated using the symbol “-” or word “to” means a range that includes numerical values written before and after the symbol “-” or word “to” as the lower limit value and the upper limit value, respectively.

Further, in the present disclosure, when a plurality of substances corresponding to each component are present in a composition, an amount of each component in the composition means a total amount of a plurality of corresponding substances present in the composition, unless otherwise specified.

In the present disclosure, “mass %” and “weight %” have the same meaning, and “parts by mass” and “parts by weight” have the same meaning.

### [Resist Composition]

A resist composition according to an embodiment of the present invention is a resist composition that generates an acid upon exposure and whose solubility with respect to a liquid developer changes by an action of the acid, the resist composition including:
a base material component (A) whose solubility with respect to a liquid developer changes by an action of an acid (hereinafter, also referred to as “component (A)”);
an acid generating agent component (B) that generates an acid upon exposure (hereinafter, also referred to as “component (B)”);
a first acid diffusion control component (D1) (hereinafter, also referred to as “component (D1)”); and
a second acid diffusion control component (D2) (hereinafter, also referred to as “component (D2)”), in which
the first acid diffusion control component (D1) contains a compound (d1-1) represented by the following general formula (d1-1), and
the second acid diffusion control component (D2) contains a compound (d2-1) represented by the following general formula (d2-1).

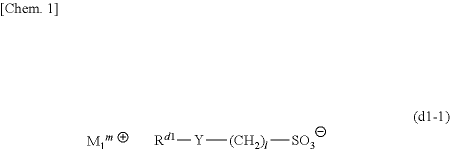

[In the general formula (d1-1), R^{d1} represents a cyclic group that may include a substituent or a chain alkyl group that may include a substituent, Y represents a single bond or a divalent linking group containing a heteroatom, 1 represents an integer of 1 or more, m represents an integer of 1 or more, and M₁^{m+} represents an m-valent organic cation.]

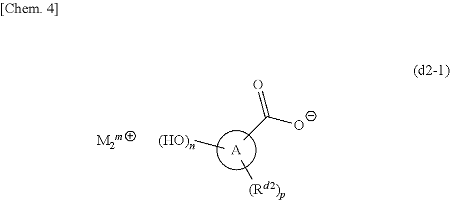

[In the general formula (d2-1), ring A represents a monocyclic aromatic hydrocarbon group or a polycyclic aromatic hydrocarbon group, R^{d2} represents a substituent other than a hydroxy group, p represents an integer of 0 to 3, a plurality of R^{d2}'s may be the same as or different from each other when p represents 2 or 3, n represents an integer of 2 or more, m represents an integer of 1 or more, and M₂^{m+} represents an m-valent organic cation.]

When a resist film is formed using the resist composition of the present embodiment and the resist film is selectively exposed, an acid is generated from the component (B) in an exposed portion of the resist film, and a solubility of the component (A) with respect to a liquid developer changes by an action of the acid, whereas the solubility of the component (A) with respect to the liquid developer does not change in an unexposed portion of the resist film, resulting in a difference in solubility with respect to the liquid developer between the exposed portion and the unexposed portion. Therefore, when the resist film is developed, the exposed portion of the resist film is dissolved and removed to form a positive resist pattern in the case where the resist composition is a positive resist composition, and the unexposed portion of the resist film is dissolved and removed to form a negative resist pattern in the case where the resist composition is a negative resist composition.

In the present description, a resist composition that forms a positive resist pattern by dissolving and removing an exposed portion of a resist film is referred to as a positive resist composition, and a resist composition that forms a negative resist pattern by dissolving and removing an unexposed portion of a resist film is referred to as a negative resist composition.

The resist composition according to the embodiment of the present invention may be a positive resist composition or a negative resist composition.

In addition, the resist composition according to the embodiment of the present invention may be for an alkaline developing process in which an alkaline liquid developer is used in a developing treatment at the time of resist pattern formation, or may be for a solvent developing process in which a liquid developer (an organic liquid developer) containing an organic solvent is used in the developing treatment.

### <Component (A)>

In the resist composition of the present embodiment, the component (A) preferably contains a resin component (A1) whose solubility with respect to a liquid developer changes by an action of an acid (hereinafter, also referred to as “component (A1)”). By using the component (A1), a polarity of the base material component changes before and after the exposure, so that a good development contrast can be obtained not only in the alkaline developing process but also in the solvent developing process.

As the component (A), at least the component (A1) is used, and other high molecular weight compounds and/or low molecular weight compounds may be used in combination with the component (A1).

When the alkaline developing process is applied, the base material component containing the component (A1) is poorly soluble with respect to the alkaline liquid developer before exposure, and for example, when an acid is generated from the component (B) upon exposure, the polarity thereof increases by the action of the acid, thereby increasing the solubility with respect to the alkaline liquid developer. Therefore, in forming a resist pattern, when a resist film obtained by coating a support with the resist composition is selectively exposed, an exposed portion of the resist film changes from poorly soluble to soluble with respect to the alkaline liquid developer, whereas an unexposed portion of the resist film remains poorly soluble with respect to alkaline and does not change. Therefore, a positive resist pattern can be formed by alkaline development.

On the other hand, when the solvent developing process is applied, the base material component containing the component (A1) has a high solubility with respect to the organic liquid developer before exposure, and for example, when an acid is generated from the component (B) upon exposure, the polarity thereof increases by the action of the acid, and the solubility with respect to the organic liquid developer decreases. Therefore, in forming a resist pattern, when a resist film obtained by coating a support with the resist composition is selectively exposed, an exposed portion of the resist film changes from soluble to poorly soluble with respect to the organic liquid developer, whereas an unexposed portion of the resist film remains soluble and does not change. Therefore, by developing with the organic liquid developer, a contrast can be created between the exposed portion and the unexposed portion, and a negative resist pattern can be formed.

In the resist composition of the present embodiment, the component (A) may be used alone or in combination of two or more kinds thereof.

### Regarding Component (A1)

The component (A1) is a resin component whose solubility with respect to a liquid developer changes by an action of an acid.

The component (A1) preferably contains a structural unit (a1) containing an acid-decomposable group whose polarity increases by an action of an acid.

The component (A1) may contain other structural units, in addition to the structural unit (a1), as necessary.

<<Structural Unit (a1)>>

The structural unit (a1) is a structural unit containing an acid-decomposable group whose polarity increases by the action of the acid.

Examples of the acid-dissociable group include those proposed as acid-dissociable groups of base resins for chemically amplified resist compositions in the related art.

Specific examples of those proposed as acid-dissociable groups of base resins for chemically amplified resist compositions include an “acetal acid-dissociable group”, a “tertiary alkyl ester acid-dissociable group” and a “tertiary alkyloxycarbonyl acid-dissociable group”, which are explained below.

### Acetal Acid-Dissociable Group:

Among the polar groups, examples of the acid-dissociable group that protects a carboxy group or a hydroxy group include an acid-dissociable group represented by the following general formula (a1-r-1)(hereinafter, may be referred to as an “acetal acid-dissociable group”).

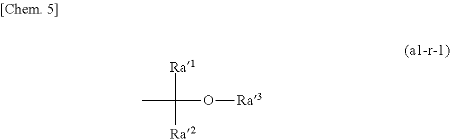

[In the formula, Ra′¹ and Ra′² are a hydrogen atom or an alkyl group. Ra′³ is a hydrocarbon group, and Ra′³ may be bonded to either Ra′¹ or Ra′² to form a ring.]

In the formula (a1-r-1), it is preferable that at least one of Ra′¹ and Ra′² is a hydrogen atom, and it is more preferable that both are a hydrogen atom.

When Ra′¹ or Ra′² is an alkyl group, the alkyl group is preferably an alkyl group having 1 to 5 carbon atoms. Specifically, preferred examples thereof include a linear or branched alkyl group. More specific examples thereof include a methyl group, an ethyl group, a propyl group, an isopropyl group, an n-butyl group, an isobutyl group, a tert-butyl group, a pentyl group, an isopentyl group, and a neopentyl group. A methyl group or an ethyl group is more preferred, and a methyl group is particularly preferred.

In the formula (a1-r-1), examples of the hydrocarbon group for Ra′³ include a linear or branched alkyl group, or a cyclic hydrocarbon group.

The linear alkyl group preferably has 1 to 5 carbon atoms, more preferably has 1 to 4 carbon atoms, and still more preferably has 1 or 2 carbon atoms. Specific examples thereof include a methyl group, an ethyl group, an n-propyl group, an n-butyl group, and an n-pentyl group. Among them, a methyl group, an ethyl group, or an n-butyl group is preferred, and a methyl group or an ethyl group is more preferred.

The branched alkyl group preferably has 3 to 10 carbon atoms, and more preferably has 3 to 5 carbon atoms. Specific examples thereof include an isopropyl group, an isobutyl group, a tert-butyl group, an isopentyl group, a neopentyl group, a 1,1-diethylpropyl group, and a 2,2-dimethylbutyl group. An isopropyl group is preferred.

When Ra′³ is a cyclic hydrocarbon group, the hydrocarbon group may be an aliphatic hydrocarbon group or an aromatic hydrocarbon group, and may be a polycyclic group or a monocyclic group.

The aliphatic hydrocarbon group which is a monocyclic group is preferably a group in which one hydrogen atom is removed from a monocycloalkane. The monocycloalkane preferably has 3 to 6 carbon atoms, and specific examples thereof include cyclopentane and cyclohexane.

The aliphatic hydrocarbon group which is a polycyclic group is preferably a group in which one hydrogen atom is removed from a polycycloalkane. The polycycloalkane is preferably a group having 7 to 12 carbon atoms, and specific examples thereof include adamantane, norborane, isobornane, tricyclodecane, and tetracyclododecane.

When the cyclic hydrocarbon group for Ra′³ is an aromatic hydrocarbon group, the aromatic hydrocarbon group is a hydrocarbon group having at least one aromatic ring.

The aromatic ring is not particularly limited as long as it is of a cyclic conjugated system having 4n+2 π electrons, and may be monocyclic or polycyclic. The number of carbon atoms of the aromatic ring is preferably 5 to 30, more preferably 5 to 20, still more preferably 6 to 15, and particularly preferably 6 to 12.

Specific examples of the aromatic ring include an aromatic hydrocarbon ring such as benzene, naphthalene, anthracene, and phenanthrene; and an aromatic heterocyclic ring in which a part of carbon atoms constituting the aromatic hydrocarbon ring is replaced by a heteroatom. Examples of the heteroatom in the aromatic heterocyclic ring include an oxygen atom, a sulfur atom, and a nitrogen atom. Specific examples of the aromatic heterocyclic ring include a pyridine ring and a thiophene ring.

Specific examples of the aromatic hydrocarbon group in Ra′³ include a group in which one hydrogen atom is removed from the aromatic hydrocarbon ring or aromatic heterocyclic ring (an aryl group or a heteroaryl group); a group in which one hydrogen atom is removed from an aromatic compound containing two or more aromatic rings (for example, biphenyl or fluorene); and a group in which one hydrogen atom in the aromatic hydrocarbon ring or aromatic heterocyclic ring is replaced by an alkylene group (for example, an arylalkyl group such as a benzyl group, a phenethyl group, a 1-naphthyl methyl group, a 2-naphthyl methyl group, a 1-naphthyl ethyl group, or a 2-naphthyl ethyl group). The number of carbon atoms of the alkylene group bonded to the aromatic hydrocarbon ring or aromatic heterocyclic ring is preferably 1 to 4, more preferably 1 to 2, and particularly preferably 1.

The cyclic hydrocarbon group in Ra′³ may include a substituent. Examples of the substituent include —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN, and —R^{P2}—COOH (hereinafter, these substituents are collectively referred to as “Ra^{x5}”)

Here, R^{P1} is a monovalent chain saturated hydrocarbon group having 1 to 10 carbon atoms, a monovalent aliphatic cyclic saturated hydrocarbon group having 3 to 20 carbon atoms, or a monovalent aromatic hydrocarbon group having 6 to 30 carbon atoms. R^{PZ} is a single bond, a divalent chain saturated hydrocarbon group having 1 to 10 carbon atoms, a divalent aliphatic cyclic saturated hydrocarbon group having 3 to 20 carbon atoms, or a divalent aromatic hydrocarbon group having 6 to 30 carbon atoms. A part or all of hydrogen atoms of the chain saturated hydrocarbon group, the aliphatic cyclic saturated hydrocarbon group, and the aromatic hydrocarbon group for R^{P1} and R^{P2} may be replaced by fluorine atoms. The aliphatic cyclic hydrocarbon group may have one or more substituents of one kind mentioned above, or may have one or more substituents of each of two or more kinds mentioned above.

Examples of the monovalent chain saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and a cyclododecyl group; and polycyclic aliphatic saturated hydrocarbon groups such as a bicyclo[2.2.2]octanyl group, a tricyclo[5.2.1.02,6]decanyl group, a tricyclo[3.3.1.13,7]decanyl group, a tetracyclo[6.2.1.13,6.02,7]dodecanyl group, and an adamantyl group.

Examples of the monovalent aromatic hydrocarbon group having 6 to 30 carbon atoms include a group in which one hydrogen atom is removed from an aromatic hydrocarbon ring such as benzene, biphenyl, fluorene, naphthalene, anthracene, and phenanthrene.

When Ra′³ is bonded to either Ra′¹ or Ra′² to form a ring, the cyclic group is preferably a 4- to 7-membered ring, and more preferably a 4- to 6-membered ring. Specific examples of the cyclic group include a tetrahydropyranyl group and a tetrahydrofuranyl group.

### Tertiary Alkyl Ester Acid-Dissociable Group:

Among the polar groups, examples of the acid-dissociable group that protects a carboxy group include an acid-dissociable group represented by the following general formula (a1-r-2).

Among the acid-dissociable group represented by the following formula (a1-r-2), those constituted by an alkyl group may be referred to as a “tertiary alkyl ester acid-dissociable group” hereinafter for convenience.

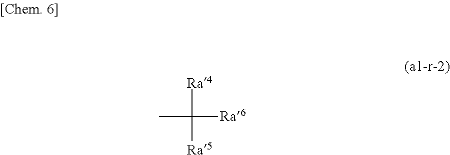

[In the formula, Ra⁴ to Ra′⁶ each represent a hydrocarbon group, and Ra′⁵ and Ra′⁶ may be bonded to each other to form a ring.]

Examples of the hydrocarbon group for Ra′⁴ include a linear or branched alkyl group, a chain or cyclic alkenyl group, or a cyclic hydrocarbon group.

Examples of the linear or branched alkyl group and the cyclic hydrocarbon group (the aliphatic hydrocarbon group which is a monocyclic group, the aliphatic hydrocarbon group which is a polycyclic group, and the aromatic hydrocarbon group) in Ra′⁴ include those same as the Ra′³.

The chain or cyclic alkenyl group in Ra′⁴ is preferably an alkenyl group having 2 to 10 carbon atoms.

Examples of the hydrocarbon group of Ra′⁵ and Ra′⁶ include those same as the Ra′³.

When Ra′⁵ and Ra′⁶ are bonded to each other to form a ring, suitable examples thereof include a group represented by the following general formula (a1-r2-1), a group represented by the following general formula (a1-r2-2), and a group represented by the following general formula (a1-r2-3).

On the other hand, when Ra′⁴ to Ra′⁶ are not bonded to each other and are independent hydrocarbon groups, suitable examples thereof include a group represented by the following general formula (a1-r2-4).

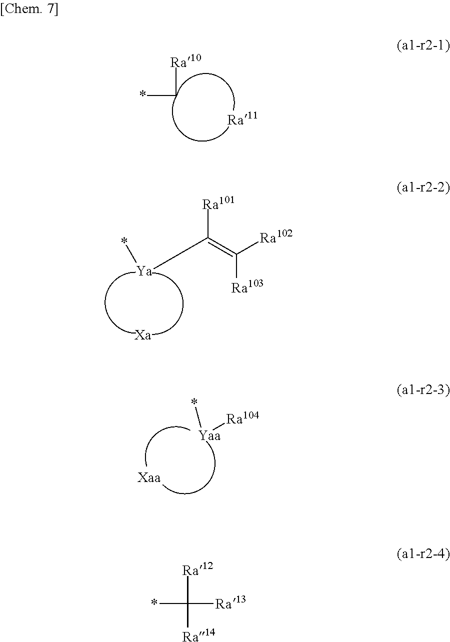

[In the formula (a1-r2-1), Ra′¹⁰ represents a linear or branched alkyl group having 1 to 12 carbon atoms, a part of which may be replaced by a halogen atom or a heteroatom-containing group. Ra′¹¹ represents a group forming an aliphatic cyclic group together with a carbon atom to which Ra′¹⁰ is bonded. In the formula (a1-r2-2), Ya represents a carbon atom. Xa is a group that forms a cyclic hydrocarbon group together with Ya. A part or all of hydrogen atoms of the cyclic hydrocarbon group may be replaced. Ra¹⁰¹ to Ra¹⁰³ each independently represent a hydrogen atom, a monovalent chain saturated hydrocarbon group having 1 to 10 carbon atoms, or a monovalent aliphatic cyclic saturated hydrocarbon group having 3 to 20 carbon atoms. A part or all of hydrogen atoms of the chain saturated hydrocarbon group and the aliphatic cyclic saturated hydrocarbon group may be replaced. Two or more of Ra¹⁰¹ to Ra¹⁰³ may be bonded to each other to form a cyclic structure. In the formula (a1-r2-3), Yaa represents a carbon atom. Xaa is a group that forms an aliphatic cyclic group together with Yaa. Ra¹⁰4 represents an aromatic hydrocarbon group that may include a substituent. In the formula (a1-r2-4), Ra′¹² and Ra′¹³ each independently represent a monovalent chain saturated hydrocarbon group having 1 to 10 carbon atoms. A part or all of hydrogen atoms in the chain saturated hydrocarbon group may be replaced. Ra′¹⁴ is a hydrocarbon group that may include a substituent. * indicates a bond.]

In the above formula (a1-r2-1), Ra′¹⁰ is a linear or branched alkyl group having 1 to 12 carbon atoms, a part of which may be replaced by a halogen atom or a heteroatom-containing group.

The linear alkyl group in Ra′¹⁰ has 1 to 12 carbon atoms, preferably has 1 to 10 carbon atoms, and particularly preferably has 1 to 5 carbon atoms.

Examples of the branched alkyl group in Ra′¹⁰ include those same as the Ra′³.

The alkyl group in Ra′¹⁰ may be partially replaced by a halogen atom or a heteroatom-containing group. For example, a part of hydrogen atoms constituting the alkyl group may be replaced by a halogen atom or a heteroatom-containing group. A part of carbon atoms constituting the alkyl group (such as a methylene group) may be replaced by a heteroatom-containing group.

Examples of the heteroatom used here include an oxygen atom, a sulfur atom, and a nitrogen atom. Examples of the heteroatom-containing group include (—O—), —C(═O)—O—, —O—C(═O)—, —C(═O)—, —O—C(═O)—O—, —C(═O)—NH—, —NH—, —S—, —S(═O)₂—, and —S(═O)₂—O—.

In the formula (a1-r2-1), Ra′¹¹ (an aliphatic cyclic group formed together with a carbon atom to which Ra′¹⁰ is bonded) is preferably a group exemplified as the aliphatic hydrocarbon group (alicyclic hydrocarbon group) which is a monocyclic group or a polycyclic group for Ra′³ in the formula (a1-r-1). Among them, a monocyclic alicyclic hydrocarbon group is preferred, and specifically, a cyclopentyl group and a cyclohexyl group are more preferred, and a cyclopentyl group is still more preferred.

In the formula (a1-r2-2), examples of the cyclic hydrocarbon group formed by Xa together with Ya include a group in which one or more hydrogen atoms are further removed from the cyclic monovalent hydrocarbon group (the aliphatic hydrocarbon group) in Ra′³ in the above formula (a1-r-1).

The cyclic hydrocarbon group formed by Xa together with Ya may include a substituent. Examples of the substituent include those same as the substituent which the cyclic hydrocarbon group in the Ra′³ may have.

Examples of the monovalent chain saturated hydrocarbon group having 1 to 10 carbon atoms in Ra¹⁰¹ to Ra¹⁰³ in the formula (a1-r2-2) include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms in Ra¹⁰¹ to Ra¹⁰³ include monocyclic aliphatic saturated hydrocarbon groups such as a cyclopropyl group, a cyclobutyl group, a cyclopentyl group, a cyclohexyl group, a cycloheptyl group, a cyclooctyl group, a cyclodecyl group, and a cyclododecyl group; and polycyclic aliphatic saturated hydrocarbon groups such as a bicyclo[2.2.2]octanyl group, a tricyclo[5.2.1.02,6]decanyl group, a tricyclo[3.3.1.13,7]decanyl group, a tetracyclo[6.2.1.13,6.02,7]dodecanyl group, and an adamantyl group.

Among them, from the viewpoint of ease of synthesis, Ra¹⁰¹ to Ra¹⁰³ are preferably a hydrogen atom or a monovalent chain saturated hydrocarbon group having 1 to 10 carbon atoms, more preferably a hydrogen atom, a methyl group, or an ethyl group, and particularly preferably a hydrogen atom.

Examples of the substituent that the chain saturated hydrocarbon group or the aliphatic cyclic saturated hydrocarbon group represented by any one of Ra¹⁰¹ to Ra¹⁰³ may include groups same as those represented by Ra^{x5} above.

Examples of the group containing a carbon-carbon double bond generated by two or more of Ra¹⁰¹ to Ra¹⁰³ bonding to each other to form a cyclic structure include a cyclopentenyl group, a cyclohexenyl group, a methylcyclopentenyl group, a methylcyclohexenyl group, a cyclopentylideneethenyl group, and a cyclohexylideneethenyl group. Among them, from the viewpoint of ease of synthesis, a cyclopentenyl group, a cyclohexenyl group, and a cyclopentylideneethenyl group are preferred.

In the formula (a1-r2-3), the aliphatic cyclic group formed by Xaa together with Yaa is preferably a group exemplified as the aliphatic hydrocarbon group which is a monocyclic group or a polycyclic group for Ra′³ in the formula (a1-r-1).

Examples of the aromatic hydrocarbon group in Ra¹⁰⁴ in the formula (a1-r2-3) include a group in which one or more hydrogen atoms are removed from an aromatic hydrocarbon ring having 5 to 30 carbon atoms. Among them, Ra¹⁰⁴ is preferably a group in which one or more hydrogen atoms are removed from an aromatic hydrocarbon ring having 6 to 15 carbon atoms, more preferably a group in which one or more hydrogen atoms are removed from benzene, naphthalene, anthracene, or phenanthrene, still more preferably a group in which one or more hydrogen atoms are removed from benzene, naphthalene, or anthracene, particularly preferably a group in which one or more hydrogen atoms are removed from benzene or naphthalene, and most preferably a group in which one or more hydrogen atoms are removed from benzene.

Examples of the substituent that Ra¹⁰⁴ in the formula (a1-r2-3) may have include a methyl group, an ethyl group, a propyl group, a hydroxy group, a carboxy group, a halogen atom, an alkoxy group (such as a methoxy group, an ethoxy group, a propoxy group, and a butoxy group), and an alkyloxycarbonyl group.

In the formula (a1-r2-4), Ra′¹² and Ra′¹³ each independently represent a monovalent chain saturated hydrocarbon group having 1 to 10 carbon atoms. Examples of the monovalent chain saturated hydrocarbon group having 1 to 10 carbon atoms in Ra′¹² and Ra′¹³ include those same as the monovalent chain saturated hydrocarbon group having 1 to 10 carbon atoms in the Ra¹⁰¹ to Ra¹⁰³. A part or all of hydrogen atoms of the chain saturated hydrocarbon group may be replaced.

Among them, Ra′¹² and Ra′¹³ are preferably an alkyl group having 1 to 5 carbon atoms, more preferably a methyl group or an ethyl group, and particularly preferably a methyl group.

When the chain saturated hydrocarbon groups represented by Ra′¹² and Ra′¹³ are replaced, examples of the substituent include groups same as those described above for Ra^{x5}.

In the formula (a1-r2-4), Ra′¹⁴ represents a hydrocarbon group that may include a substituent. Examples of the hydrocarbon group in Ra′¹⁴ include a linear or branched alkyl group and a cyclic hydrocarbon group.

The linear alkyl group in Ra′¹⁴ preferably has 1 to 5 carbon atoms, more preferably has 1 to 4 carbon atoms, and still more preferably has 1 or 2 carbon atoms. Specific examples thereof include a methyl group, an ethyl group, an n-propyl group, an n-butyl group, and an n-pentyl group. Among them, a methyl group, an ethyl group, or an n-butyl group is preferred, and a methyl group or an ethyl group is more preferred.

The branched alkyl group in Ra′¹⁴ preferably has 3 to 10 carbon atoms, and more preferably has 3 to 5 carbon atoms. Specific examples thereof include an isopropyl group, an isobutyl group, a tert-butyl group, an isopentyl group, a neopentyl group, a 1,1-diethylpropyl group, and a 2,2-dimethylbutyl group. An isopropyl group is preferred.

When Ra′¹⁴ is a cyclic hydrocarbon group, the hydrocarbon group may be an aliphatic hydrocarbon group or an aromatic hydrocarbon group, and may be a polycyclic group or a monocyclic group.

The aliphatic hydrocarbon group which is a monocyclic group is preferably a group in which one hydrogen atom is removed from a monocycloalkane. The monocycloalkane preferably has 3 to 6 carbon atoms, and specific examples thereof include cyclopentane and cyclohexane.

The aliphatic hydrocarbon group which is a polycyclic group is preferably a group in which one hydrogen atom is removed from a polycycloalkane. The polycycloalkane is preferably a group having 7 to 12 carbon atoms, and specific examples thereof include adamantane, norbornane, isobornane, tricyclodecane, and tetracyclododecane.

Examples of the aromatic hydrocarbon group in Ra′¹⁴ include those same as the aromatic hydrocarbon group in Ra¹⁰⁴. Among them, Ra′¹⁴ is preferably a group in which one or more hydrogen atoms are removed from an aromatic hydrocarbon ring having 6 to 15 carbon atoms, more preferably a group in which one or more hydrogen atoms are removed from benzene, naphthalene, anthracene, or phenanthrene, still more preferably a group in which one or more hydrogen atoms are removed from benzene, naphthalene, or anthracene, particularly preferably a group in which one or more hydrogen atoms are removed from naphthalene or anthracene, and most preferably a group in which one or more hydrogen atoms are removed from naphthalene.

Examples of the substituent that Ra′¹⁴ may have include those same as the substituents that Ra¹⁰⁴ may have.

When Ra′¹⁴ in the formula (a1-r2-4) is a naphthyl group, a position at which Ra′¹⁴ bonds to a tertiary carbon atom in the formula (a1-r2-4) may be either 1-position or 2-position of the naphthyl group.

When Ra′¹⁴ in the formula (a1-r2-4) is an anthryl group, a position at which Ra′¹⁴ bonds to a tertiary carbon atom in the formula (a1-r2-4) may be any of 1-position, 2-position, and 9-position of the anthryl group.

Specific examples of the group represented by the formula (a1-r2-1) are shown below.

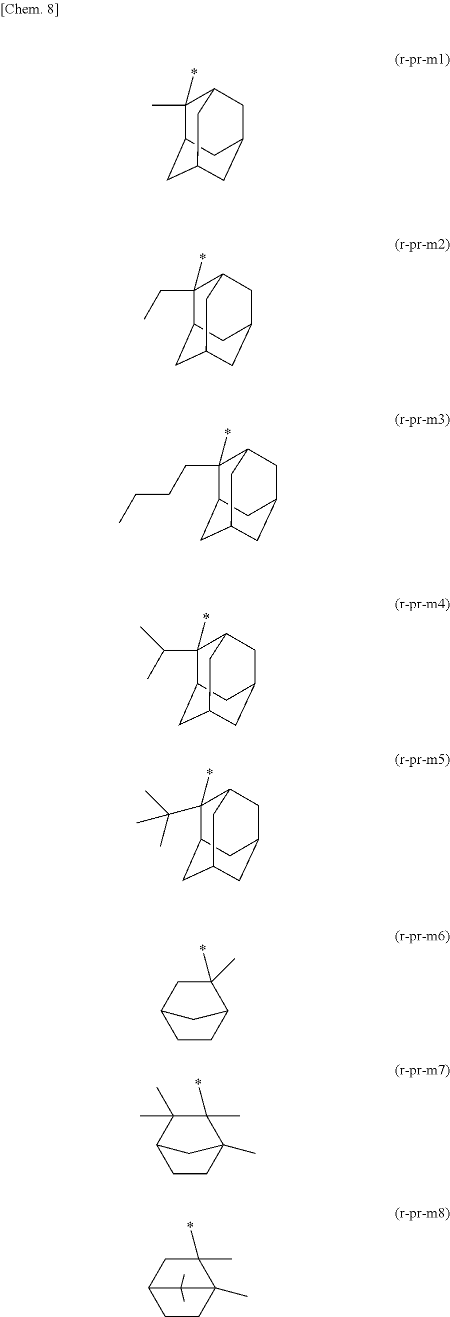

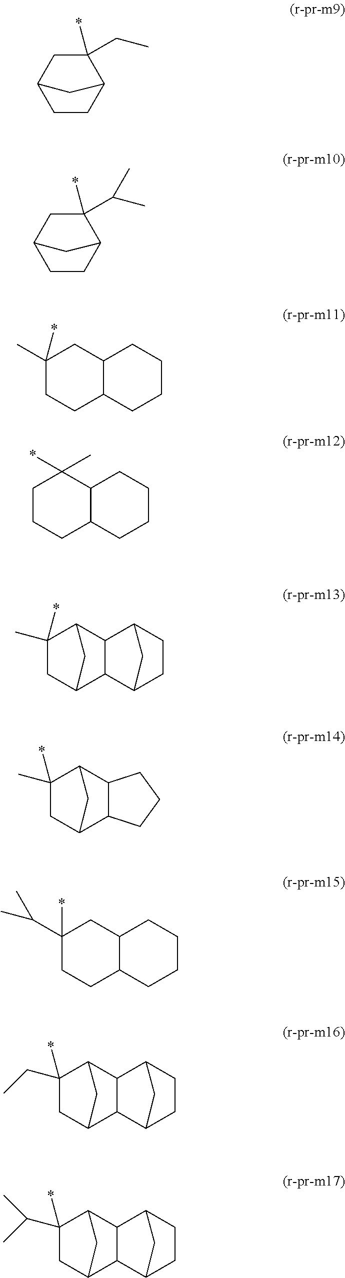

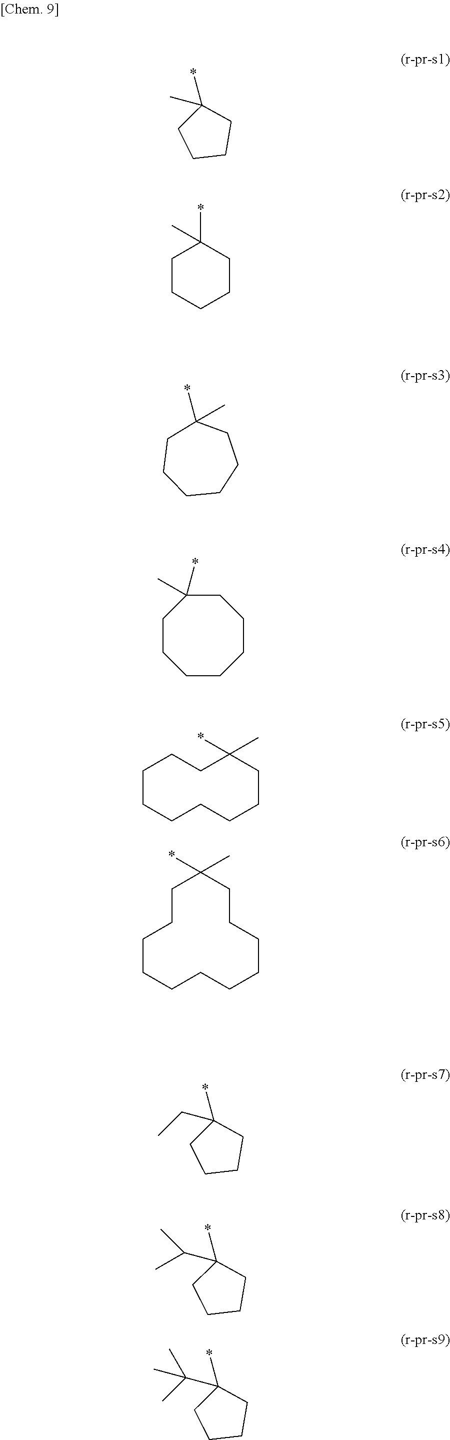

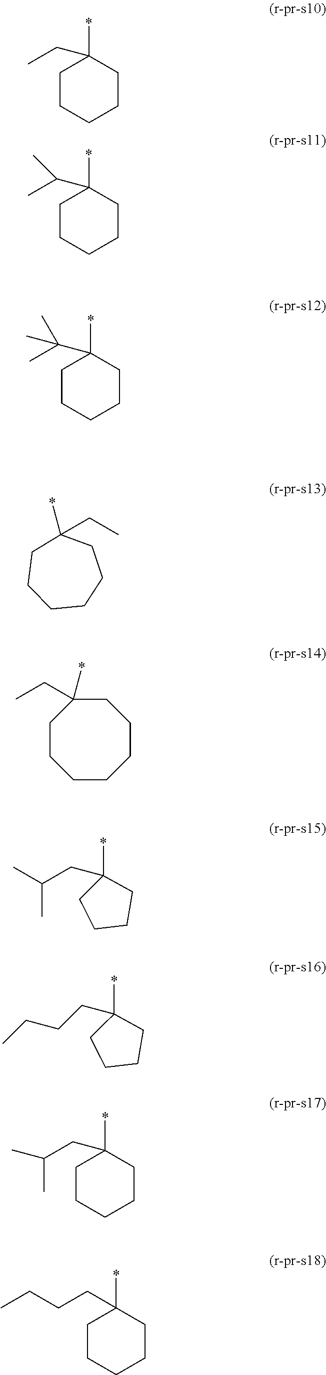

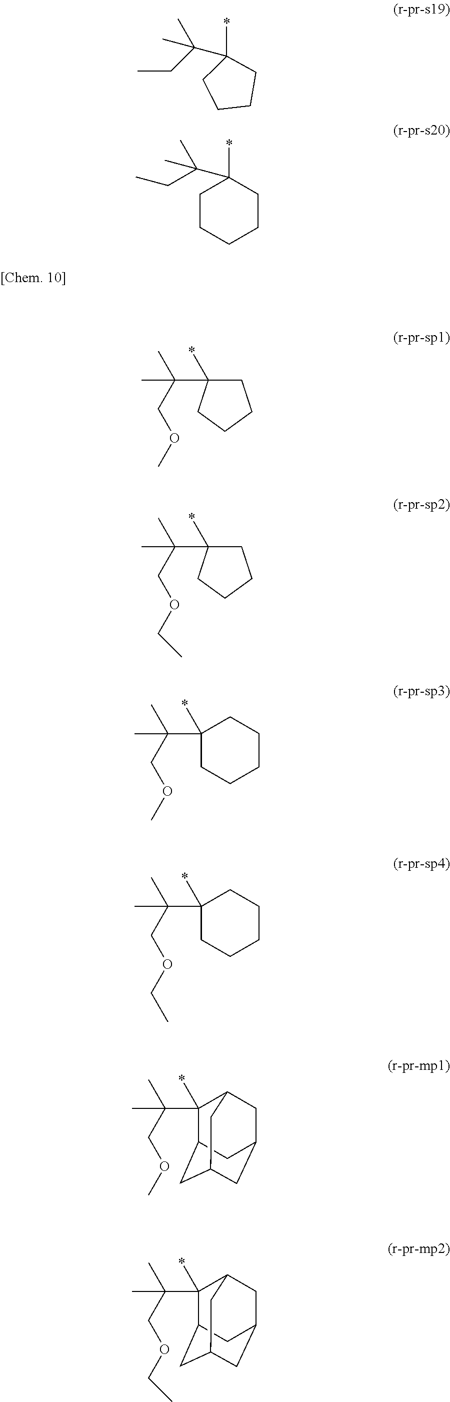

Specific examples of the group represented by the formula (a1-r2-2) are shown below.

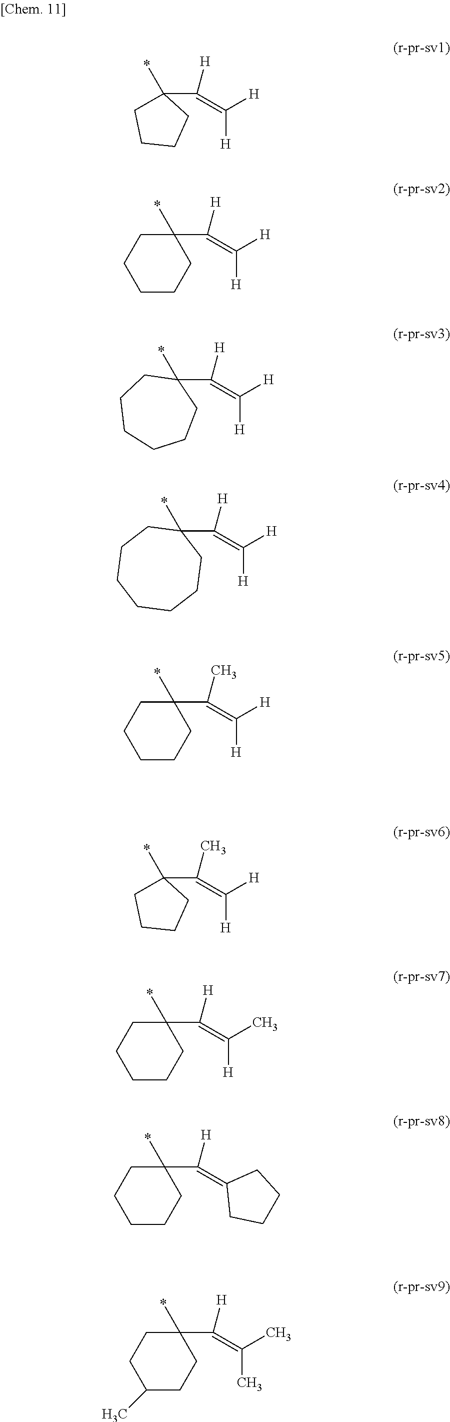

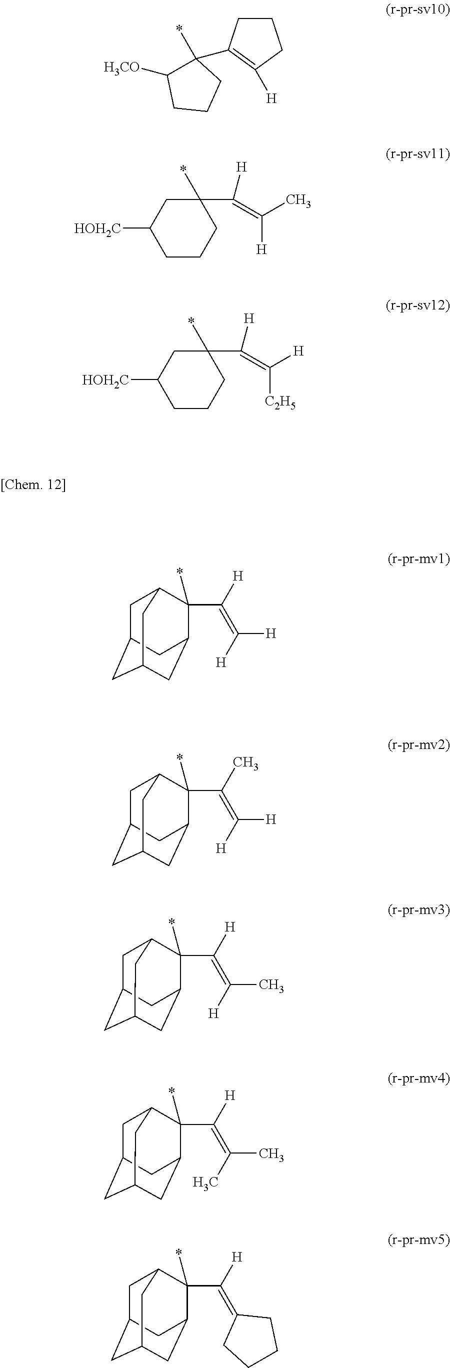

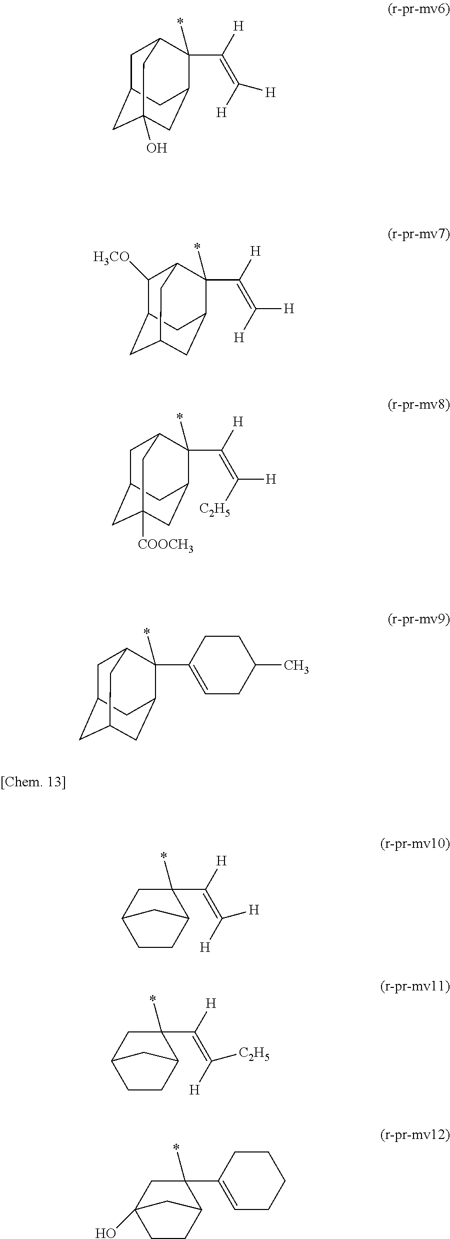

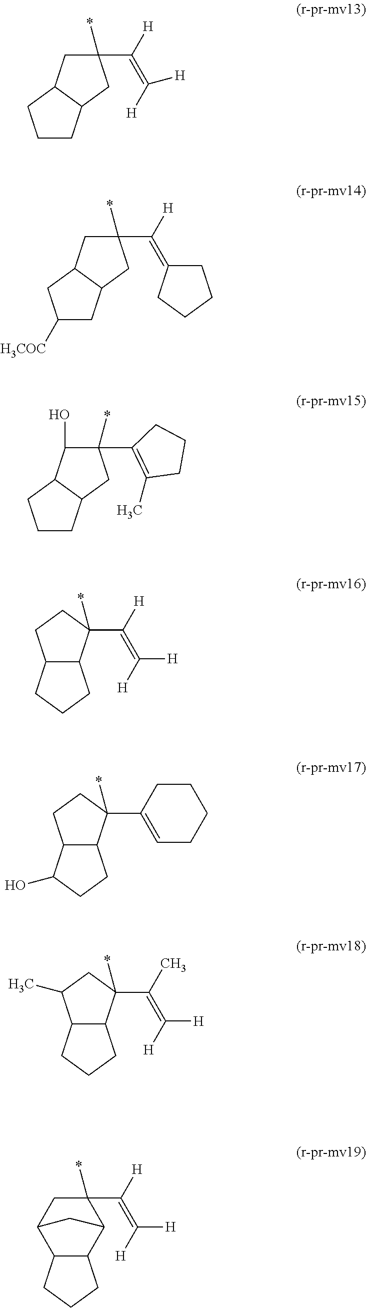

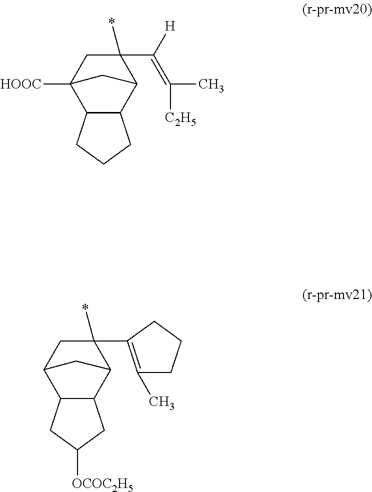

Specific examples of the group represented by the formula (a1-r2-3) are shown below.

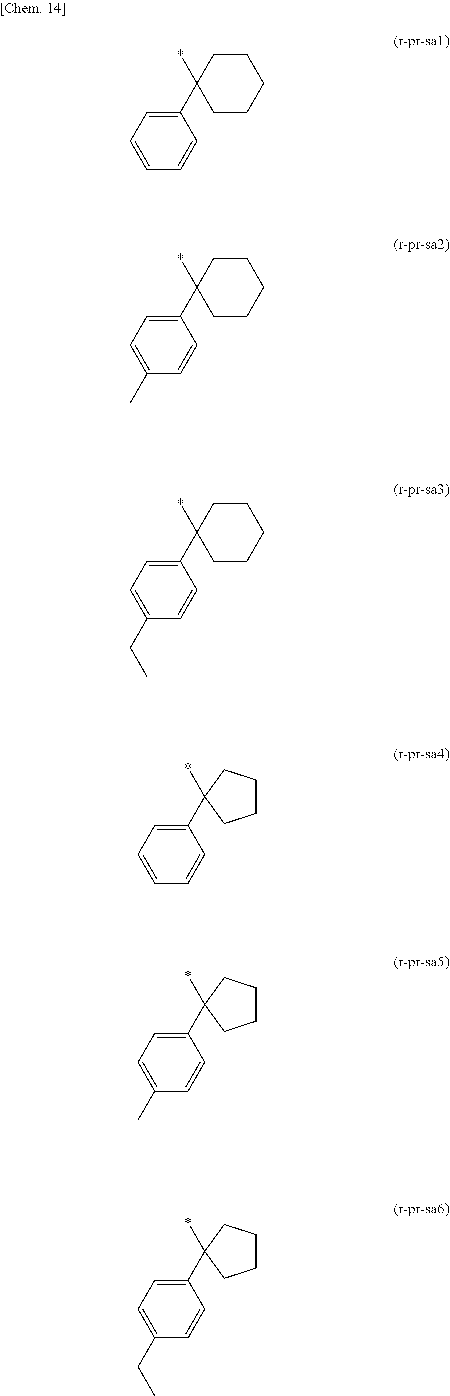 [SMILES: *C1(c2ccccc2)CCCCC1 ; *C1(c2ccc(C)cc2)CCCCC1 ; *C1(c2ccc(CC)cc2)CCCCC1 ; *C1(c2ccccc2)CCCC1 ; *C1(c2ccc(C)cc2)CCCC1 ; *C1(c2ccc(CC)cc2)CCCC1]

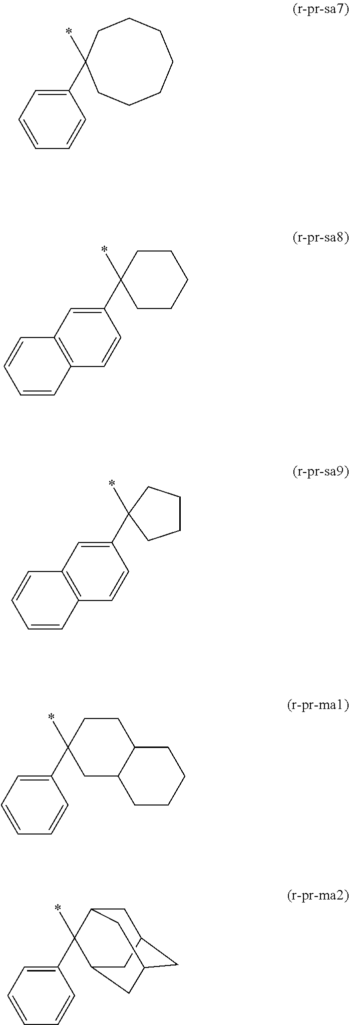 [SMILES: *C1(c2ccccc2)CCCCCCC1 ; *C1(c2ccc3ccccc3c2)CCCCC1 ; *C1(c2ccc3ccccc3c2)CCCC1 ; *C1(c2ccccc2)CCC2CCCCC2C1 ; *C1(c2ccccc2)C2CC3CC(C2)CC1C3]

Specific examples of the group represented by the formula (a1-r2-4) are shown below.

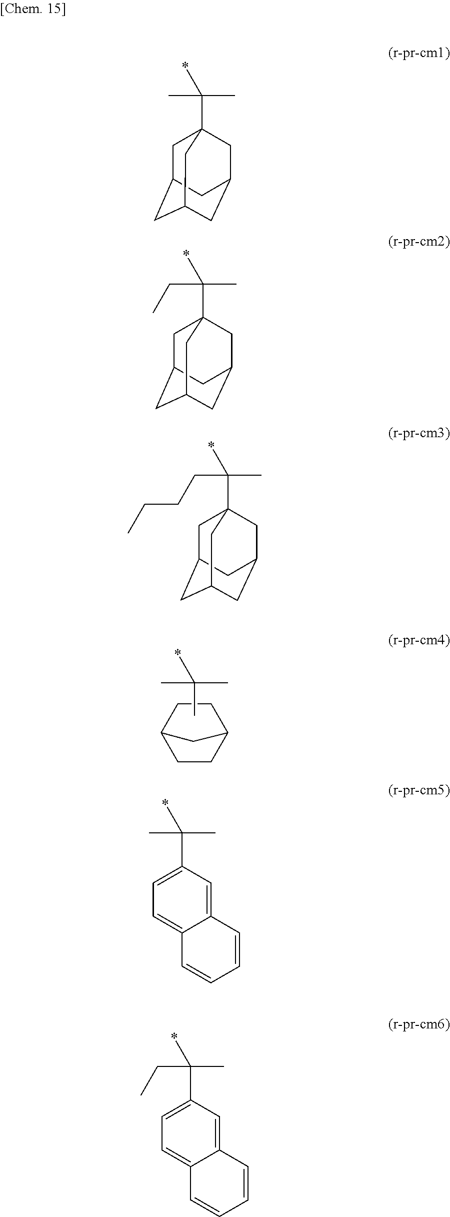

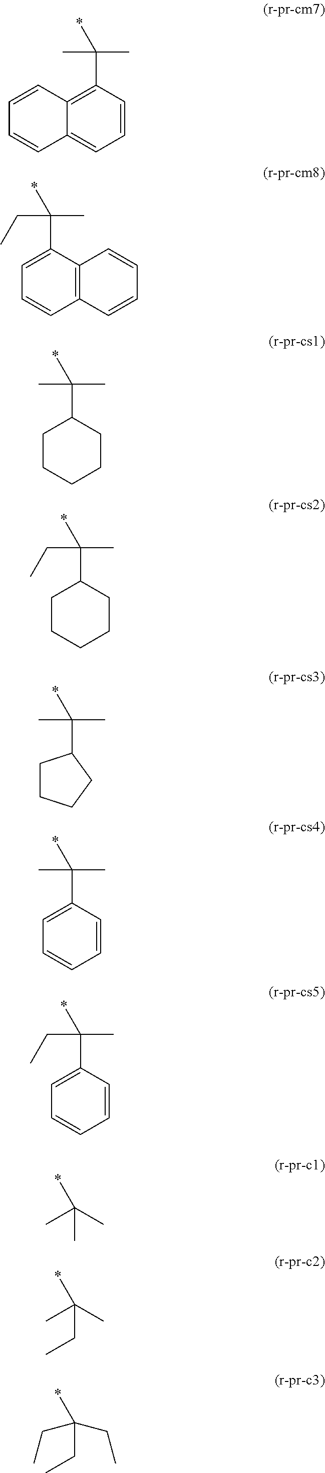

### Tertiary Alkyloxycarbonyl Acid-Dissociable Group:

Among the polar groups, examples of the acid-dissociable group that protects a hydroxy group include an acid-dissociable group represented by the following general formula (a1-r-3) (hereinafter, for convenience, may be referred to as “tertiary alkyloxycarbonyl acid-dissociable group”).

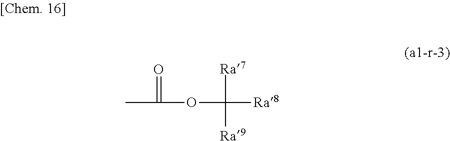

[In the formula, Ra′⁷ to Ra′⁹ each represent an alkyl group.]

In the formula (a1-r-3), Ra′⁷ to Ra′⁹ are each preferably an alkyl group having 1 to 5 carbon atoms, and more preferably an alkyl group having 1 to 3 carbon atoms.

The total number of carbon atoms in each alkyl group is preferably 3 to 7, more preferably 3 to 5, and most preferably 3 or 4.

Examples of the structural unit (a1) include a structural unit derived from an acrylic ester in which a hydrogen atom bonded to a carbon atom at the α-position may be replaced by a substituent, a structural unit derived from an acrylamide, a structural unit in which at least a part of hydrogen atoms in a hydroxy group of a structural unit derived from hydroxystyrene or a hydroxystyrene derivative is protected by a substituent containing the acid-decomposable group, and a structural unit in which at least a part of hydrogen atoms in —C(═O)—OH of a structural unit derived from vinylbenzoic acid or a vinylbenzoic acid derivative is protected by a substituent containing the acid-decomposable group.

As the structural unit (a1), among the above, a structural unit derived from an acrylic ester in which a hydrogen atom bonded to a carbon atom at the α-position may be replaced by a substituent is preferred.

Preferred specific examples of such a structural unit (a1) include a structural unit represented by the following general formula (a1-1) or (a1-2).

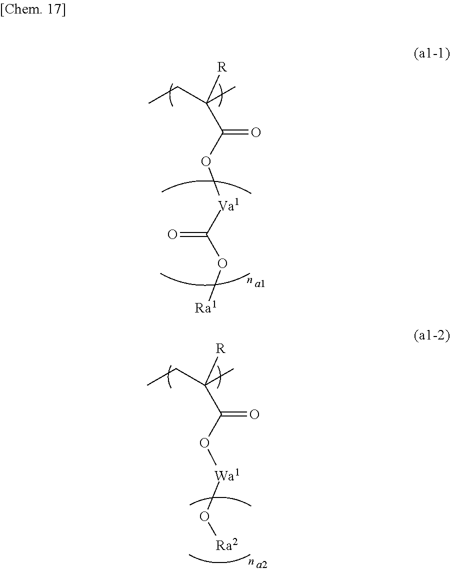

(In the formula, R represents a hydrogen atom, an alkyl group having 1 to 5 carbon atoms, or a halogenated alkyl group having 1 to 5 carbon atoms. Va¹ is a divalent hydrocarbon group that may include an ether bond. The symbol nₐ₁ is an integer of 0 to 2. Ra¹ is an acid-dissociable group represented by the above general formula (a1-r-1) or (a1-r-2). Wa¹ is a nₐ₂+1-valent hydrocarbon group, nₐ₂ is an integer of 1 to 3, and Ra² is an acid-dissociable group represented by the above general formula (a1-r-1) or (a1-r-3).]

In the formula (a1-1) and (a1-2), the alkyl group having 1 to 5 carbon atoms of R is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group in which a part or all of hydrogen atoms of the alkyl group having 1 to 5 carbon atoms are replaced by halogen atoms. The halogen atom is particularly preferably a fluorine atom.

R is preferably a hydrogen atom, an alkyl group having 1 to 5 carbon atoms, or a fluorinated alkyl group having 1 to 5 carbon atoms, and from the viewpoint of industrial availability, a hydrogen atom or a methyl group is most preferred.

In the formula (a1-1), the divalent hydrocarbon group in Va¹ may be either an aliphatic hydrocarbon group or an aromatic hydrocarbon group.

The aliphatic hydrocarbon group as the divalent hydrocarbon group in Va¹ may be saturated or unsaturated, and generally, is preferably saturated.

More specific examples of the aliphatic hydrocarbon group include a linear or branched aliphatic hydrocarbon group, and an aliphatic hydrocarbon group containing a ring in the structure thereof.

The linear aliphatic hydrocarbon group preferably has 1 to 10 carbon atoms, more preferably has 1 to 6 carbon atoms, still more preferably has 1 to 4 carbon atoms, and most preferably has 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group preferably has 2 to 10 carbon atoms, more preferably has 3 to 6 carbon atoms, still more preferably has 3 or 4 carbon atoms, and most preferably has 3 carbon atoms.

The branched aliphatic hydrocarbon group is preferably a branched alkylene group, and specific examples thereof include alkyl alkylene groups such as alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyl trimethylene groups such as —CH(CH₃)CH₂CH₂— and —CH₂CH(CH₃)CH₂—; and alkyl tetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

Examples of the aliphatic hydrocarbon group containing a ring in the structure thereof include an alicyclic hydrocarbon group (a group in which two hydrogen atoms are removed from an aliphatic hydrocarbon ring), a group in which an alicyclic hydrocarbon group is bonded to the terminal of a linear or branched aliphatic hydrocarbon group, and a group in which an alicyclic hydrocarbon group is interposed in the middle of a linear or branched aliphatic hydrocarbon group. Examples of the linear or branched aliphatic hydrocarbon group include those same as the linear aliphatic hydrocarbon group or the branched aliphatic hydrocarbon group.

The alicyclic hydrocarbon group preferably has 3 to 20 carbon atoms, and more preferably has 3 to 12 carbon atoms.

The alicyclic hydrocarbon group may be polycyclic or monocyclic. The monocyclic alicyclic hydrocarbon group is preferably a group in which two hydrogen atoms are removed from a monocycloalkane. The monocycloalkane preferably has 3 to 6 carbon atoms, and specific examples thereof include cyclopentane and cyclohexane. The polycyclic alicyclic hydrocarbon group is preferably a group in which two hydrogen atoms are removed from a polycycloalkane. The polycycloalkane is preferably a group having 7 to 12 carbon atoms. Specific examples thereof include adamantane, norbornane, isobornane, tricyclodecane, and tetracyclododecane.

The aromatic hydrocarbon group as the divalent hydrocarbon group in Va¹ is a hydrocarbon group having an aromatic ring.

The aromatic hydrocarbon group preferably has 3 to 30 carbon atoms, more preferably has 5 to 30 carbon atoms, still more preferably has 5 to 20 carbon atoms, particularly preferably has 6 to 15 carbon atoms, and most preferably has 6 to 12 carbon atoms. The number of the carbon atoms does not include the number of the carbon atoms in the substituent.

Specific examples of the aromatic ring contained in the aromatic hydrocarbon group include an aromatic hydrocarbon ring such as benzene, biphenyl, fluorene, naphthalene, anthracene, and phenanthrene; and an aromatic heterocyclic ring in which a part of carbon atoms constituting the aromatic hydrocarbon ring is replaced by a heteroatom. Examples of the heteroatom in the aromatic heterocyclic ring include an oxygen atom, a sulfur atom, and a nitrogen atom.

Specific examples of the aromatic hydrocarbon group include a group in which two hydrogen atoms are removed from the aromatic hydrocarbon ring (an arylene group); a group in which one hydrogen atom of a group in which one hydrogen atom is removed from the aromatic hydrocarbon ring (an aryl group) is replaced by an alkylene group (for example, a group in which one hydrogen atom is further removed from the aryl group in an arylalkyl group such as a benzyl group, a phenethyl group, a 1-naphthylmethyl group, a 2-naphthylmethyl group, a 1-naphthylethyl group, or a 2-naphthylethyl group). The number of carbon atoms of the alkylene group (an alkyl chain in the arylalkyl group) is preferably 1 to 4, more preferably 1 to 2, and particularly preferably 1.

In the formula (a1-1), Ra¹ is an acid-dissociable group represented by the above formula (a1-r-1) or (a1-r-2).

In the formula (a1-2), the nₐ₂+1-valent hydrocarbon group in Wa¹ may be an aliphatic hydrocarbon group or an aromatic hydrocarbon group. The aliphatic hydrocarbon group means a hydrocarbon group having no aromaticity, and may be saturated or unsaturated, and generally, is preferably saturated. Examples of the aliphatic hydrocarbon group include a linear or branched aliphatic hydrocarbon group, an aliphatic hydrocarbon group containing a ring in the structure thereof, and a group obtained by combining a linear or branched aliphatic hydrocarbon group and an aliphatic hydrocarbon group containing a ring in the structure thereof.

The nₐ₂+1-valence is preferably 2-valent to 4-valent, and more preferably 2-valent or 3-valent.

In the formula (a1-2), Ra² is an acid-dissociable group represented by the above general formula (a1-r-1) or (a1-r-3).

Specific examples of the structural unit represented by the formula (a1-1) are shown below. In the following formulae, R^{α} represents a hydrogen atom, a methyl group, or a trifluoromethyl group.

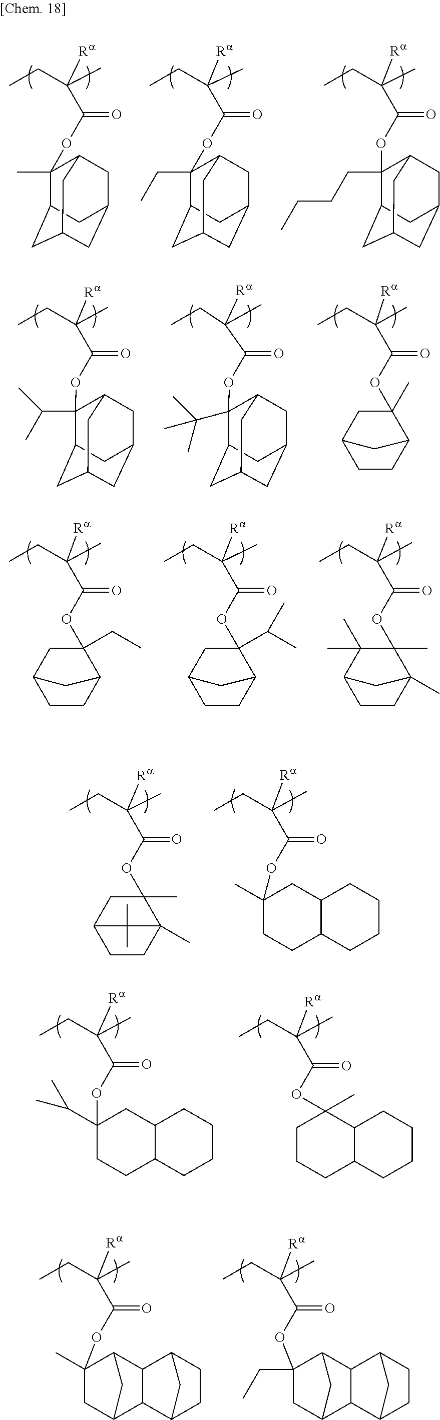

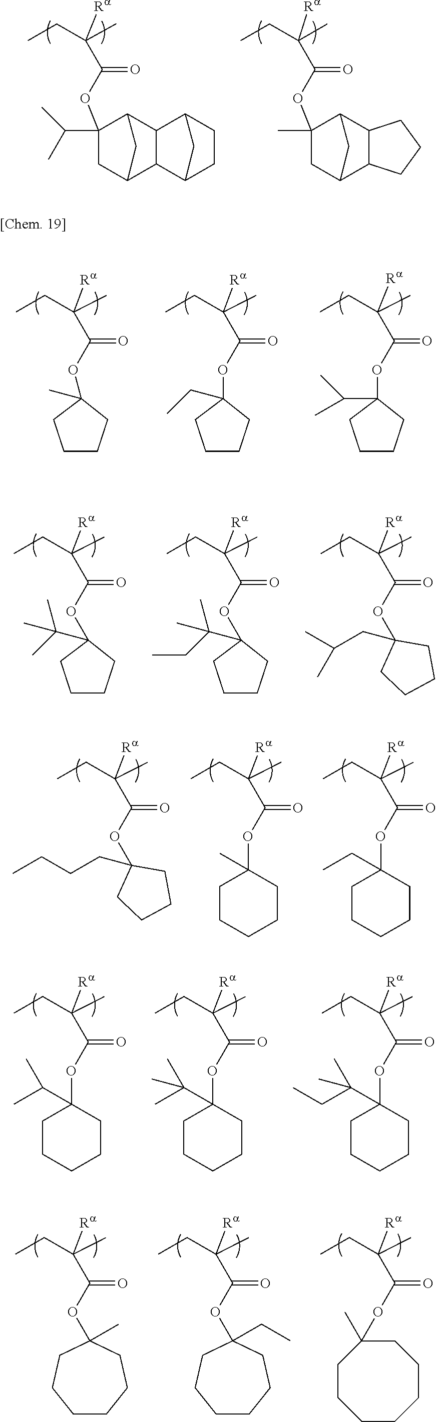

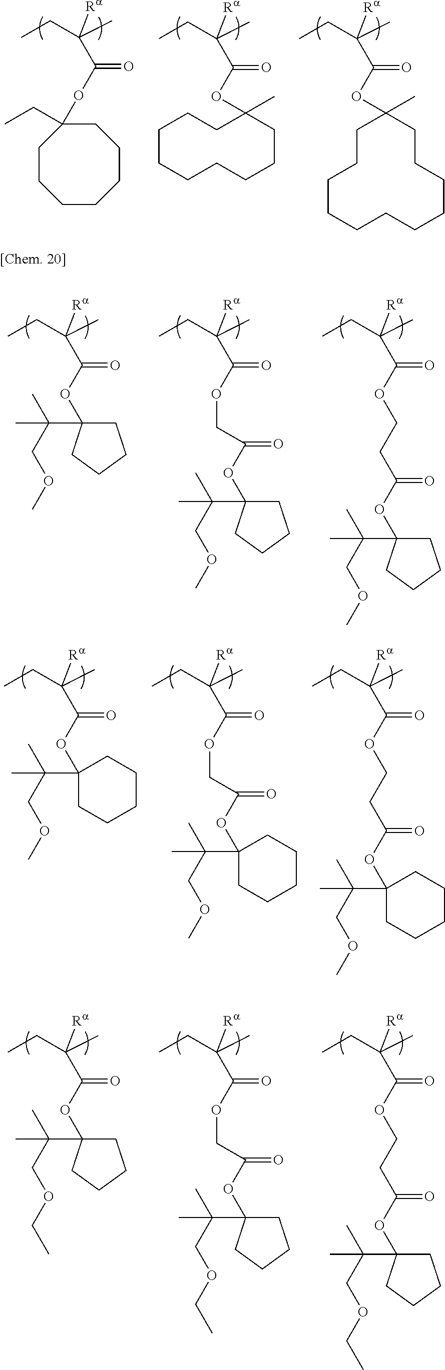

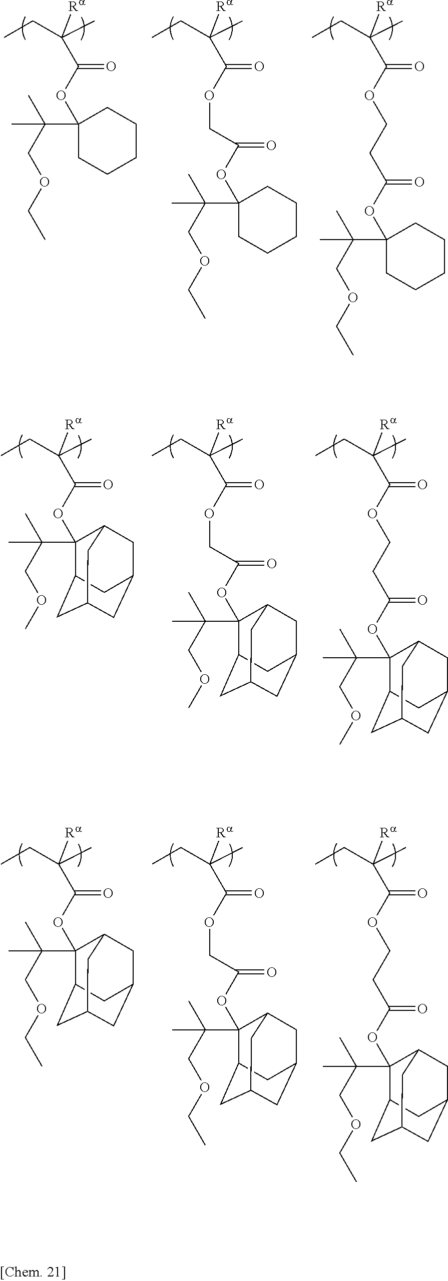

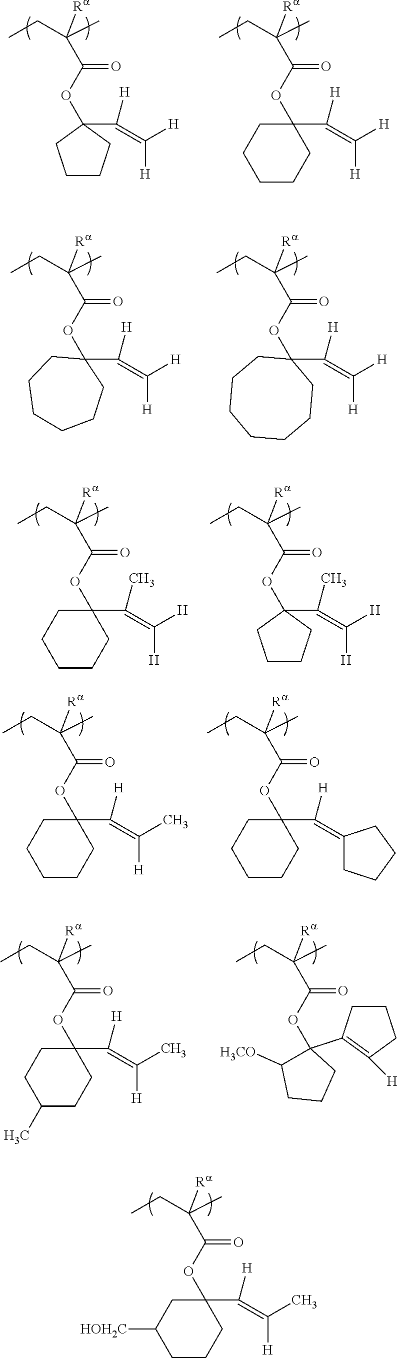

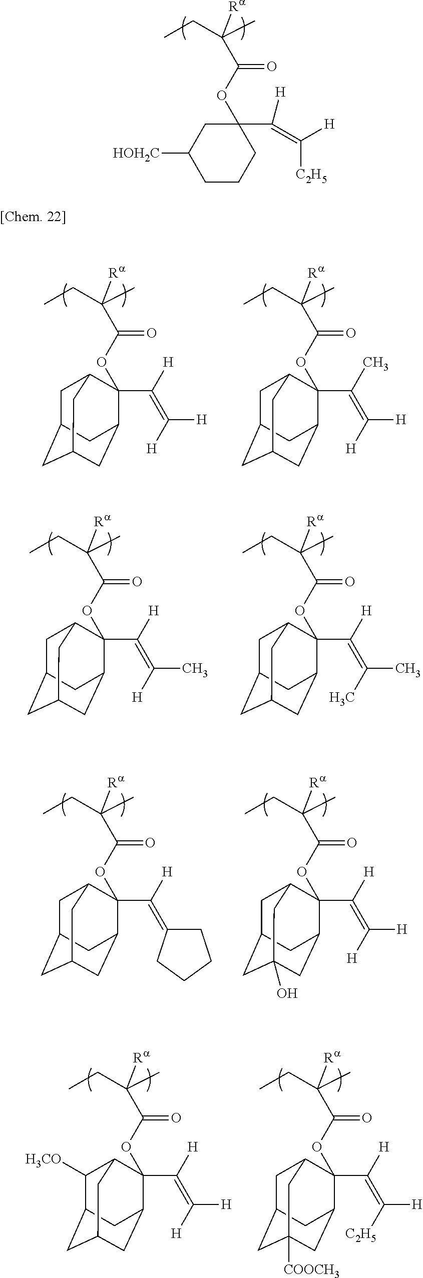

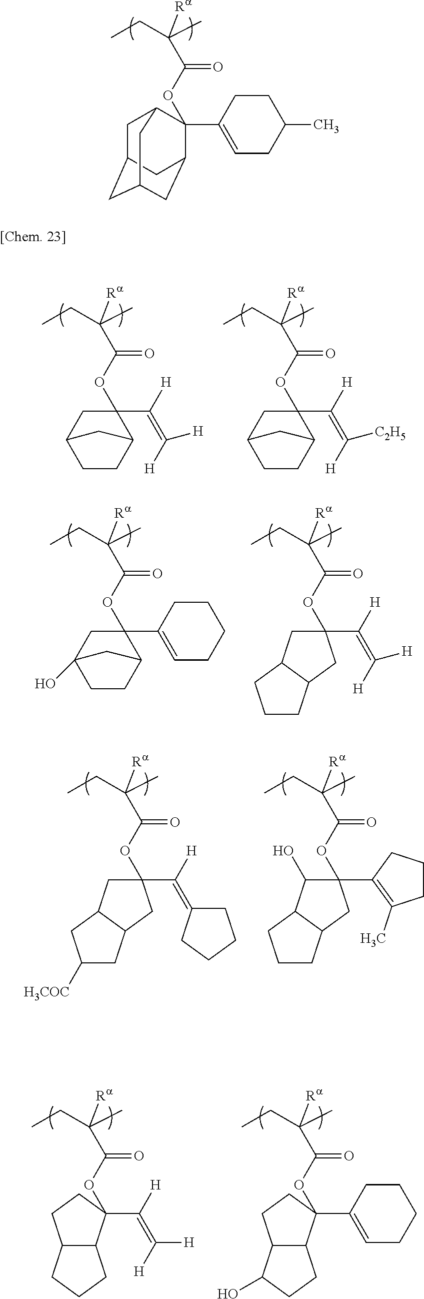

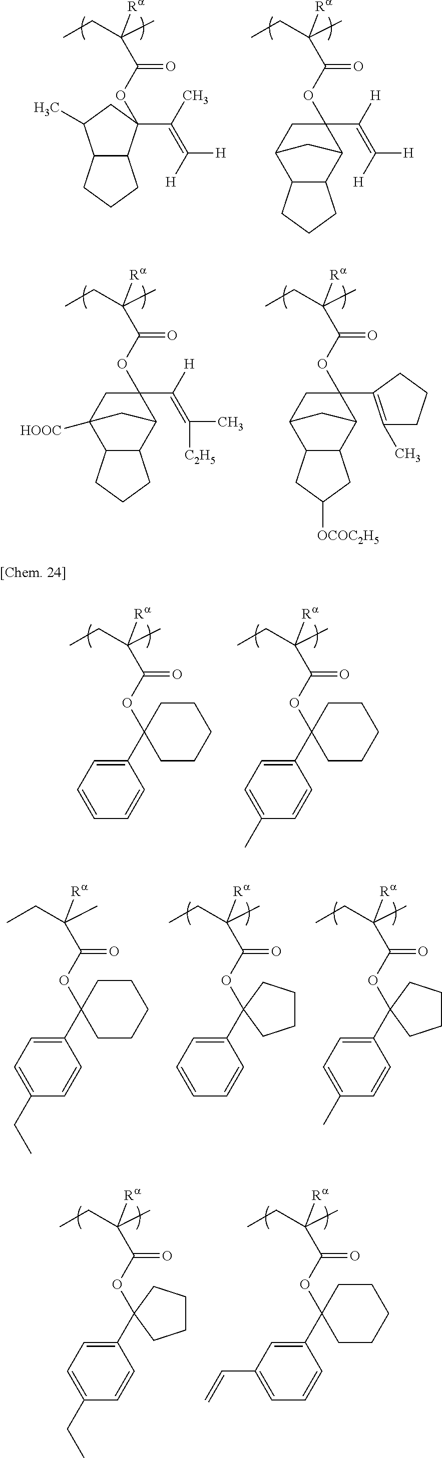

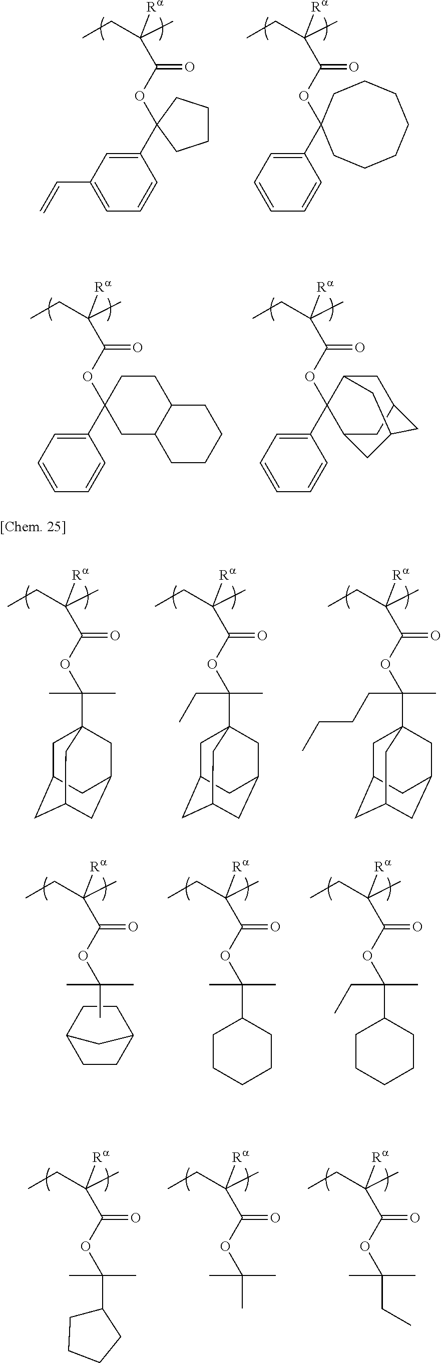

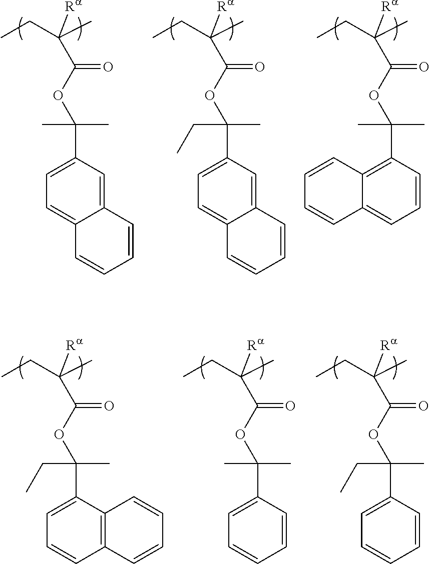

The structural unit (a1) contained in the component (A1) may be used alone or in combination of two or more kinds thereof.

As the structural unit (a1), a structural unit represented by the formula (a1-1) is more preferred, since characteristics (sensitivity, shape, or the like) in lithography using an electron beam or EUV can be easily improved.

Among the above, as the structural unit (a1), one containing a structural unit represented by the following general formula (a1-1-1) is particularly preferred.

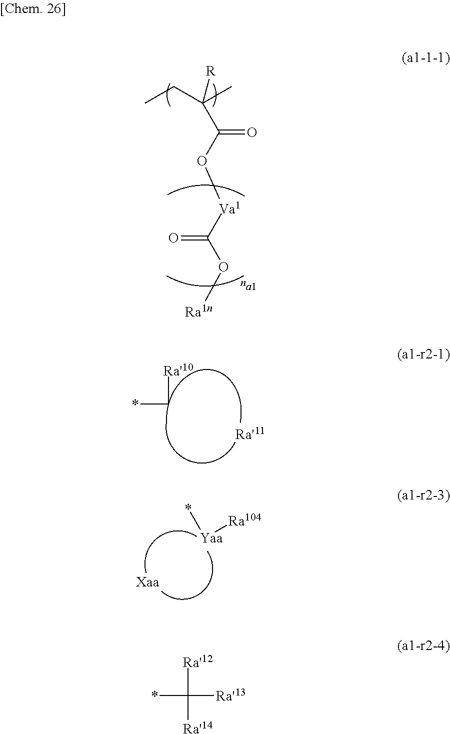

[In the formula, Ra¹″ is an acid-dissociable group represented by the general formula (a1-r2-1), (a1-r2-3), or (a1-r2-4).]

In the general formula (a1-1-1), R, Va¹ and nₐ₁ are the same as defined for R, Va¹ and nₐ₁ in the general formula (a1-1).

The acid-dissociable group represented by the general formula (a1-r2-1), (a1-r2-3), or (a1-r2-4) is as described above. Among them, it is preferable to select one in which the acid-dissociable group is a cyclic group since the reactivity is suitably improved for EB or EUV.

In the formula (a1-1-1), Ra¹″ is preferably an acid-dissociable group represented by the general formula (a1-r2-1) among the above.

A proportion of the structural unit (a1) in the component (A1) is preferably 5 mol % to 80 mol %, more preferably 10 mol % to 75 mol %, still more preferably 30 mol % to 70 mol %, and particularly preferably 40 mol % to 70 mol %, with respect to a total (100 mol %) of all structural units constituting the component (A1).

When the proportion of the structural unit (a1) is equal to or larger than the lower limit value of the preferred range, lithography properties such as resolution, and roughness improvement are improved. On the other hand, when the proportion of the structural unit (a1) is equal to or less than the upper limit value of the preferred range, a balance with other structural units can be achieved, and various lithography properties are improved.

### <<Other Structural Units>>

The component (A1) may contain other structural units, in addition to the above structural unit (a1), as necessary.

Examples of the other structural units include a structural unit (a2) containing a lactone-containing cyclic group, an —SO₂— containing cyclic group, or a carbonate-containing cyclic group; a structural unit (a3) containing a polar group-containing aliphatic hydrocarbon group; and a structural unit (a4) containing an acid non-dissociable aliphatic cyclic group.

In the resist composition according to the embodiment of the present invention, it is preferable that the component (A1) do not contain, as the structural unit, a structural unit (st) derived from styrene or a styrene derivative; or a structural unit derived from hydroxystyrene or a hydroxystyrene derivative, since the properties in lithography using ArF can be easily improved.

### Regarding Structural Unit (a2):

The component (A1) may further contain, in addition to the structural unit (a1), a structural unit (a2) containing a lactone-containing cyclic group, an —SO₂— containing cyclic group, or a carbonate-containing cyclic group (provided that one corresponding to the structural unit (a1) is excluded).

The lactone-containing cyclic group, the —SO₂— containing cyclic group, or the carbonate-containing cyclic group of the structural unit (a2) is effective in improving adhesion of the resist film to the substrate when the component (A1) is used for forming a resist film. When the structural unit (a2) is contained, for example, an acid diffusion length can be appropriately adjusted, the adhesion of the resist film to the substrate can be improved, and the solubility during development can be appropriately adjusted, resulting in improved lithography properties.

The term “lactone-containing cyclic group” refers to a cyclic group containing a ring (a lactone ring) containing —O—C(═O)— in the ring skeleton thereof. When a lactone ring is counted as a first ring, a group having only a lactone ring is referred to as a monocyclic group, and a group further having another ring structure is referred to as a polycyclic group regardless of the structure. The lactone-containing cyclic group may be a monocyclic group or a polycyclic group.

The lactone-containing cyclic group in the structural unit (a2) is not particularly limited, and any group can be used. Specific examples thereof include a group represented by any one of the following general formulae (a2-r-1) to (a2-r-7).

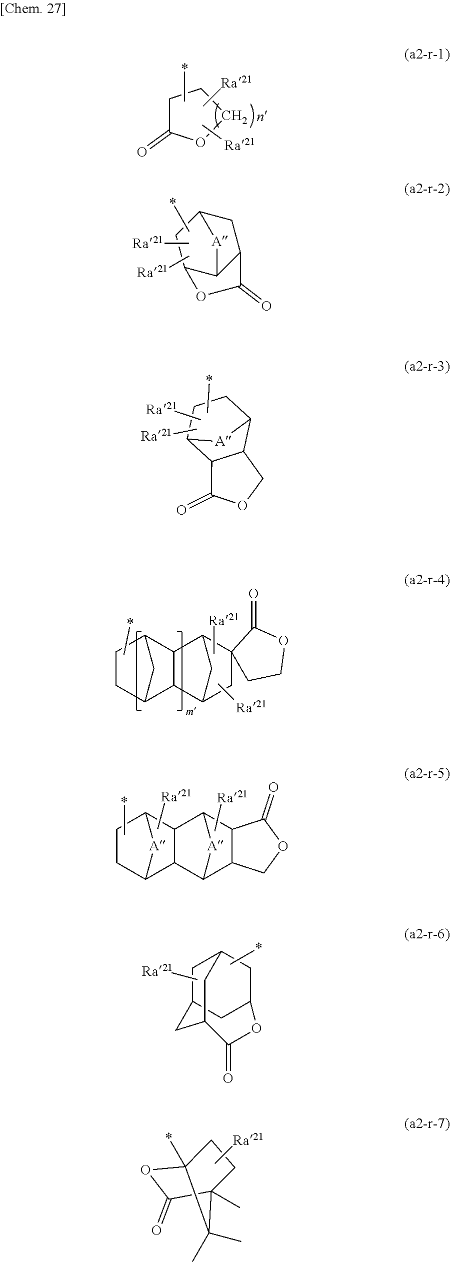

[In the formula, Ra′²¹'s each independently represent a hydrogen atom, an alkyl group, an alkoxy group, a halogen atom, a halogenated alkyl group, a hydroxy group, —COOR″, —OC(═O)R″, a hydroxyalkyl group, or a cyano group; R″ represents a hydrogen atom, an alkyl group, a lactone-containing cyclic group, a carbonate-containing cyclic group, or an —SO₂— containing cyclic group; A″ represents an alkylene group having 1 to 5 carbon atoms which may contain an oxygen atom (—O—) or a sulfur atom (—S—), an oxygen atom, or a sulfur atom; n′ represents an integer of 0 to 2, and m′ represents 0 or 1.]

In the general formulae (a2-r-1) to (a2-r-7), the alkyl group in Ra′²¹ is preferably an alkyl group having 1 to 6 carbon atoms. The alkyl group is preferably linear or branched. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among them, a methyl group or an ethyl group is preferred, and a methyl group is particularly preferred.

The alkoxy group in Ra′²¹ is preferably an alkoxy group having 1 to 6 carbon atoms. The alkoxy group is preferably linear or branched. Specific examples thereof include a group in which an oxygen atom (—O—) is linked to an alkyl group described as the alkyl group in Ra′²¹.

The halogen atom in Ra′²¹ is preferably a fluorine atom.

Examples of the halogenated alkyl group in Ra′²¹ include a group in which a part or all of hydrogen atoms in the alkyl group in Ra′²¹ are replaced by the halogen atoms. The halogenated alkyl group is preferably a fluorinated alkyl group, and particularly preferably a perfluoroalkyl group.

In —COOR″ and —OC(═O)R″ in Ra′²¹, R″ represents a hydrogen atom, an alkyl group, a lactone-containing cyclic group, a carbonate-containing cyclic group, or a —SO₂— containing cyclic group.

The alkyl group in R″ may be linear, branched, or cyclic, and preferably has 1 to 15 carbon atoms.

When R″ is a linear or branched alkyl group, R″ preferably has 1 to 10 carbon atoms, and more preferably has 1 to 5 carbon atoms, and is particularly preferably a methyl group or an ethyl group.

When R″ is a cyclic alkyl group, R″ preferably has 3 to 15 carbon atoms, more preferably has 4 to 12 carbon atoms, and most preferably has 5 to 10 carbon atoms. Specific examples thereof include a group in which one or more hydrogen atoms are removed from a monocycloalkane that may or may not be replaced by a fluorine atom or a fluorinated alkyl group; and a group in which one or more hydrogen atoms are removed from a polycycloalkane such as a bicycloalkane, a tricycloalkane, or a tetracycloalkane. More specific examples thereof include a group in which one or more hydrogen atoms are removed from a monocycloalkane such as cyclopentane or cyclohexane; and a group in which one or more hydrogen atoms are removed from a polycycloalkane such as adamantane, norbornane, isobornane, tricyclodecane, or tetracyclododecane.

Examples of the lactone-containing cyclic group in R″ include those same as the group represented by any one of the general formulae (a2-r-1) to (a2-r-7).

The carbonate-containing cyclic group in R″ is the same as the carbonate-containing cyclic group described below, and specific examples thereof include a group represented by any one of general formulae (ax3-r-1) to (ax3-r-3).

The —SO₂— containing cyclic group in R″ is the same as the —SO₂-containing cyclic group described below, and specific examples thereof include a group represented by any one of general formulae (a5-r-1) to (a5-r-4).

The hydroxyalkyl group in Ra′²¹ preferably has 1 to 6 carbon atoms, and specific examples thereof include a group in which at least one hydrogen atom of the alkyl group in Ra′²¹ is replaced by a hydroxy group.

Among the above, it is preferable that Ra′²¹'s each independently represent a hydrogen atom or a cyano group.

In the general formulae (a2-r-2), (a2-r-3), and (a2-r-5), the alkylene group having 1 to 5 carbon atoms in A″ is preferably a linear or branched alkylene group, and examples thereof include a methylene group, an ethylene group, an n-propylene group, and an isopropylene group. When the alkylene group contains an oxygen atom or a sulfur atom, specific examples thereof include a group in which —O— or —S— is interposed at the terminal of the alkylene group or between carbon atoms of the alkylene group, and examples thereof include —O—CH₂—, —CH₂—O—CH₂—, —S—CH₂—, and —CH₂—S—CH₂—. A″ is preferably an alkylene group having 1 to 5 carbon atoms or —O—, more preferably an alkylene group having 1 to 5 carbon atoms, and most preferably a methylene group.

Specific examples of the lactone-containing cyclic group such as a group represented by any one of the general formulae (a2-r-1) to (a2-r-7) are shown below.

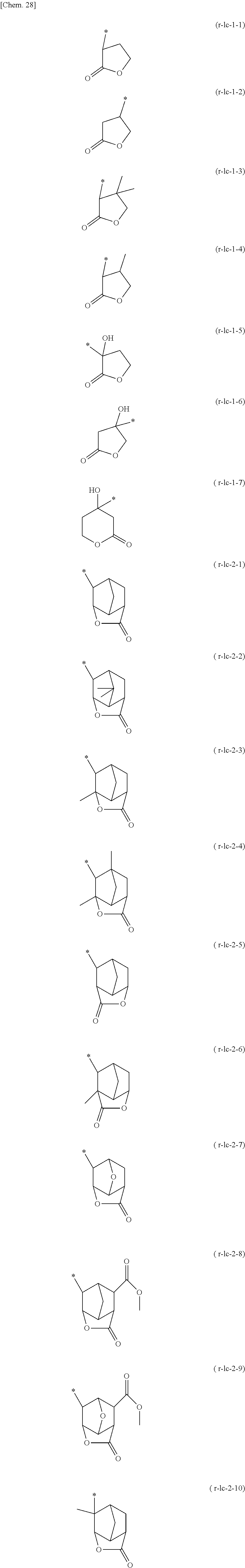

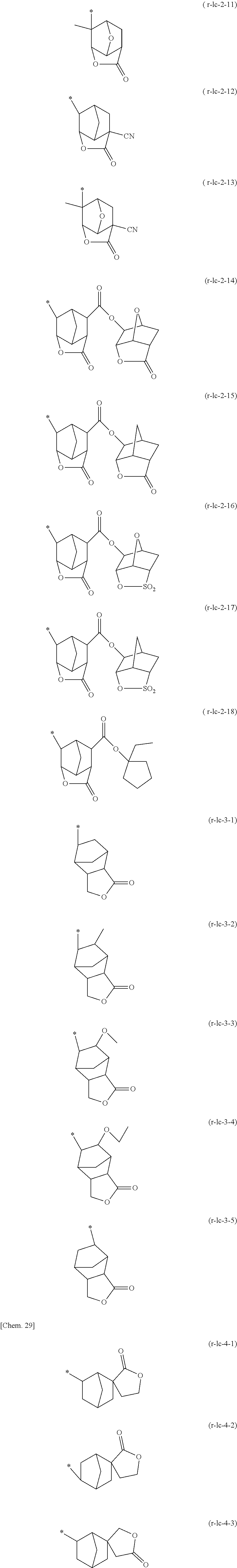

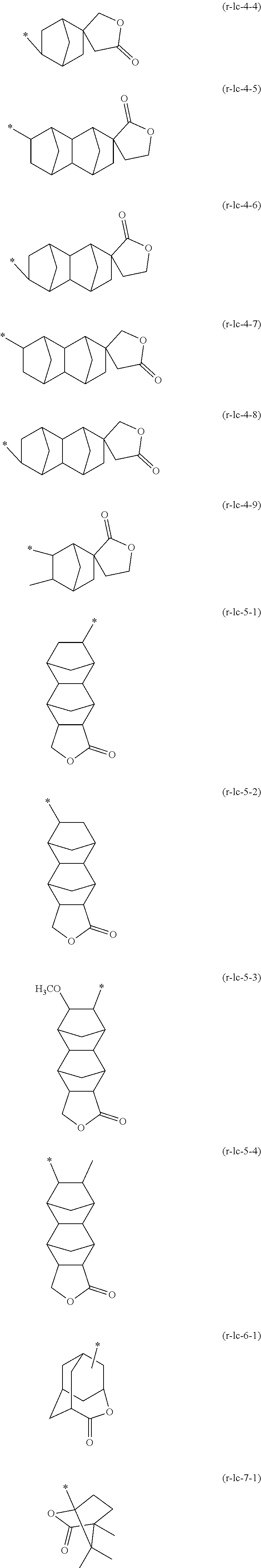

The term “—SO₂— containing cyclic group” refers to a cyclic group containing an —SO₂— containing ring in the ring skeleton thereof, and specifically, the —SO₂— containing cyclic group is a cyclic group in which a sulfur atom (S) in —SO₂— forms a part of the ring skeleton of the cyclic group. When the —SO₂— containing ring in the ring skeleton thereof is counted as a first ring, a group having only the ring is referred to as a monocyclic group, and a group further having another ring structure is referred to as a polycyclic group regardless of the structure. The —SO₂— containing cyclic group may be a monocyclic group or a polycyclic group. The —SO₂— containing cyclic group is particularly preferably an —O—SO₂— containing cyclic group in the ring skeleton thereof, that is, a cyclic group containing a sultone ring in which —O—S— in —O—SO₂— forms a part of the ring skeleton.

Specific examples of the —SO₂— containing cyclic group include a group represented by any one of the following general formulae (a5-r-1) to (a5-r-4).

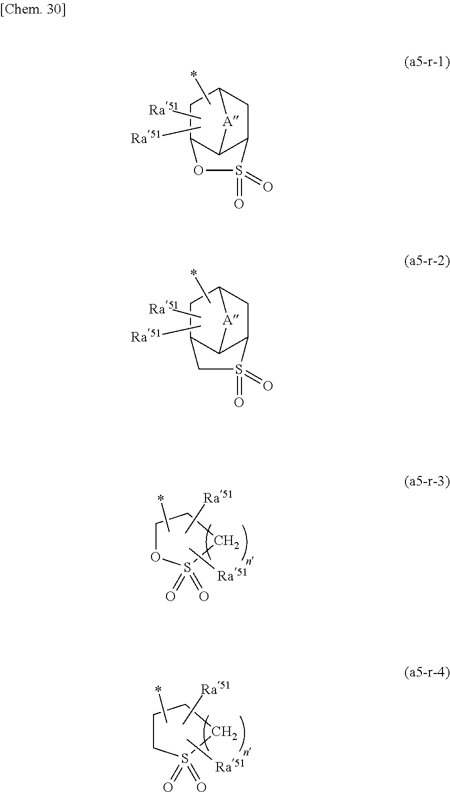

[In the formulae, Ra′⁵¹'s each independently represent a hydrogen atom, an alkyl group, an alkoxy group, a halogen atom, a halogenated alkyl group, a hydroxy group, —COOR″, —OC(═O)R″, a hydroxyalkyl group, or a cyano group; R″ represents a hydrogen atom, an alkyl group, a lactone-containing cyclic group, a carbonate-containing cyclic group, or an —SO₂— containing cyclic group; A″ represents an alkylene group having 1 to 5 carbon atoms that may contain an oxygen atom or a sulfur atom, an oxygen atom, or a sulfur atom, and n′ is an integer of 0 to 2.]

In the general formulae (a5-r-1) and (a5-r-2), A″ is the same as A″ in the general formulae (a2-r-2), (a2-r-3) and (a2-r-5).

Examples of the alkyl group, alkoxy group, halogen atom, halogenated alkyl group, —COOR″, —OC(═O)R″, and hydroxyalkyl group in Ra′⁵¹ include those same as those described in the description of Ra^{′21} in the general formulae (a2-r-1) to (a2-r-7).

Specific examples of the group represented by any one of the general formulae (a5-r-1) to (a5-r-4) are shown below. In the formula, “Ac” represents an acetyl group.

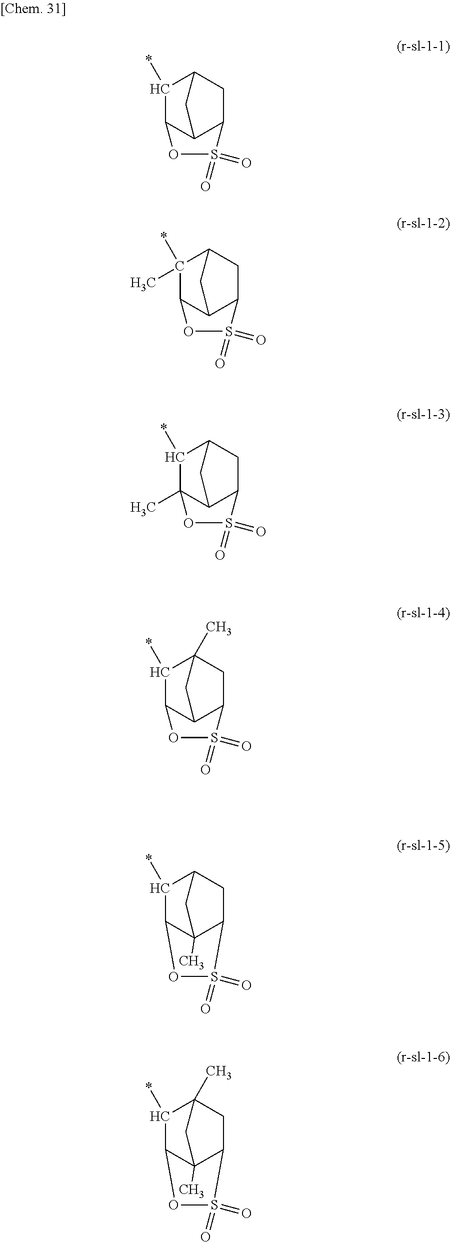

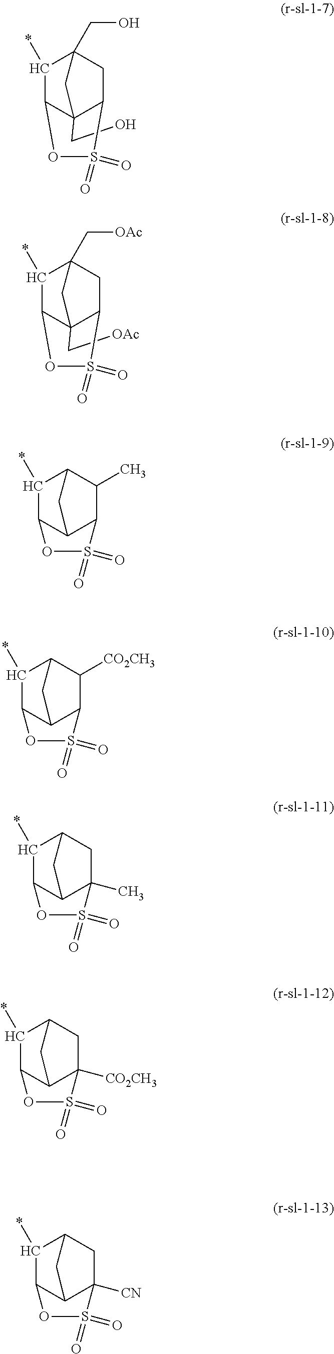

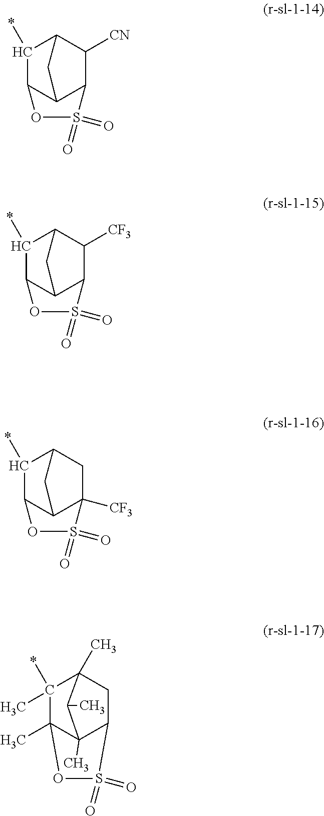

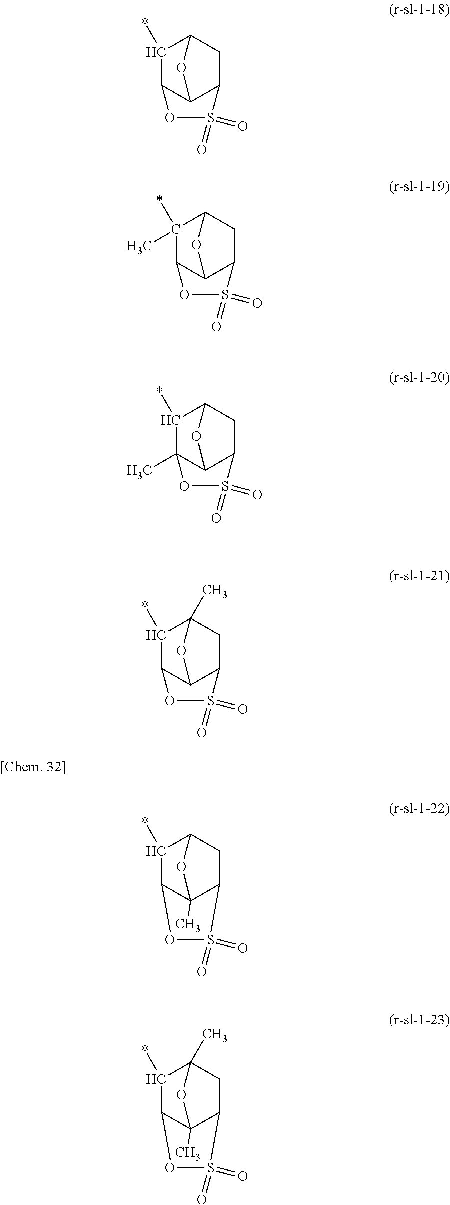

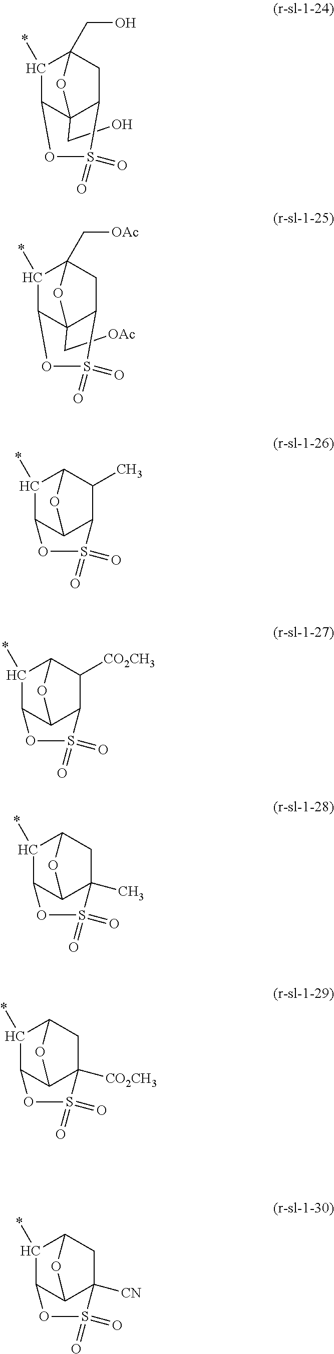

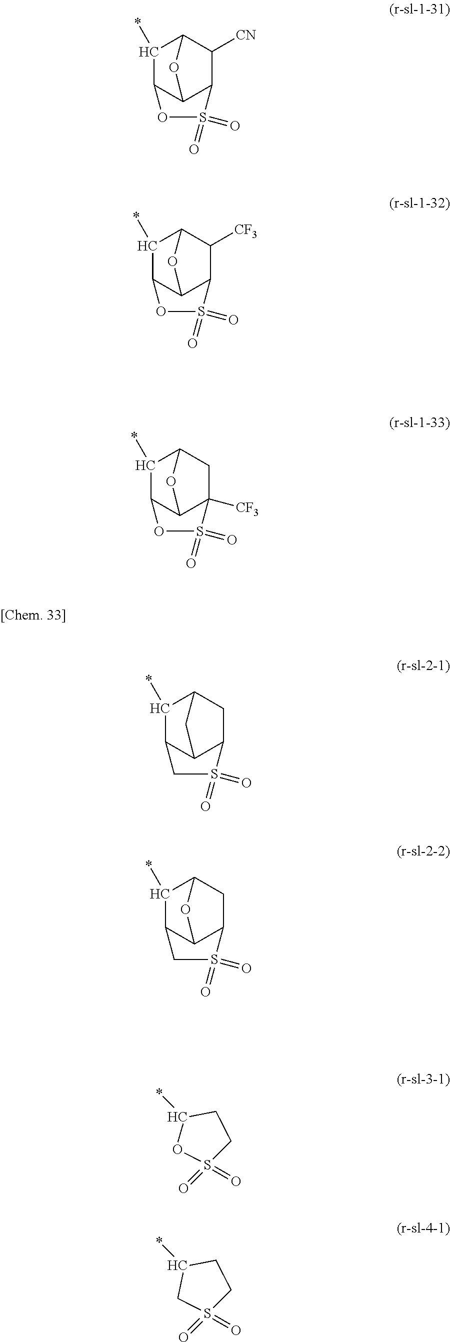

The term “carbonate-containing cyclic group” refers to a cyclic group containing a —O—C(═O)—O— containing ring (a carbonate ring) in the ring skeleton thereof. When a carbonate ring is counted as a first ring, a group having only a carbonate ring is referred to as a monocyclic group, and a group further having another ring structure is referred to as a polycyclic group regardless of the structure. The carbonate-containing cyclic group may be a monocyclic group or a polycyclic group.

The carbonate ring-containing cyclic group is not particularly limited, and any group can be used. Specific examples thereof include a group represented by any one of the following general formulae (ax3-r-1) to (ax-r-3).

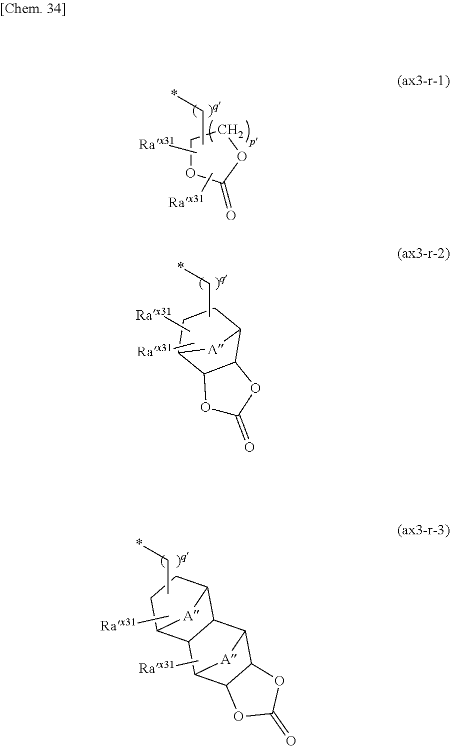

[In the formulae, Ra′^{x31}'s each independently represent a hydrogen atom, an alkyl group, an alkoxy group, a halogen atom, a halogenated alkyl group, a hydroxy group, —COOR″, —OC(═O)R″, a hydroxyalkyl group, or a cyano group; R″ represents a hydrogen atom, an alkyl group, a lactone-containing cyclic group, a carbonate-containing cyclic group, or an —SO₂— containing cyclic group; A″ represents an alkylene group having 1 to 5 carbon atoms that may contain an oxygen atom or a sulfur atom, an oxygen atom, or a sulfur atom, p′ is an integer of 0 to 3, and q′ is 0 or 1.]

In the general formulae (ax3-r-2) and (ax3-r-3), A″ is the same as A″ in the general formulae (a2-r-2), (a2-r-3) and (a2-r-5).

Examples of the alkyl group, alkoxy group, halogen atom, halogenated alkyl group, —COOR″, —OC(═O)R″, and hydroxyalkyl group in Ra′³¹ include those same as those described in the description of Ra^{′21} in the general formulae (a2-r-1) to (a2-r-7).

Specific examples of the group represented by any one of the general formulae (ax3-r-1) to (ax3-r-3) are shown below.

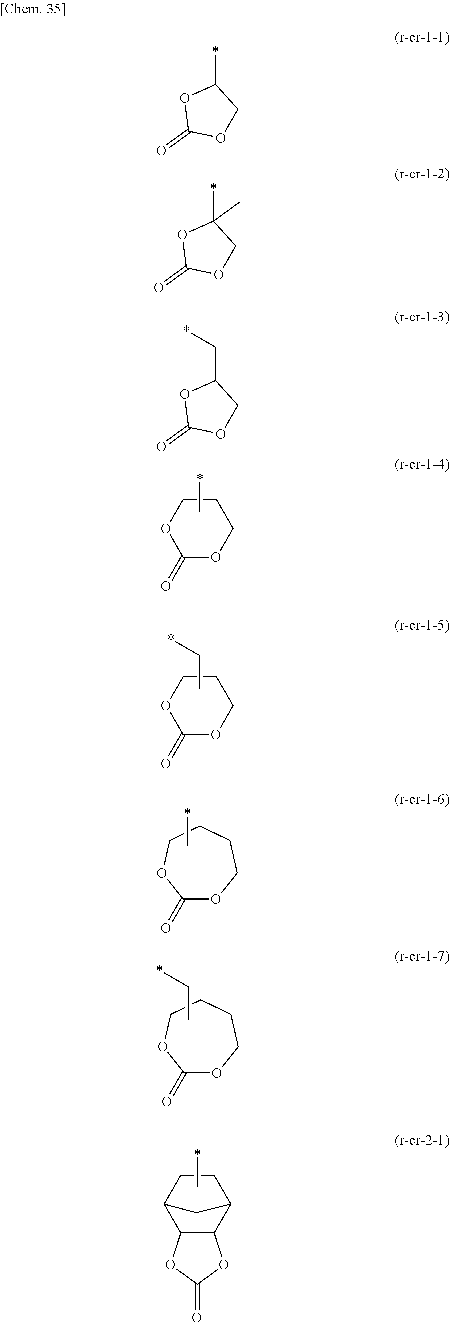

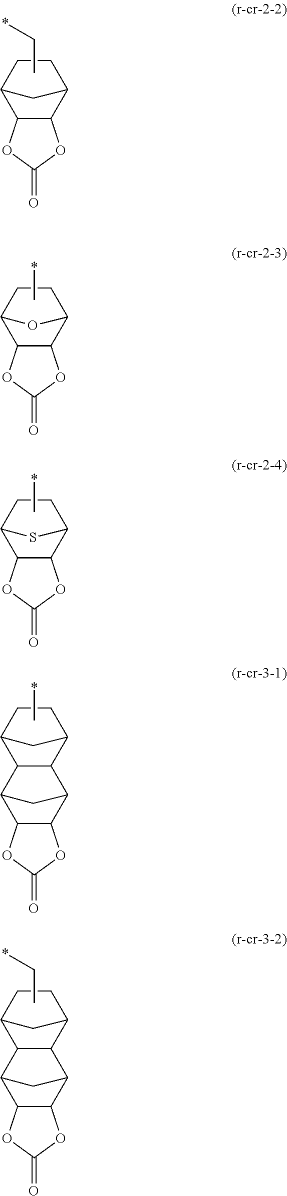

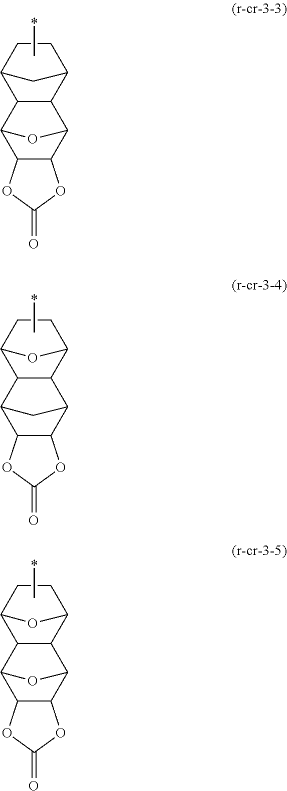

As the structural unit (a2), a structural unit derived from an acrylic ester in which a hydrogen atom bonded to a carbon atom at an α-position may be replaced by a substituent is preferred.

Such a structural unit (a2) is preferably a structural unit represented by the following general formula (a2-1).

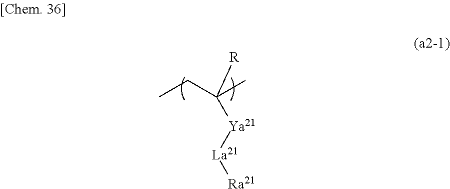

(In the formula, R represents a hydrogen atom, an alkyl group having 1 to 5 carbon atoms, or a halogenated alkyl group having 1 to 5 carbon atoms. Ya²¹ represents a single bond or a divalent linking group. La²¹ is —O—, —COO—, —CON(R′)—, —OCO—, —CONHCO— or —CONHCS—, R′ represents a hydrogen atom or a methyl group. When La²¹ is —O—, Ya²¹ does not represent —CO—. Ra²¹ is a lactone-containing cyclic group, a carbonate-containing cyclic group, or an —SO₂— containing cyclic group.]

In the formula (a2-1), R is the same as defined above. R is preferably a hydrogen atom, an alkyl group having 1 to 5 carbon atoms, or a fluorinated alkyl group having 1 to 5 carbon atoms, and from the viewpoint of industrial availability, a hydrogen atom or a methyl group is particularly preferred.

In the formula (a2-1), the divalent linking group in Ya²¹ is not particularly limited, and suitable examples thereof include a divalent hydrocarbon group that may include a substituent, and a divalent linking group containing a heteroatom.

Divalent Hydrocarbon Group that May Include Substituent:

When Ya²¹ is a divalent hydrocarbon group that may include a substituent, the hydrocarbon group may be an aliphatic hydrocarbon group or an aromatic hydrocarbon group.

### Aliphatic Hydrocarbon Group in Ya²¹

An aliphatic hydrocarbon group means a hydrocarbon group having no aromaticity. The aliphatic hydrocarbon group may be saturated or unsaturated, and is generally preferably saturated.

Examples of the aliphatic hydrocarbon group include a linear or branched aliphatic hydrocarbon group and an aliphatic hydrocarbon group containing a ring in the structure thereof.

### Linear or Branched Aliphatic Hydrocarbon Group

The linear aliphatic hydrocarbon group preferably has 1 to 10 carbon atoms, more preferably has 1 to 6 carbon atoms, still more preferably has 1 to 4 carbon atoms, and most preferably has 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group preferably has 2 to 10 carbon atoms, more preferably has 3 to 6 carbon atoms, still more preferably has 3 or 4 carbon atoms, and most preferably has 3 carbon atoms.

The branched aliphatic hydrocarbon group is preferably a branched alkylene group, and specific examples thereof include alkyl alkylene groups such as alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyl trimethylene groups such as —CH(CH₃)CH₂CH₂— and —CH₂CH(CH₃)CH₂—; and alkyl tetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

The linear or branched aliphatic hydrocarbon group may or may not include a substituent. Examples of the substituent include a fluorine atom, a fluorinated alkyl group having 1 to 5 carbon atoms and being replaced by a fluorine atom, and a carbonyl group.

### Aliphatic Hydrocarbon Group Containing Ring in Structure Thereof

Examples of the aliphatic hydrocarbon group containing a ring in the structure thereof include a cyclic aliphatic hydrocarbon group that may include a substituent containing a heteroatom in the ring structure thereof (a group in which two hydrogen atoms are removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in the middle of a linear or branched aliphatic hydrocarbon group. Examples of the linear or branched aliphatic hydrocarbon group include those same as described above.

The cyclic aliphatic hydrocarbon group preferably has 3 to 20 carbon atoms, and more preferably has 3 to 12 carbon atoms.

The cyclic aliphatic hydrocarbon group may be either a polycyclic group or a monocyclic group. The monocyclic alicyclic hydrocarbon group is preferably a group in which two hydrogen atoms are removed from a monocycloalkane. The monocycloalkane preferably has 3 to 6 carbon atoms, and specific examples thereof include cyclopentane and cyclohexane. The polycyclic alicyclic hydrocarbon group is preferably a group in which two hydrogen atoms are removed from a polycycloalkane. The polycycloalkane is preferably a group having 7 to 12 carbon atoms, and specific examples thereof include adamantane, norbornane, isobornane, tricyclodecane, and tetracyclododecane.

The cyclic aliphatic hydrocarbon group may or may not include a substituent. Examples of the substituent include an alkyl group, an alkoxy group, a halogen atom, a halogenated alkyl group, a hydroxy group, and a carbonyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group, or an ethoxy group.

The halogen atom as the substituent is preferably a fluorine atom.

Examples of the halogenated alkyl group as the substituent include a group in which a part or all of hydrogen atoms of the alkyl group are replaced by halogen atoms.

In the cyclic aliphatic hydrocarbon group, a part of carbon atoms constituting the ring structure thereof may be replaced by a substituent containing a heteroatom. The heteroatom-containing substituent is preferably —O—, —C(═O)—O—, —S—, —S(═O)₂—, or —S(═O)₂—O—.

### Aromatic Hydrocarbon Group in Ya²¹

The aromatic hydrocarbon group is a hydrocarbon group having at least one aromatic ring.

The aromatic ring is not particularly limited as long as it is of a cyclic conjugated system having 4n+2 π electrons, and may be monocyclic or polycyclic. The number of carbon atoms of the aromatic ring is preferably 5 to 30, more preferably 5 to 20, still more preferably 6 to 15, and particularly preferably 6 to 12. The number of the carbon atoms does not include the number of the carbon atoms in the substituent.

Specific examples of the aromatic ring include an aromatic hydrocarbon ring such as benzene, naphthalene, anthracene, and phenanthrene; and an aromatic heterocyclic ring in which a part of carbon atoms constituting the aromatic hydrocarbon ring is replaced by a heteroatom. Examples of the heteroatom in the aromatic heterocyclic ring include an oxygen atom, a sulfur atom, and a nitrogen atom. Specific examples of the aromatic heterocyclic ring include a pyridine ring and a thiophene ring.

Specific examples of the aromatic hydrocarbon group include a group in which two hydrogen atoms are removed from the aromatic hydrocarbon ring or aromatic heterocyclic ring (an arylene group or a heteroarylene group); a group in which two hydrogen atoms are removed from an aromatic compound containing two or more aromatic rings (for example, biphenyl or fluorene); and a group in which one hydrogen atom of a group in which one hydrogen atom is removed from the aromatic hydrocarbon ring or aromatic heterocyclic ring (an aryl group or a heteroaryl group) is replaced by an alkylene group (for example, a group in which one hydrogen atom is further removed from the aryl group in the arylalkyl group, such as a benzyl group, a phenethyl group, a 1-naphthylmethyl group, a 2-naphthylmethyl group, a 1-naphthylethyl group, or a 2-naphthylethyl group). The number of carbon atoms of the alkylene group bonded to the aryl group or the heteroaryl group is preferably 1 to 4, more preferably 1 to 2, and particularly preferably 1.

In the aromatic hydrocarbon group, a hydrogen atom contained in the aromatic hydrocarbon group may be replaced by a substituent. For example, a hydrogen atom bonded to an aromatic ring in the aromatic hydrocarbon group may be replaced by a substituent. Examples of the substituent include an alkyl group, an alkoxy group, a halogen atom, a halogenated alkyl group, and a hydroxy group.

The alkyl group as the substituent is preferably an alkyl group having 1 to 5 carbon atoms, and more preferably a methyl group, an ethyl group, a propyl group, an n-butyl group, or a tert-butyl group.

Examples of the alkoxy group, halogen atom, and halogenated alkyl group as the substituent include those exemplified as the substituent for replacing the hydrogen atom in the cyclic aliphatic hydrocarbon group.

### Divalent Linking Group Containing Heteroatom:

When Ya²¹ is a divalent linking group containing a heteroatom, preferred examples of the linking group include —O—, —C(═O)—O—, —O—C(═O)—, —C(═O)—, —O—C(═O)—O—, —C(═O)—NH—, —NH—, —NH—C(═NH)— (H may be replaced by a substituent such as an alkyl group or an acyl group), —S—, —S(═O)₂—, —S(═O)₂—O—, and a group represented by a general formula —Y²¹—O—Y²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²— [in the formulae, Y²¹ and Y²² each independently represent a divalent hydrocarbon group that may include a substituent, O is an oxygen atom, and m″ is an integer of 0 to 31.

When the divalent linking group containing a heteroatom is —C(═O)—NH—, —CO)—NH—CO)—, —NH—, or —NH—C(═NH)—, H thereof may be replaced by a substituent such as an alkyl group or an acyl group. The substituent (an alkyl group, an acyl group, or the like) preferably has 1 to 10 carbon atoms, more preferably has 1 to 8 carbon atoms, and particularly preferably has 1 to 5 carbon atoms.

In the general formulae —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²—, Y²¹ and Y²² each independently represent a divalent hydrocarbon group that may include a substituent. Examples of the divalent hydrocarbon group include those same as those described above for the divalent linking group in Ya²¹ (the divalent hydrocarbon group that may include a substituent).

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group, and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by the formula —[Y²¹—C(═O)—O]_{m″}—Y²²—, m″ is an integer of 0 to 3, preferably an integer of 0 to 2, more preferably 0 or 1, and particularly preferably 1. That is, the group represented by the formula —[Y²¹—C(═O)—O]_{m″}—Y²²—, a group represented by the formula —Y²¹—C(═O)—O—Y²²— is particularly preferred. Among them, a group represented by the formula —(CH₂)_{a′}—C(═O)—O—(CH₂)_{b′}— is preferred. In the formula, the symbol a′ is an integer of 1 to 10, preferably an integer of 1 to 8, more preferably an integer of 1 to 5, still more preferably 1 or 2, and most preferably 1. The symbol b′ is an integer of 1 to 10, preferably an integer of 1 to 8, more preferably an integer of 1 to 5, still more preferably 1 or 2, and most preferably 1.

Among them, Ya²¹ is preferably a single bond, an ester bond [—C(═O)—O—], an ether bond (—O—), a linear or branched alkylene group, or a combination thereof.

In the formula (a2-1), Ra²¹ represents a lactone-containing cyclic group, a —SO₂— containing cyclic group, or a carbonate-containing cyclic group.

Suitable examples of the lactone-containing cyclic group, the —SO₂— containing cyclic group, and the carbonate-containing cyclic group in Ra²¹ include a group represented by any one of the general formulae (a2-r-1) to (a2-r-7), a group represented by any one of general formulae (a5-r-1) to (a5-r-4), and a group represented by any one of general formulae (ax3-r-1) to (ax3-r-3).

Among them, a lactone-containing cyclic group or an —SO₂— containing cyclic group is preferred, a group represented by any one of the general formulae (a2-r-1), (a2-r-2), (a2-r-6), and (a5-r-1) is more preferred, and a group represented by any one of the general formulae (a2-r-2) and (a5-r-1) is still more preferred. Specifically, any group represented by any one of the chemical formulae (r-lc-1-1) to (r-lc-1-7), (r-lc-2-1) to (r-lc-2-18), (r-lc-6-1), (r-sl-1-1), and (r-sl-1-18) is preferred, any group represented by any one of the chemical formulae (r-lc-2-1) to (r-lc-2-18), and (r-sl-1-1) is more preferred, and any group represented by any one of the chemical formulae (r-lc-2-1), (r-lc-2-12), and (r-sl-1-1) is still more preferred.

The structural unit (a2) contained in the component (A1) may be used alone or in combination of two or more kinds thereof.

When the component (A1) contains the structural unit (a2), a proportion of the structural unit (a2) is preferably 5 mol % to 60 mol %, more preferably 10 mol % to 60 mol %, still more preferably 20 mol % to 60 mol %, and particularly preferably 30 mol % to 60 mol %, with respect to a total (100 mol %) of all structural units constituting the component (A1).

When the proportion of the structural unit (a2) is equal to or larger than a preferred lower limit value, the effects of containing the structural unit (a2) can be sufficiently obtained due to the above-described effects. When the proportion of the structural unit (a2) is equal to or less than an upper limit value, a balance with other structural units can be achieved, and various lithography properties become excellent.

### Regarding Structural Unit (a3):

The component (A1) may further contain, in addition to the structural unit (a1), a structural unit (a3) containing a polar group-containing aliphatic hydrocarbon group (provided that one corresponding to the structural unit (a1) or the structural unit (a2) is excluded). When the component (A1) contains the structural unit (a3), hydrophilicity of the component (A) is increased, which contributes to improvement of the resolution. The acid diffusion length can be appropriately adjusted.

Examples of the polar group include a hydroxy group, a cyano group, a carboxy group, and a hydroxyalkyl group in which a part of hydrogen atoms of an alkyl group is replaced by a fluorine atom, and a hydroxy group is particularly preferred.

Examples of the aliphatic hydrocarbon group include a linear or branched hydrocarbon group having 1 to 10 carbon atoms (preferably an alkylene group) and a cyclic aliphatic hydrocarbon group (a cyclic group). The cyclic group may be a monocyclic group or a polycyclic group, and for example, can be appropriately selected from a number of groups proposed for a resist composition for ArF excimer lasers.

When the cyclic group is a monocyclic group, the number of carbon atoms thereof is more preferably 3 to 10. Among them, a structural unit derived from an acrylic ester containing an aliphatic monocyclic group that contains a hydroxy group, a cyano group, a carboxy group, or a hydroxyalkyl group in which a part of hydrogen atoms of the alkyl group is replaced by a fluorine atom is more preferred. Examples of the monocyclic group include a group in which two or more hydrogen atoms are removed from a monocycloalkane. Specific examples thereof include a group in which two or more hydrogen atoms are removed from a monocycloalkane such as cyclopentane, cyclohexane, or cyclooctane. Among the monocyclic group, a group in which two or more hydrogen atoms are removed from cyclopentane and a group in which two or more hydrogen atoms are removed from cyclohexane are industrially preferred.

When the cyclic group is a polycyclic group, the number of carbon atoms of the polycyclic group is more preferably 7 to 30. Among them, a structural unit derived from an acrylic ester containing an aliphatic polycyclic group that contains a hydroxy group, a cyano group, a carboxy group, or a hydroxyalkyl group in which a part of hydrogen atoms of the alkyl group is replaced by a fluorine atom is more preferred. Examples of the polycyclic group include a group in which two or more hydrogen atoms are removed from a bicycloalkane, tricycloalkane, tetracycloalkane, or the like. Specific examples thereof include a group in which two or more hydrogen atoms are removed from a polycycloalkane such as adamantane, norbornane, isobornane, tricyclodecane, or tetracyclododecane. Among the polycyclic groups, a group in which two or more hydrogen atoms are removed from adamantane, a group in which two or more hydrogen atoms are removed from norbornane, and a group in which two or more hydrogen atoms are removed from tetracyclododecane are industrially preferred.

There are no particular limitations on the structural unit (a3), and any structural unit can be used as long as it contains a polar group-containing aliphatic hydrocarbon group.

As the structural unit (a3), a structural unit derived from an acrylic ester in which the hydrogen atom bonded to the carbon atom on the α-position may be replaced by a substituent and containing a polar group-containing aliphatic hydrocarbon group is preferred.

When the hydrocarbon group in the polar group-containing aliphatic hydrocarbon group is a linear or branched hydrocarbon group having 1 to 10 carbon atoms, the structural unit (a3) is preferably a structural unit derived from a hydroxy ethyl ester of acrylic acid.

When the hydrocarbon group in the polar group-containing aliphatic hydrocarbon group is a polycyclic group, preferred examples of the structural unit (a3) include a structural unit represented by the following formula (a3-1), a structural unit represented by the following formula (a3-2), and a structural unit represented by the following formula (a3-3). When the hydrocarbon group in the polar group-containing aliphatic hydrocarbon group is a monocyclic group, preferred examples of the structural unit (a3) include a structural unit represented by the following formula (a3-4).

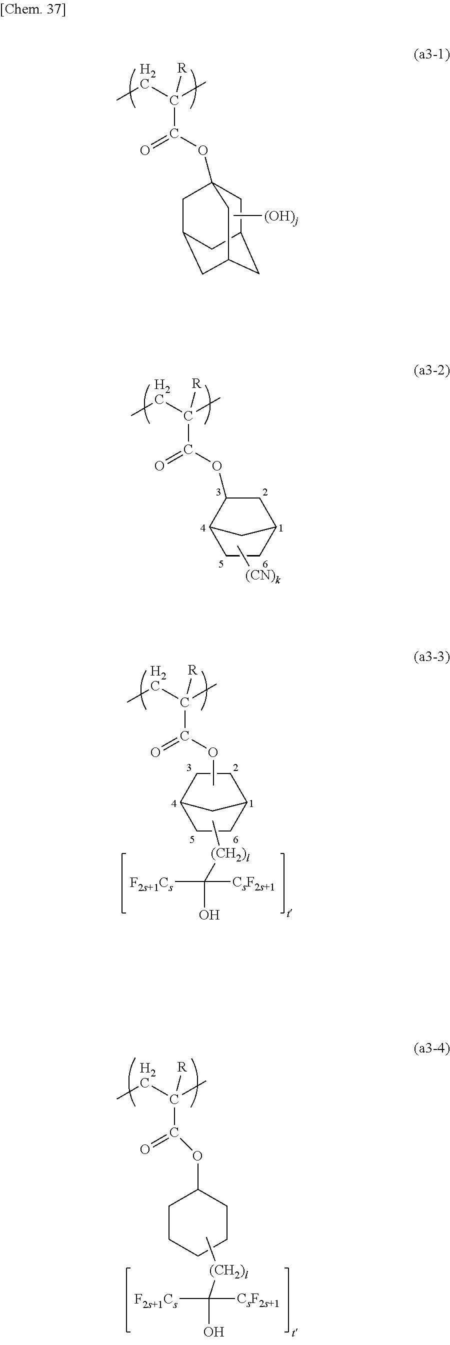

[In the formula, R is the same as above, j is an integer of 1 to 3, k is an integer of 1 to 3, t′ is an integer of 1 to 3, l is an integer of 0 to 5, and s is an integer of 1 to 3.]

In the formula (a3-1), j is preferably 1 or 2, and more preferably 1. When j is 2, the hydroxy groups are preferably bonded to the 3-position and 5-position of the adamantyl group. When j is 1, the hydroxy group is preferably bonded to the 3-position of the adamantyl group.

It is preferable that j be 1, and it is particularly preferable that the hydroxy group be bonded to the 3-position of the adamantyl group.

In the formula (a3-2), k is preferably 1. The cyano group is preferably bonded to the 5-position or 6-position of a norbornyl group.

In the formula (a3-3), t′ is preferably 1. The symbol 1 is preferably 1. The symbol s is preferably 1. A 2-norbornyl group or a 3-norbornyl group is preferably bonded to the terminal of the carboxy group of acrylic acid. The fluorinated alkyl alcohol is preferably bonded to the 5-position or 6-position of the norbornyl group.

In the formula (a3-4), t′ is preferably 1 or 2. The symbol 1 is preferably 0 or 1. The symbol s is preferably 1. The fluorinated alkyl alcohol is preferably bonded to the 3-position or 5-position of the cyclohexyl group.

The structural unit (a3) contained in the component (A1) may be used alone or in combination of two or more kinds thereof.

When the component (A1) contains the structural unit (a3), a proportion of the structural unit (a3) is preferably 1 mol % to 30 mol %, more preferably 2 mol % to 25 mol %, and still more preferably 5 mol % to 20 mol %, with respect to the total (100 mol %) of all structural units constituting the component (A1).

When the proportion of the structural unit (a3) is equal to or more than the preferred lower limit value, the effects of containing the structural unit (a3) can be sufficiently obtained due to the above-described effects. When the proportion of the structural unit (a3) is equal to or less than the preferred upper limit value, a balance with other structural units can be achieved, and various lithography properties become excellent.

### Regarding Structural Unit (a4):

The component (A1) may further contain, in addition to the structural unit (a1), a structural unit (a4) containing an acid non-dissociable aliphatic cyclic group.

When the component (A1) contains the structural unit (a4), the dry etching resistance of the resist pattern to be formed is improved. In addition, the hydrophobicity of the component (A) is increased. The improvement in hydrophobicity contributes to improvements in the resolution, resist pattern shape, and the like, particularly in the case of a solvent developing process.

The “acid non-dissociable cyclic group” in the structural unit (a4) is a cyclic group that, when acid is generated in the resist composition upon exposure (for example, when acid is generated from a structural unit that generates acid upon exposure or from the component (B)), does not dissociate even when acted by the acid, and remains as is within the structural unit.

As the structural unit (a4), for example, a structural unit derived from an acrylic ester that contains an acid non-dissociable aliphatic cyclic group is preferred. As the cyclic group, many known related-art cyclic groups to be used in resin components of resist compositions for ArF excimer lasers and KrF excimer lasers (preferably for ArF excimer lasers) can be used.

From the viewpoint of industrial availability, the cyclic group is preferably at least one selected from the group consisting of a tricyclodecyl group, an adamantyl group, a tetracyclododecyl group, an isobornyl group, and a norbornyl group. The polycyclic group may include a linear or branched alkyl group having 1 to 5 carbon atoms as a substituent.

Specific examples of the structural unit (a4) include a structural unit represented by any one of the following general formulae (a4-1) to (a4-7).

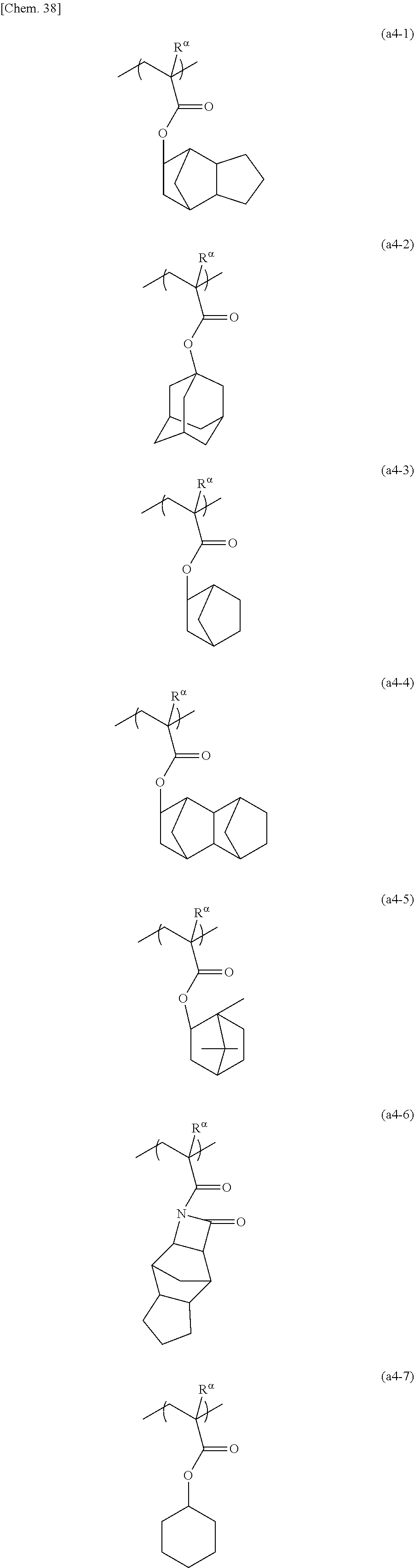

[In the formula, R^{α} is the same as defined above.]

The structural unit (a4) contained in the component (A1) may be used alone or in combination of two or more kinds thereof.

When the component (A1) contains the structural unit (a4), a proportion of the structural unit (a4) is preferably 1 mol % to 40 mol %, and more preferably 5 mol % to 20 mol %, with respect to the total (100 mol %) of all structural units constituting the component (A1).

When the proportion of the structural unit (a4) is equal to or larger than the preferred lower limit value, the effect of containing the structural unit (a4) can be sufficiently obtained. When the proportion of the structural unit (a4) is equal to or less than the preferred upper limit value, a balance with other structural units can be easily achieved.

### Regarding Structural Unit (St):

The structural unit (st) is a structural unit derived from styrene or a styrene derivative. The term “structural unit derived from styrene” means a structural unit formed by cleavage of an ethylenic double bond of styrene. The term “structural unit derived from a styrene derivative” means a structural unit formed by cleavage of an ethylenic double bond of a styrene derivative.

The term “styrene derivative” means a compound in which at least a part of hydrogen atoms of styrene is replaced by a substituent. Examples of the styrene derivative include those in which the hydrogen atom of styrene on the α-position is replaced by a substituent, those in which one or more hydrogen atoms of a benzene ring of styrene are replaced by a substituent, and those in which the hydrogen atom of styrene on the α-position and one or more hydrogen atoms of the benzene ring are replaced by a substituent.

Examples of the substituent for replacing the hydrogen atom of styrene at the α-position include an alkyl group having 1 to 5 carbon atoms and a halogenated alkyl group having 1 to 5 carbon atoms.

The alkyl group having 1 to 5 carbon atoms is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group having 1 to 5 carbon atoms is a group in which a part or all of hydrogen atoms of the alkyl group having 1 to 5 carbon atoms are replaced by halogen atoms. The halogen atom is particularly preferably a fluorine atom.

The substituent for replacing the hydrogen atom of styrene at the α-position is preferably an alkyl group having 1 to 5 carbon atoms or a fluorinated alkyl group having 1 to 5 carbon atoms, more preferably an alkyl group having 1 to 3 carbon atoms or a fluorinated alkyl group having 1 to 3 carbon atoms, and still more preferably a methyl group from the viewpoint of industrial availability.

Examples of the substituent for replacing the hydrogen atom of the benzene ring of styrene include an alkyl group, an alkoxy group, a halogen atom, and a halogenated alkyl group.

The alkyl group as the substituent is preferably an alkyl group having 1 to 5 carbon atoms, and more preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and still more preferably a methoxy group, or an ethoxy group.

The halogen atom as the substituent is preferably a fluorine atom.

Examples of the halogenated alkyl group as the substituent include a group in which a part or all of hydrogen atoms of the alkyl group are replaced by halogen atoms.

The substituent for replacing the hydrogen atom of the benzene ring of styrene is preferably an alkyl group having 1 to 5 carbon atoms, more preferably a methyl group or an ethyl group, and still more preferably a methyl group.

The structural unit (st) is preferably a structural unit derived from styrene or a structural unit derived from a styrene derivative in which the hydrogen atom of styrene at the α-position is replaced by an alkyl group having 1 to 5 carbon atoms or a halogenated alkyl group having 1 to 5 carbon atoms, more preferably a structural unit derived from styrene or a structural unit derived from a styrene derivative in which the hydrogen atom of styrene at the α-position is replaced by a methyl group, and still more preferably a structural unit derived from styrene.

The structural unit (st) contained in the component (A1) may be used alone or in combination of two or more kinds thereof.

When the component (A1) contains the structural unit (st), a proportion of the structural unit (st) is preferably 1 mol % to 30 mol %, and more preferably 3 mol % to 20 mol %, with respect to the total (100 mol %) of all structural units constituting the component (A1).

The component (A1) contained in the resist composition may be used alone or in combination of two or more kinds thereof.

In the resist composition of the present embodiment, examples of the component (A1) include a high molecular weight compound including a repeating structure of the structural unit (a1), and preferably include a high molecular weight compound including a repeating structure of the structural unit (a1) and the structural unit (a2).

Among the above, suitable examples of the component (A1) include a high molecular weight compound including a repeating structure of the structural unit (a1) and the structural unit (a2); and a high molecular weight compound including a repeating structure of the structural unit (a1), the structural unit (a2), and the structural unit (a3).

In a high molecular weight compound including a repeating structure of the structural unit (a1) and the structural unit (a2), a proportion of the structural unit (a1) is preferably 10 mol % to 90 mol %, more preferably 20 mol % to 80 mol %, still more preferably 30 mol % to 70 mol %, and particularly preferably 40 mol % to 70 mol %, with respect to the total (100 mol %) of all structural units constituting the high molecular weight compound.

A proportion of the structural unit (a2) in the high molecular weight compound is preferably 10 mol % to 90 mol %, more preferably 20 mol % to 80 mol %, still more preferably 30 mol % to 70 mol %, and particularly preferably 30 mol % to 60 mol %, with respect to the total (100 mol %) of all structural units constituting the high molecular weight compound.

In a high molecular weight compound including a repeating structure of the structural unit (a1), the structural unit (a2), and the structural unit (a3), a proportion of the structural unit (a1) is preferably 20 mol % to 80 mol %, more preferably 30 mol % to 70 mol %, still more preferably 40 mol % to 60 mol %, and particularly preferably 45 mol % to 55 mol %, with respect to the total (100 mol %) of all structural units constituting the high molecular weight compound.

A proportion of the structural unit (a2) in the high molecular weight compound is preferably 10 mol % to 70 mol %, more preferably 20 mol % to 60 mol %, still more preferably 30 mol % to 50 mol %, and particularly preferably 35 mol % to 45 mol %, with respect to the total (100 mol %) of all structural units constituting the high molecular weight compound.

A proportion of the structural unit (a3) in the high molecular weight compound is preferably 1 mol % to 30 mol %, more preferably 5 mol % to 25 mol %, still more preferably 5 mol % to 20 mol %, and particularly preferably 5 mol % to 15 mol %, with respect to the total (100 mol %) of all structural units constituting the high molecular weight compound.

A molar ratio of the structural unit (a1) to the structural unit (a2) (structural unit (a1):structural unit (a2)) in the high molecular weight compound is preferably 2:8 to 8:2, more preferably 3:7 to 7:3, and still more preferably 4:6 to 6:4.

Such a component (A1) can be produced by dissolving a monomer from which each structural unit is derived in a polymerization solvent, and then adding a radical polymerization initiator such as azobisisobutyronitrile (AIBN) or dimethyl azobisisobutyrate (for example, V-601) thereto to perform polymerization.

Alternatively, such a component (A1) can be produced by dissolving a monomer from which the structural unit (a1) is derived and, if necessary, a monomer from which a structural unit other than the structural unit (a1) (for example, the structural unit (a2)) is derived in a polymerization solvent, and adding the radical polymerization initiator as described above thereto to perform polymerization.

During the polymerization, a chain transfer agent such as HS—CH₂—CH₂—CH₂—C(CF₃)₂—OH may be used in combination to introduce a —C(CF₃)₂—OH group into the terminal. As described above, a copolymer into which a hydroxyalkyl group in which a part of hydrogen atoms of an alkyl group is replaced by a fluorine atom is introduced is effective in reducing development defects and reducing line edge roughness (LER: uneven unevenness of a line side wall).

A weight average molecular weight (Mw) (in terms of polystyrene determined by gel permeation chromatography (GPC)) of the component (A1) is not particularly limited, and is preferably 1,000 to 50,000, more preferably 2,000 to 30,000, and still more preferably 3,000 to 20,000.

When the Mw of the component (A1) is equal to or less than the preferred upper limit value of the range, the component (A1) has sufficient solubility in a resist solvent for use as a resist, and when the Mw of the component (A1) is equal to or larger than the preferred lower limit value of the range, the dry etching resistance and cross-sectional shape of the resist pattern are improved.

A dispersity (Mw/Mn) of the component (A1) is not particularly limited, and is preferably 1.0 to 4.0, more preferably 1.0 to 3.0, and particularly preferably 1.0 to 2.0. Mn indicates a number average molecular weight.

### Regarding Component (A2)

The resist composition of the present embodiment may also use, as the component (A), a base material component (hereafter, referred to as “component (A2)”) that does not fall under the category of the component (A1) and whose solubility with respect to the liquid developer changes by an action of an acid.

The component (A2) is not particularly limited, and may be any selected from many known related-art components as a base material component for a chemically amplified resist composition.

As the component (A2), one kind of high molecular weight compound or low molecular weight compound may be used alone, or two or more kinds thereof may be used in combination.

A proportion of the component (A1) in the component (A) is preferably 25 mass % or more, more preferably 50 mass % or more, still more preferably 75 mass % or more, and may be 100 mass %, with respect to the total mass of the component (A). When the proportion is 25 mass % or more, a resist pattern excellent in various lithography properties such as a high sensitivity, resolution, and roughness is easily formed.

A content of the component (A) in the resist composition of the present embodiment may be adjusted depending on a thickness of a resist film to be formed.

### <Acid Generating Agent Component (B)>

The resist composition of the present embodiment further contains, in addition to the component (A), an acid generating agent component (B) that generates an acid upon exposure.

The component (B) is not particularly limited, and those proposed as an acid generating agent for a chemically amplified resist composition can be used.

Examples of such an acid generating agent include various acid generating agents such as onium salt acid generating agents such as an iodonium salt and a sulfonium salt; oxime sulfonate acid generating agents; diazomethane acid generating agents such as bisalkyl or bisarylsulfonyl diazomethanes and poly(bissulfonyl) diamethanes; nitrobenzyl sulfonate acid generating agents; iminoosulfonate acid generating agents; and disulfone acid generating agents.

Examples of the onium salt acid generating agent include a compound represented by the following general formula (b-1) (hereinafter, also referred to as “component (b-1)”), a compound represented by the following general formula (b-2) (hereinafter, also referred to as “component (b-2)”), and a compound represented by the following general formula (b-3) (hereinafter, also referred to as “component (b-3)”).

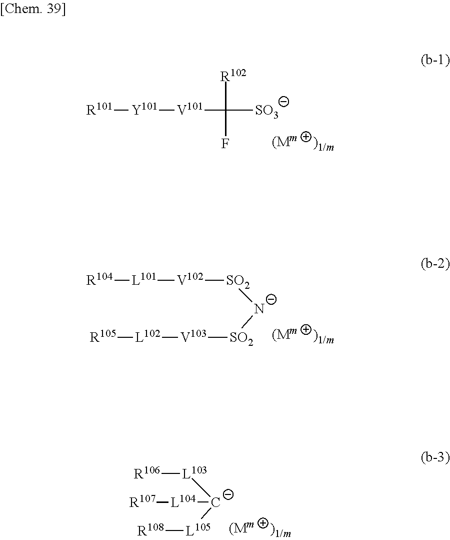

[In the formula, R¹⁰¹ and R¹⁰⁴ to R¹⁰⁸ each independently represent a cyclic group that may include a substituent, a chain alkyl group that may include a substituent, or a chain alkenyl group that may include a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a single bond or a divalent linking group containing an oxygen atom. V¹⁰¹ to V¹⁰³ each independently represent a single bond, an alkylene group, or a fluorinated alkylene group. L¹⁰¹ to L¹⁰² each independently represent a single bond or an oxygen atom. L¹⁰³ to L¹⁰⁵ each independently represent a single bond, —CO— or —SO₂—. The symbol m is an integer of 1 or more, and M^{m+} is an m-valent onium cation.]

### {Anion Moiety}

Anion in Component (b-1)

In the formula (b-1), R¹⁰¹ represents a cyclic group that may include a substituent, a chain alkyl group that may include a substituent, or a chain alkenyl group that may include a substituent.

Cyclic Group that May Include Substituent:

The cyclic group is preferably a cyclic hydrocarbon group, and the cyclic hydrocarbon group may be an aromatic hydrocarbon group or an aliphatic hydrocarbon group. An aliphatic hydrocarbon group means a hydrocarbon group having no aromaticity. The aliphatic hydrocarbon group may be saturated or unsaturated, and is generally preferably saturated.

The aromatic hydrocarbon group in R¹⁰¹ is a hydrocarbon group having an aromatic ring. The number of carbon atoms of the aromatic hydrocarbon group is preferably 3 to 30, more preferably 5 to 30, still more preferably 5 to 20, particularly preferably 6 to 15, and most preferably 6 to 10. The number of the carbon atoms does not include the number of the carbon atoms in the substituent.

Specific examples of the aromatic ring contained in the aromatic hydrocarbon group in R¹⁰¹ include benzene, fluorene, naphthalene, anthracene, phenanthrene, biphenyl, and an aromatic heterocyclic ring in which a part of carbon atoms constituting the aromatic ring is replaced by a heteroatom. Examples of the heteroatom in the aromatic heterocyclic ring include an oxygen atom, a sulfur atom, and a nitrogen atom.

Specific examples of the aromatic hydrocarbon group in R¹⁰¹ include a group in which one hydrogen atom is removed from the aromatic ring (an aryl group: for example, a phenyl group or a naphthyl group), and a group in which one hydrogen atom of the aromatic ring is replaced by an alkylene group (for example, an arylalkyl group such as a benzyl group, a phenethyl group, a 1-naphthyl methyl group, a 2-naphthyl methyl group, a 1-naphthyl ethyl group, or a 2-naphthyl ethyl group). The number of carbon atoms of the alkylene group (an alkyl chain in the arylalkyl group) is preferably 1 to 4, more preferably 1 to 2, and particularly preferably 1.

The cyclic aliphatic hydrocarbon group in R¹⁰¹ includes an aliphatic hydrocarbon group containing a ring in the structure thereof.

Examples of the aliphatic hydrocarbon group containing a ring in the structure thereof include an alicyclic hydrocarbon group (a group in which one hydrogen atom is removed from an aliphatic hydrocarbon ring), a group in which an alicyclic hydrocarbon group is bonded to the terminal of a linear or branched aliphatic hydrocarbon group, and a group in which an alicyclic hydrocarbon group is interposed in the middle of a linear or branched aliphatic hydrocarbon group.

The alicyclic hydrocarbon group preferably has 3 to 20 carbon atoms, and more preferably has 3 to 12 carbon atoms.

The alicyclic hydrocarbon group may be a polycyclic group or a monocyclic group. The monocyclic alicyclic hydrocarbon group is preferably a group in which one or more hydrogen atoms are removed from a monocycloalkane. The monocycloalkane preferably has 3 to 6 carbon atoms, and specific examples thereof include cyclopentane and cyclohexane. The polycyclic alicyclic hydrocarbon group is preferably a group in which one or more hydrogen atoms are removed from a polycycloalkane, and the polycycloalkane preferably has 7 to 30 carbon atoms. Among them, the polycycloalkane is more preferably a polycycloalkane including a crosslinked ring polycyclic skeleton, such as adamantane, norbornane, isobornane, tricyclodecane, or tetracyclododecane; or a polycycloalkane including a fused ring polycyclic skeleton, such as a cyclic group including a steroid skeleton.

Among them, as the cyclic aliphatic hydrocarbon group in R¹⁰¹, a group in which one or more hydrogen atoms are removed from a monocycloalkane or a polycycloalkane is preferred, a group in which one hydrogen atom is removed from a polycycloalkane is more preferred, an adamantyl group or a norbornyl group is still more preferred, and an adamantyl group is particularly preferred.

The number of carbon atoms of the linear aliphatic hydrocarbon group which may be bonded to the alicyclic hydrocarbon group is preferably 1 to 10, more preferably 1 to 6, still more preferably 1 to 4, and most preferably 1 to 3. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The number of carbon atoms of the branched aliphatic hydrocarbon group which may be bonded to the alicyclic hydrocarbon group is preferably 2 to 10, more preferably 3 to 6, still more preferably 3 or 4, and most preferably 3. The branched aliphatic hydrocarbon group is preferably a branched alkylene group, and specific examples thereof include alkyl alkylene groups such as alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyl trimethylene groups such as —CH(CH₃)CH₂CH₂— and —CH₂CH(CH₃)CH₂—; and alkyl tetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

The cyclic hydrocarbon group in R¹⁰¹ may contain a heteroatom, similar to a heterocyclic ring. Specific examples thereof include a lactone-containing cyclic group represented by any one of the general formulae (a2-r-1) to (a2-r-7), an —SO₂— containing cyclic group represented by any one of the general formulae (a5-r-1) to (a5-r-4), and a heterocyclic group represented by any one of the following chemical formulae (r-hr-1) to (r-hr-16). In the formula, * represents a bond to be bonded to Y¹⁰¹ in the formula (b-1).

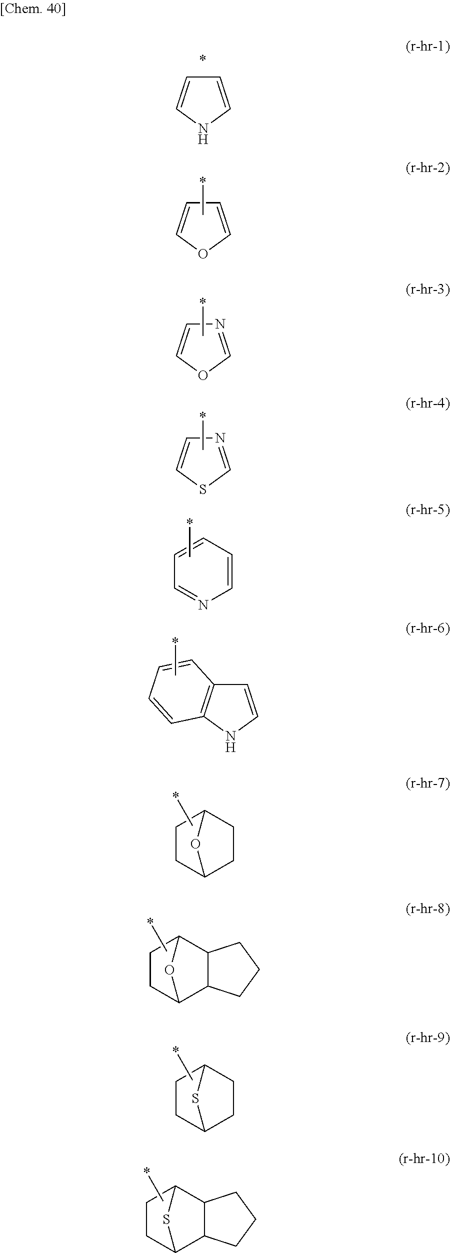

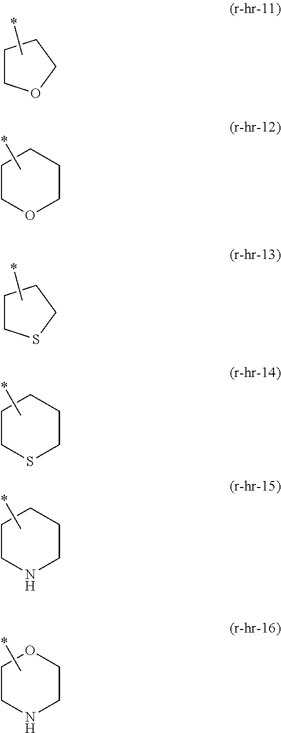

Examples of the substituent in the cyclic group of R¹⁰¹ include an alkyl group, an alkoxy group, a halogen atom, a halogenated alkyl group, a hydroxy group, a carbonyl group, and a nitro group.

The alkyl group as the substituent is preferably an alkyl group having 1 to 5 carbon atoms, and most preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom as the substituent include a fluorine atom, a chlorine atom, a bromine atom, and an iodine atom. A fluorine atom is preferred.

Examples of the halogenated alkyl group as the substituent include an alkyl group having 1 to 5 carbon atoms, for example, a group in which a part or all of hydrogen atoms of a methyl group, an ethyl group, a propyl group, an n-butyl group, a tert-butyl group, or the like are replaced by halogen atoms.

The carbonyl group as the substituent is a group for replacing a methylene group (—CH₂—) constituting the cyclic hydrocarbon group.

The cyclic hydrocarbon group in R¹⁰¹ may be a fused cyclic group containing a fused ring in which an aliphatic hydrocarbon ring and an aromatic ring are fused. Examples of the fused ring include those in which one or more aromatic rings are fused in a polycycloalkane including a crosslinked ring polycyclic skeleton. Specific examples of the crosslinked ring polycycloalkane include bicycloalkanes such as bicyclo[2.2.1]heptane (norbornane) and bicyclo[2.2.2]octane. The fused ring is preferably a group containing a fused ring in which two or three aromatic rings are fused to a bicycloalkane, and more preferably a group containing a fused ring in which two or three aromatic rings are fused to bicyclo[2.2.2]octane. Specific examples of the fused cyclic group in R¹⁰¹ include a group represented by the following formula (r-br-1) or (r-br-2). In the formula, * represents a bond to be bonded to Y¹⁰¹ in the formula (b-1).

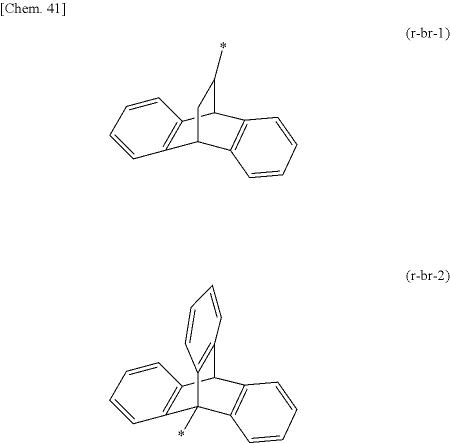 [SMILES: *C1CC2c3ccccc3C1c1ccccc12 ; *C12c3ccccc3C(c3ccccc31)c1ccccc12]

Examples of the substituent which the fused cyclic group in R¹⁰¹ may have include an alkyl group, an alkoxy group, a halogen atom, a halogenated alkyl group, a hydroxy group, a carbonyl group, a nitro group, an aromatic hydrocarbon group, and an alicyclic hydrocarbon group.

Examples of the alkyl group, alkoxy group, halogen atom and halogenated alkyl group as the substituent of the fused cyclic group include those same as those described as the substituent of the cyclic group in the R¹⁰¹.

Examples of the aromatic hydrocarbon group as the substituent of the fused ring group include a group in which one hydrogen atom is removed from an aromatic ring (an aryl group: for example, a phenyl group, and a naphthyl group), a group in which one hydrogen atom of the aromatic ring is replaced by an alkylene group (for example, an arylalkyl group such as a benzyl group, a phenethyl group, a 1-naphthylmethyl group, a 2-naphthylmethyl group, a 1-naphthylethyl group, and a 2-naphthylethyl group), and a heterocyclic group represented by any one of the above formulae (r-hr-1) to (r-hr-6).

Examples of the alicyclic hydrocarbon group as the substituent of the fused cyclic group include a group in which one hydrogen atom is removed from a monocycloalkane such as cyclopentane or cyclohexane; a group in which one hydrogen atom is removed from a polycycloalkane such as adamantane, norbornane, isobornane, tricyclodecane or tetracyclododecane; a lactone-containing cyclic group represented by any one of the general formulae (a2-r-1) to (a2-r-7); an —SO₂— containing cyclic group represented by any one of the general formulae (a5-r-1) to (a5-r-4); and a heterocyclic group represented by any one of the formulae (r-hr-7) to (r-hr-16).

Chain Alkyl Group that May Include Substituent:

The chain alkyl group of R¹⁰¹ may be either linear or branched.

The linear alkyl group preferably has 1 to 20 carbon atoms, more preferably has 1 to 15 carbon atoms, and most preferably has 1 to 10 carbon atoms.

The branched alkyl group preferably has 3 to 20 carbon atoms, more preferably has 3 to 15 carbon atoms, and most preferably has 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain Alkenyl Group that May Include Substituent:

The chain alkenyl group of R¹⁰¹ may be either linear or branched, and preferably has 2 to 10 carbon atoms, more preferably has 2 to 5 carbon atoms, still more preferably has 2 to 4 carbon atoms, and particularly preferably has 2 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, as the chain alkenyl group, a linear alkenyl group is preferred, a vinyl group or a propenyl group is more preferred, and a vinyl group is particularly preferred.

Examples of the substituent in the chain alkyl group or alkenyl group of R¹⁰¹ include an alkoxy group, a halogen atom, a halogenated alkyl group, a hydroxy group, a carbonyl group, a nitro group, and an amino group, and a cyclic group in the above R¹⁰¹.

Among the above, R¹⁰¹ is preferably a cyclic group that may include a substituent, and more preferably a cyclic hydrocarbon group that may include a substituent. More specifically, the cyclic hydrocarbon group is preferably a group in which one or more hydrogen atoms are removed from a phenyl group, a naphthyl group, or a polycycloalkane; a lactone-containing cyclic group represented by any one of the general formulae (a2-r-1) to (a2-r-7); or an —SO₂— containing cyclic group represented by any one of the general formulae (a5-r-1) to (a5-r-4), more preferably a group in which one or more hydrogen atoms are removed from a polycycloalkane, or an —SO₂— containing cyclic group represented by any one of the general formulae (a5-r-1) to (a5-r-4), and still more preferably an adamantyl group or an —SO₂-containing cyclic group represented by the general formula (a5-r-1).

When the cyclic hydrocarbon group includes a substituent, the substituent is preferably a hydroxy group.

In the formula (b-1), Y¹⁰¹ is a single bond or a divalent linking group containing an oxygen atom.

When Y¹⁰¹ is the divalent linking group containing an oxygen atom, the Y¹⁰¹ may contain an atom other than the oxygen atom. Examples of the atom other than the oxygen atom include a carbon atom, a hydrogen atom, a sulfur atom, and a nitrogen atom.

Examples of the divalent linking group containing an oxygen atom include a non-hydrocarbon oxygen atom-containing linking group such as an oxygen atom (an ether bond: —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and a combination of the non-hydrocarbon oxygen atom-containing linking group and an alkylene group. A sulfonyl group (—SO₂—) may be further linked to the combination. Examples of such a divalent linking group containing an oxygen atom include a linking group represented by any one of the following general formulae (y-al-1) to (y-al-7). In the following general formulae (y-al-1) to (y-al-7), V′¹⁰¹ in the following general formulae (y-al-1) to (y-al-7) is to be bonded to R¹⁰¹ in the formula (b-1).

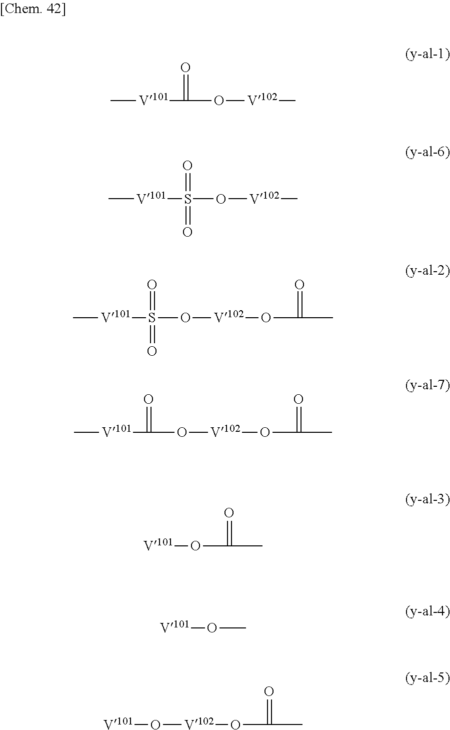

[In the formula, V′¹⁰¹ represents a single bond or an alkylene group having 1 to 5 carbon atoms, and V′¹⁰² represents a divalent saturated hydrocarbon group having 1 to 30 carbon atoms.]

The divalent saturated hydrocarbon group in V′¹⁰² is preferably an alkylene group having 1 to 30 carbon atoms, more preferably an alkylene group having 1 to 10 carbon atoms, and still more preferably an alkylene group having 1 to 5 carbon atoms.

The alkylene group in V′¹⁰¹ and V′¹⁰² may be a linear alkylene group or a branched alkylene group, and a linear alkylene group is preferred.

Specific examples of the alkylene group in V′¹⁰¹ and V′¹⁰² include am methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; an ethylene group [—CH₂CH₂—]; an alkylethylene group such as —CH(CH₃)CH₂—, —CH(CH₃)CH(CH₃)—, —C(CH₃CH₂—, and —CH(CH₂CH₃)CH₂—; a trimethylene group (an n-propylene group) [—CH₂CH₂CH₂—]; an alkyltrimethylene group such as —CH(CH₃)CH₂CH₂—, and —CH₂CH(CH₃)CH₂—; a tetramethylene group [—CH₂CH₂CH₂CH₂—]; an alkyl tetramethylene group such as —CH(CH₃)CH₂CH₂CH₂—, and —CH₂CH(CH₃)CH₂CH₂—; and a pentamethylene group [—CH₂CH₂CH₂CH₂CH₂—].

Some of the methylene groups in the alkylene group in V′¹⁰¹ or V′¹⁰² may be replaced by a divalent aliphatic cyclic group having 5 to 10 carbon atoms. The aliphatic cyclic group is preferably a divalent group in which one hydrogen atom is further removed from the cyclic aliphatic hydrocarbon group (monocyclic aliphatic hydrocarbon group or polycyclic aliphatic hydrocarbon group) of Ra′³ in the formula (a1-r-1), and is more preferably a cycloxylene group, a 1,5-adamantylene group, or a 2,6-adamantylene group.

Y¹⁰¹ is preferably a divalent linking group containing an ester bond or a divalent linking group containing an ether bond, and more preferably a linking group represented by any one of the formulae (y-al-1) to (y-al-5).

In the formula (b-1), V¹⁰¹ represents a single bond, an alkylene group, or a fluorinated alkylene group. The alkylene group and fluorinated alkylene group in V¹⁰¹ preferably have 1 to 4 carbon atoms. Examples of the fluorinated alkylene group in V¹⁰¹ include a group in which a part or all of hydrogen atoms of the alkylene group in V¹⁰¹ are replaced by a fluorine atom. Among them, V¹⁰¹ is preferably a single bond or a fluorinated alkylene group having 1 to 4 carbon atoms.

In the formula (b-1), R¹⁰² is a fluorine atom or a fluorinated alkyl group having 1 to 5 carbon atoms. R¹⁰² is preferably a fluorine atom or a perfluoroalkyl group having 1 to 5 carbon atoms, and more preferably a fluorine atom.

Specific examples of an anion moiety represented by the formula (b-1) include a fluorinated alkylsulfonate anion such as a trifluoromethanesulfonate anion and a perfluorobutanesulfonate anion when Y¹⁰¹ is a single bond, and an anion represented by any one of the following formulae (an-1) to (an-3) when Y¹⁰¹ is a divalent linking group containing an oxygen atom.

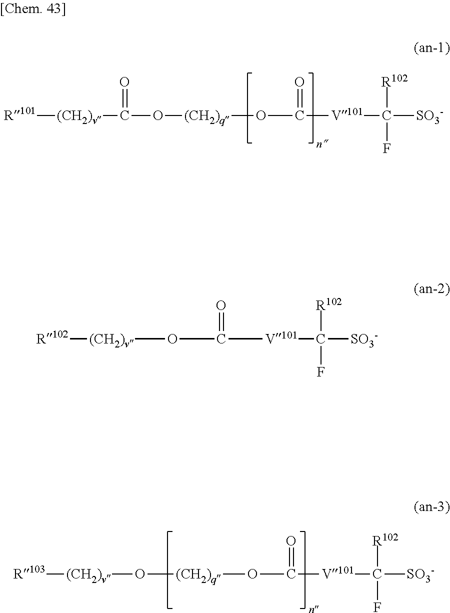

[In the formula, R″¹⁰¹ is an aliphatic cyclic group that may include a substituent, a monovalent heterocyclic group represented by any one of the chemical formulae (r-hr-1) to (r-hr-6), a fused cyclic group represented by the formula (r-br-1) or (r-br-2), or a chain alkyl group that may include a substituent. R″¹⁰² is an aliphatic cyclic group that may include a substituent, a fused cyclic group represented by the formula (r-br-1) or (r-br-2), a lactone-containing cyclic group represented by any one of the general formulae (a2-r-1) and (a2-r-3) to (a2-r-7), or an —SO₂— containing cyclic group represented by any one of the general formulae (a5-r-1) to (a5-r-4). R″¹⁰³ is an aromatic cyclic group that may include a substituent, an aliphatic cyclic group that may include a substituent, or a chain alkenyl group that may include a substituent. V″¹⁰¹ is a single bond, an alkylene group having 1 to 4 carbon atoms, or a fluorinated alkylene group having 1 to 4 carbon atoms. R¹⁰² is a fluorine atom or a fluorinated alkyl group having 1 to 5 carbon atoms. v″'s are each independently an integer of 0 to 3, q″'s are each independently an integer of 0 to 20, and n″ is 0 or 1.1

The aliphatic cyclic group that may include a substituent of R″¹⁰¹, R″¹⁰², and R″¹⁰³ is preferably a group described as the cyclic aliphatic hydrocarbon group in R¹⁰¹ in the formula (b-1). Examples of the substituent include those same as the substituent which may substitute the cyclic aliphatic hydrocarbon group in R¹⁰¹ in the formula (b-1).

The aromatic cyclic group that may include a substituent in R″¹⁰³ is preferably a group described as the aromatic hydrocarbon group in the cyclic hydrocarbon group in R¹⁰¹ in the formula (b-1). Examples of the substituent include the same as the substituent which may substitute the aromatic hydrocarbon group in R¹⁰¹ in the formula (b-1).

The chain alkyl group that may include a substituent in R″¹⁰¹ is preferably a group described as the chain alkyl group in R¹⁰¹ in the formula (b-1).

The chain alkenyl group that may include a substituent in R″¹⁰³ is preferably a group described as the chain alkenyl group in R¹⁰¹ in the formula (b-1).

Anion in Component (b-2)

In the formula (b-2), R¹⁰⁴ and R¹⁰⁵ each independently represent a cyclic group that may include a substituent, a chain alkyl group that may include a substituent, or a chain alkenyl group that may include a substituent, and examples of these include those same as R¹⁰¹ in the formula (b-1). R¹⁰⁴ and R¹⁰⁵ may be bonded to each other to form a ring.

R¹⁰⁴ and R¹⁰⁵ are preferably a chain alkyl group that may include a substituent, and more preferably a linear or branched alkyl group, or a linear or branched fluorinated alkyl group.

The number of carbon atoms of the chain alkyl group is preferably 1 to 10, more preferably 1 to 7, and still more preferably 1 to 3. The number of carbon atoms of the chain alkyl group of R¹⁰⁴ and R¹⁰⁵ is preferably as small as possible within the above range, for reasons such as good solubility in a resist solvent. It is preferable that in the chain alkyl group of R¹⁰⁴ or R¹⁰⁵, the number of hydrogen atoms replaced by a fluorine atom increase, since the acid strength increases, and the transparency to high-energy light of 250 nm or less or an electron beam is improved. A proportion of the fluorine atom in the chain alkyl group, that is, a fluorination ratio is preferably 70% to 100%, more preferably 90% to 100%, and it is most preferable that the chain alkyl group be a perfluoroalkyl group in which all of hydrogen atoms are replaced by a fluorine atom.

In the formula (b-2), V¹⁰² and V¹⁰³ each independently represent a single bond, an alkylene group, or a fluorinated alkylene group, and examples of each include those same as V¹⁰¹ in the formula (b-1).

In the formula (b-2), L¹⁰¹ and L¹⁰² each independently represent a single bond or an oxygen atom.

Anion in Component (b-3)

In the formula (b-3), R¹⁰⁶ to R¹⁰⁸ each independently represent a cyclic group that may include a substituent, a chain alkyl group that may include a substituent, or a chain alkenyl group that may include a substituent, and examples of each include those same as R¹⁰¹ in the formula (b-1).

In the formula (b-3), L¹⁰¹ to L¹⁰⁵ each independently represent a single bond, —CO—, or —SO₂—.

Among the above, the anion moiety of the component (B) is preferably an anion in the component (b-1). Among the above, an anion represented by any one of the general formulae (an-1) to (an-3) is more preferred, an anion represented by any one of the general formulae (an-1) and (an-2) is still more preferred, and an anion represented by the general formula (an-2) is particularly preferred.

### {Cation Moiety}

In the formulae (b-1), (b-2), and (b-3), M^{m+} represents an m-valent onium cation. Among the above, a sulfonium cation and an iodonium cation are preferred.

The symbol m is an integer of 1 or more.

Preferred examples of the cation moiety ((M^{m+})_{1/m}) include an organic cation represented by any one of the following general formulae (ca-1) to (ca-3).

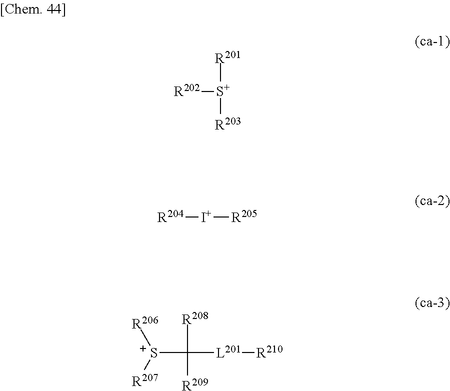

[In the formula, R²⁰¹ to R²⁰⁷ each independently represent an aryl group that may include a substituent, an alkyl group that may include a substituent, or an alkenyl group that may include a substituent. R²⁰¹ to R²⁰³ and R²⁰⁶ to R²⁰⁷ may be bonded to each other to form a ring together with the sulfur atom in the formula. R²⁰⁸ and R²⁰⁹ each independently represent a hydrogen atom or an alkyl group having 1 to 5 carbon atoms. R²¹⁰ represents an aryl group that may include a substituent, an alkyl group that may include a substituent, an alkenyl group that may include a substituent, or an —SO₂— containing cyclic group that may include a substituent. L²⁰¹ represents —C(═O)— or —C(═O)—O—.]

In the above general formulae (ca-1) to (ca-3), examples of the aryl group in R²⁰¹ to R²⁰⁷ include an unreplaced aryl group having 6 to 20 carbon atoms, and a phenyl group or a naphthyl group is preferred.

The alkyl group in R²⁰¹ to R²⁰⁷ is preferably a chain or cyclic alkyl group having 1 to 30 carbon atoms.

The alkenyl group in R²⁰¹ to R²⁰⁷ preferably has 2 to 10 carbon atoms.

Examples of the substituent which R²⁰¹ to R²⁰⁷ and R²¹⁰ may have include an alkyl group, a halogen atom, a halogenated alkyl group, a carbonyl group, a cyano group, an amino group, an aryl group, and a group represented by any one of the following general formulae (ca-r-1) to (ca-r-7).

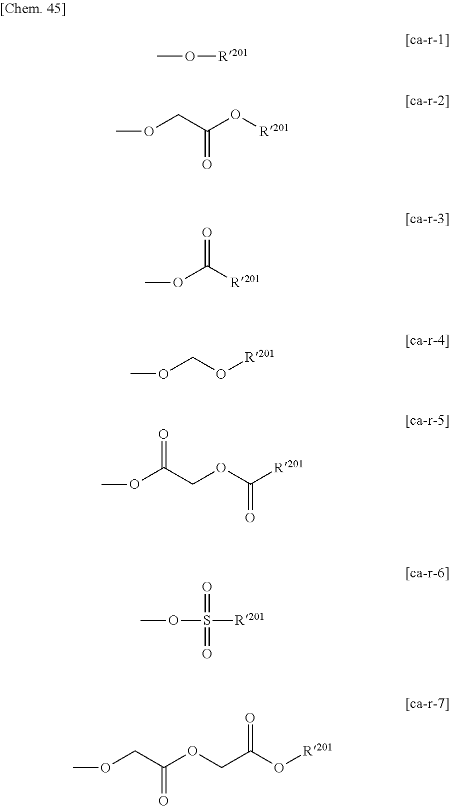

[In the formulae, R′²⁰¹'s each independently represents a hydrogen atom, a cyclic group that may include a substituent, a chain alkyl group that may include a substituent, or a chain alkenyl group that may include a substituent.]

Cyclic Group that May Include Substituent:

The cyclic group is preferably a cyclic hydrocarbon group, and the cyclic hydrocarbon group may be an aromatic hydrocarbon group or an aliphatic hydrocarbon group. An aliphatic hydrocarbon group means a hydrocarbon group having no aromaticity. The aliphatic hydrocarbon group may be saturated or unsaturated, and is generally preferably saturated.

The aromatic hydrocarbon group in R′²⁰¹ is a hydrocarbon group having an aromatic ring. The aromatic hydrocarbon group preferably has 3 to 30 carbon atoms, more preferably has 5 to 30 carbon atoms, still more preferably has 5 to 20 carbon atoms, particularly preferably has 6 to 15 carbon atoms, and most preferably has 6 to 10 carbon atoms. The number of the carbon atoms does not include the number of the carbon atoms in the substituent.

Specific examples of the aromatic ring of the aromatic hydrocarbon group in R′²⁰¹ include benzene, fluorene, naphthalene, anthracene, phenanthrene, biphenyl, and an aromatic heterocyclic ring in which a part of carbon atoms constituting the aromatic ring is replaced by a heteroatom. Examples of the heteroatom in the aromatic heterocyclic ring include an oxygen atom, a sulfur atom, and a nitrogen atom.

Specific examples of the aromatic hydrocarbon group in R′²⁰¹ include a group in which one hydrogen atom is removed from the aromatic ring (an aryl group: for example, a phenyl group or a naphthyl group), and a group in which one hydrogen atom of the aromatic ring is replaced by an alkylene group (for example, an arylalkyl group such as a benzyl group, a phenethyl group, a 1-naphthyl methyl group, a 2-naphthyl methyl group, a 1-naphthyl ethyl group, or a 2-naphthyl ethyl group). The number of carbon atoms of the alkylene group (an alkyl chain in the arylalkyl group) is preferably 1 to 4, more preferably 1 to 2, and particularly preferably 1.

Examples of the cyclic aliphatic hydrocarbon group in R′²⁰¹ include an aliphatic hydrocarbon group containing a ring in the structure thereof.

Examples of the aliphatic hydrocarbon group containing a ring in the structure thereof include an alicyclic hydrocarbon group (a group in which one hydrogen atom is removed from an aliphatic hydrocarbon ring), a group in which an alicyclic hydrocarbon group is bonded to the terminal of a linear or branched aliphatic hydrocarbon group, and a group in which an alicyclic hydrocarbon group is interposed in the middle of a linear or branched aliphatic hydrocarbon group.

The alicyclic hydrocarbon group preferably has 3 to 20 carbon atoms, and more preferably has 3 to 12 carbon atoms.

The alicyclic hydrocarbon group may be a polycyclic group or a monocyclic group. The monocyclic alicyclic hydrocarbon group is preferably a group in which one or more hydrogen atoms are removed from a monocycloalkane. The monocycloalkane preferably has 3 to 6 carbon atoms, and specific examples thereof include cyclopentane and cyclohexane. The polycyclic alicyclic hydrocarbon group is preferably a group in which one or more hydrogen atoms are removed from a polycycloalkane, and the polycycloalkane preferably has 7 to 30 carbon atoms. Among them, the polycycloalkane is more preferably a polycycloalkane including a crosslinked ring polycyclic skeleton, such as adamantane, norbornane, isobornane, tricyclodecane, or tetracyclododecane; or a polycycloalkane including a fused ring polycyclic skeleton, such as a cyclic group including a steroid skeleton.

Among them, as the cyclic aliphatic hydrocarbon group in R′²⁰¹, a group in which one or more hydrogen atoms are removed from a monocycloalkane or a polycycloalkane is preferred, a group in which one hydrogen atom is removed from a polycycloalkane is more preferred, an adamantyl group or a norbornyl group is particularly preferred, and an adamantyl group is most preferred.

The linear or branched aliphatic hydrocarbon group which may be bonded to the alicyclic hydrocarbon group preferably has 1 to 10 carbon atoms, more preferably has 1 to 6 carbon atoms, still more preferably has 1 to 4 carbon atoms, and particularly preferably has 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group is preferably a branched alkylene group, and specific examples thereof include alkyl alkylene groups such as alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyl trimethylene groups such as —CH(CH₃)CH₂CH₂— and —CH₂CH(CH₃)CH₂—; and alkyl tetramethylene groups such as —CH(CH₃)CH₂CH₂CH₂— and —CH₂CH(CH₃)CH₂CH₂—. The alkyl group in the alkylalkylene group is preferably a linear alkyl group having 1 to 5 carbon atoms.

The cyclic hydrocarbon group in R′²⁰¹ may contain a heteroatom, similar to a heterocyclic ring. Specific examples thereof include a lactone-containing cyclic group represented by any one of the general formulae (a2-r-1) to (a2-r-7), an —SO₂— containing cyclic group represented by any one of the general formulae (a5-r-1) to (a5-r-4), and a heterocyclic group represented by any one of the above chemical formulae (r-hr-1) to (r-hr-16).

Examples of the substituent in the cyclic group of R′²⁰¹ include an alkyl group, an alkoxy group, a halogen atom, a halogenated alkyl group, a hydroxy group, a carbonyl group, and a nitro group.

The alkyl group as the substituent is preferably an alkyl group having 1 to 5 carbon atoms, and most preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

The halogen atom as the substituent is preferably a fluorine atom.

Examples of the halogenated alkyl group as the substituent include an alkyl group having 1 to 5 carbon atoms, for example, a group in which a part or all of hydrogen atoms of a methyl group, an ethyl group, a propyl group, an n-butyl group, a tert-butyl group, or the like are replaced by halogen atoms.

The carbonyl group as the substituent is a group for replacing a methylene group (—CH₂—) constituting the cyclic hydrocarbon group.

Chain Alkyl Group that May Include Substituent:

The chain alkyl group of R′²⁰¹ may be either linear or branched.

The linear alkyl group preferably has 1 to 20 carbon atoms, more preferably has 1 to 15 carbon atoms, and most preferably has 1 to 10 carbon atoms.

The branched alkyl group preferably has 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain Alkenyl Group that May Include Substituent:

The chain alkenyl group of R′²⁰¹ may be either linear or branched, and preferably has 2 to 10 carbon atoms, more preferably has 2 to 5 carbon atoms, still more preferably has 2 to 4 carbon atoms, and particularly preferably has 2 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, as the chain alkenyl group, a linear alkenyl group is preferred, a vinyl group or a propenyl group is more preferred, and a vinyl group is particularly preferred.

Examples of the substituent in the chain alkyl group or alkenyl group of R′²⁰¹ include an alkoxy group, a halogen atom, a halogenated alkyl group, a hydroxy group, a carbonyl group, a nitro group, and an amino group, and a cyclic group in the above R′²⁰¹.

Examples of the cyclic group that may include a substituent, the chain alkyl group that may include a substituent, and the chain alkenyl group that may include a substituent of R′²⁰¹ include, in addition to those described above, those same as the acid-dissociable group represented by the formula (a1-r-2) as a cyclic group that may include a substituent or a chain alkyl group that may include a substituent.

Among them, R′²⁰¹ is preferably a cyclic group that may include a substituent, and more preferably a cyclic hydrocarbon group that may include a substituent. More specifically, for example, a phenyl group, a naphthyl group, a group in which one or more hydrogen atoms are removed from a polycycloalkane, a lactone-containing cyclic group represented by any one of the general formulae (a2-r-1) to (a2-r-7), and an —SO₂— containing cyclic group represented by any one of the general formulae (a5-r-1) to (a5-r-4) are preferred.

When R²⁰¹ to R²⁰³, R²⁰⁶, and R²⁰⁷ in the general formulae (ca-1) to (ca-3) are bonded to each other to form a ring together with the sulfur atom in the formula, R²⁰¹ to R²⁰³ and R²⁰⁶ to R²⁰⁷ may be bonded via a heteroatom such as a sulfur atom, an oxygen atom or a nitrogen atom, or a functional group such as a carbonyl group, —SO—, —SO₂—, —SO₃—, —COO—, —CONH— or —N(R_{N})— (the R_{N} is an alkyl group having 1 to 5 carbon atoms). Regarding the ring to be formed, one ring containing the sulfur atom of the formula in the ring skeleton is preferably a 3-membered to 10-membered ring, and particularly preferably a 5-membered to 7-membered ring, including the sulfur atom. Specific examples of the ring to be formed include a thiophene ring, a thiazole ring, a benzothiophene ring, a thianthlene ring, a benzothiophene ring, a dibenzthiophene ring, a 9H-thioxanthene ring, a thioxanthone ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms, and are preferably a hydrogen atom or an alkyl group having 1 to 3 carbon atoms. When R²⁰⁸ and R²⁰⁹ represent an alkyl group, R²⁰⁸ and R²⁰⁹ may be bonded to each other to form a ring.

R²¹⁰ represents an aryl group that may include a substituent, an alkyl group that may include a substituent, an alkenyl group that may include a substituent, or an —SO₂— containing cyclic group that may include a substituent.

Examples of the aryl group in R²¹⁰ include an unreplaced aryl group having 6 to 20 carbon atoms, and a phenyl group and a naphthyl group are preferred.

The alkyl group in R²¹⁰ is preferably a chain or cyclic alkyl group having 1 to 30 carbon atoms.

The alkenyl group in R²¹⁰ preferably has 2 to 10 carbon atoms.

As the —SO₂— containing cyclic group that may include a substituent in R²¹⁰, an “—SO₂— containing polycyclic group” is preferred, and a group represented by the above general formula (a5-r-1) is more preferred.

Specific examples of the suitable cation represented by the formula (ca-1) include a cation represented by any one of the following chemical formulae (ca-1-1) to (ca-1-70), (ca-i-1) to (ca-1-8) are preferred, and (ca-1-1) is more preferred.

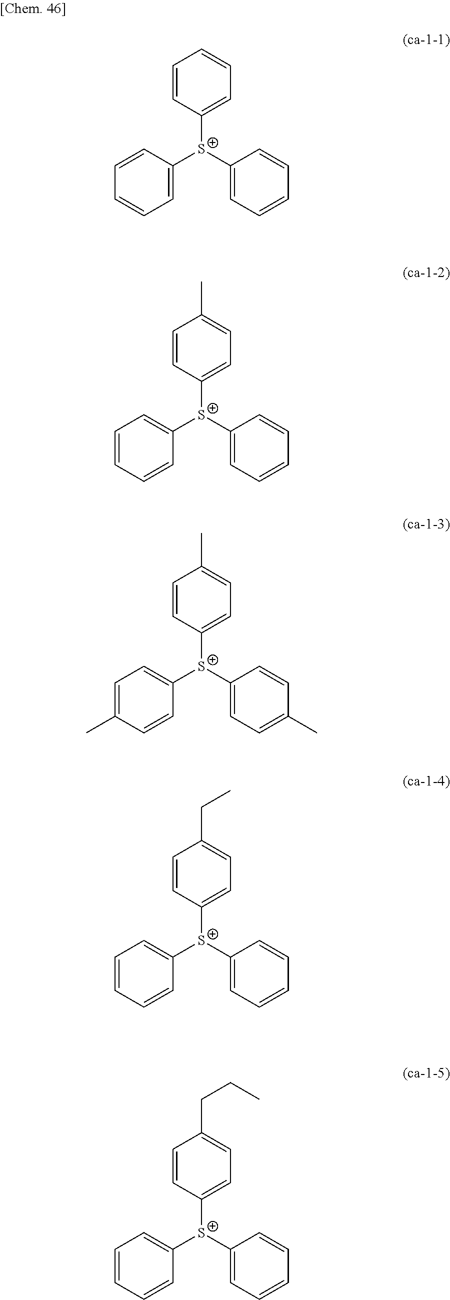

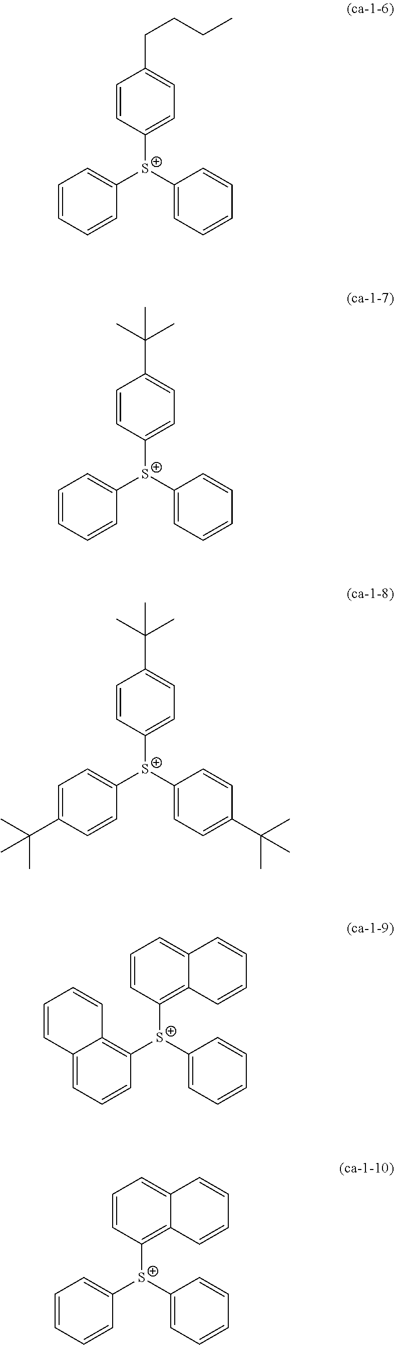 [SMILES: CCCCc1ccc([S+](c2ccccc2)c2ccccc2)cc1 ; CC(C)(C)c1ccc([S+](c2ccccc2)c2ccccc2)cc1 ; CC(C)(C)c1ccc([S+](c2ccc(C(C)(C)C)cc2)c2ccc(C(C)(C)C)cc2)cc1 ; c1ccc([S+](c2cccc3ccccc23)c2cccc3ccccc23)cc1 ; c1ccc([S+](c2ccccc2)c2cccc3ccccc23)cc1]

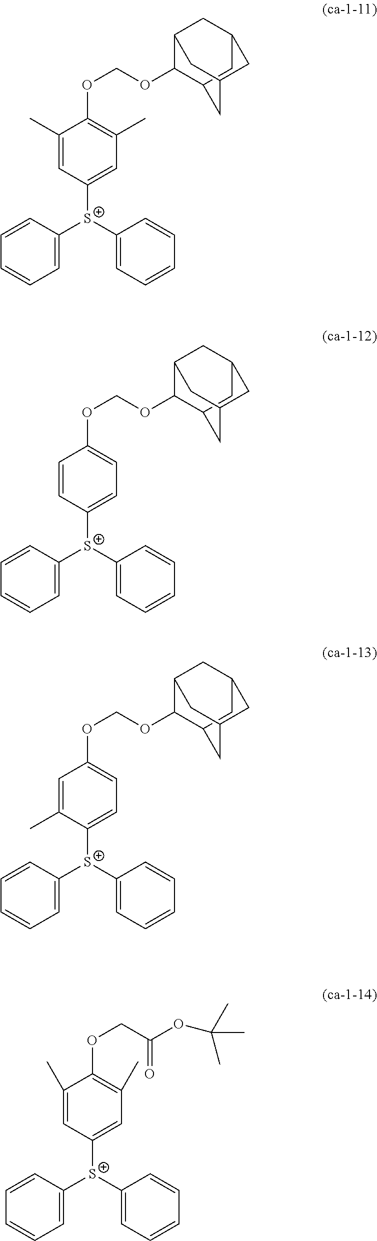 [SMILES: Cc1cc([S+](c2ccccc2)c2ccccc2)cc(C)c1OCOC1C2CC3CC(C2)CC1C3 ; c1ccc([S+](c2ccccc2)c2ccc(OCOC3C4CC5CC(C4)CC3C5)cc2)cc1 ; Cc1cc(OCOC2C3CC4CC(C3)CC2C4)ccc1[S+](c1ccccc1)c1ccccc1 ; Cc1cc([S+](c2ccccc2)c2ccccc2)cc(C)c1OCC(=O)OC(C)(C)C]

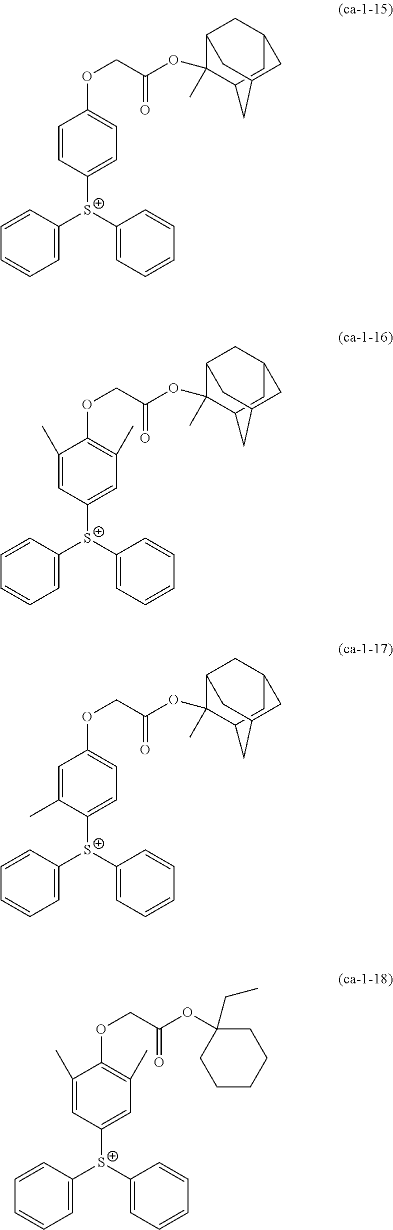 [SMILES: CC1(OC(=O)COc2ccc([S+](c3ccccc3)c3ccccc3)cc2)C2CC3CC(C2)CC1C3 ; Cc1cc([S+](c2ccccc2)c2ccccc2)cc(C)c1OCC(=O)OC1(C)C2CC3CC(C2)CC1C3 ; Cc1cc(OCC(=O)OC2(C)C3CC4CC(C3)CC2C4)ccc1[S+](c1ccccc1)c1ccccc1 ; CCC1(OC(=O)COc2c(C)cc([S+](c3ccccc3)c3ccccc3)cc2C)CCCCC1]

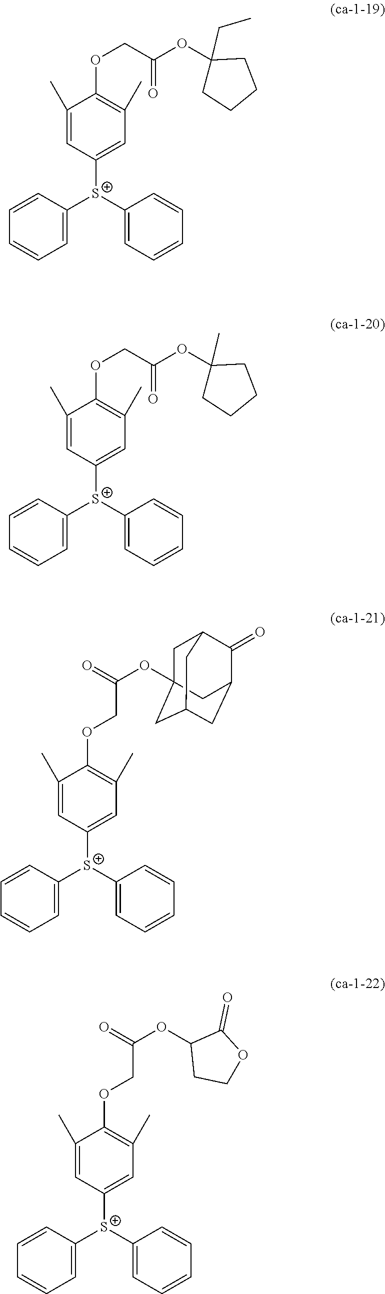 [SMILES: CCC1(OC(=O)COc2c(C)cc([S+](c3ccccc3)c3ccccc3)cc2C)CCCC1 ; Cc1cc([S+](c2ccccc2)c2ccccc2)cc(C)c1OCC(=O)OC1(C)CCCC1 ; Cc1cc([S+](c2ccccc2)c2ccccc2)cc(C)c1OCC(=O)OC12CC3CC(C1)C(=O)C(C3)C2 ; Cc1cc([S+](c2ccccc2)c2ccccc2)cc(C)c1OCC(=O)OC1CCOC1=O]

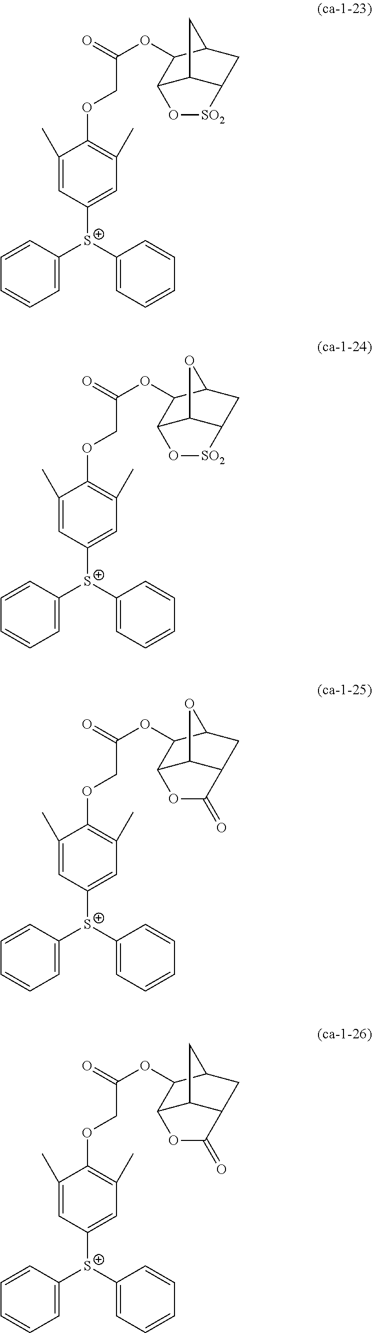 [SMILES: Cc1cc([S+](c2ccccc2)c2ccccc2)cc(C)c1OCC(=O)OC1C2CC3C1OS(=O)(=O)C3C2 ; Cc1cc([S+](c2ccccc2)c2ccccc2)cc(C)c1OCC(=O)OC1C2CC3C(O2)C1OS3(=O)=O ; Cc1cc([S+](c2ccccc2)c2ccccc2)cc(C)c1OCC(=O)OC1C2CC3C(=O)OC1C3O2 ; Cc1cc([S+](c2ccccc2)c2ccccc2)cc(C)c1OCC(=O)OC1C2CC3C(=O)OC1C3C2]

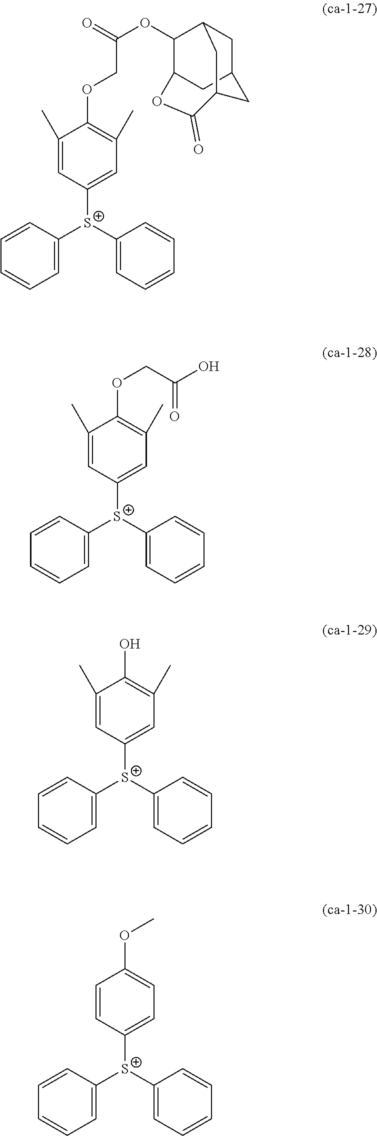 [SMILES: Cc1cc([S+](c2ccccc2)c2ccccc2)cc(C)c1OCC(=O)OC1C2CC3CC(C2)C(=O)OC1C3 ; Cc1cc([S+](c2ccccc2)c2ccccc2)cc(C)c1OCC(=O)O ; Cc1cc([S+](c2ccccc2)c2ccccc2)cc(C)c1O ; COc1ccc([S+](c2ccccc2)c2ccccc2)cc1]

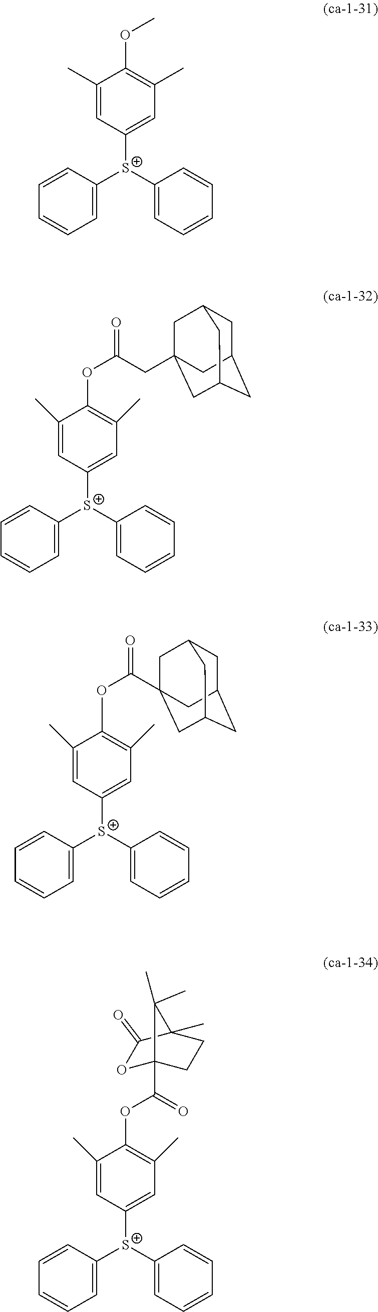 [SMILES: COc1c(C)cc([S+](c2ccccc2)c2ccccc2)cc1C ; Cc1cc([S+](c2ccccc2)c2ccccc2)cc(C)c1OC(=O)CC12CC3CC(CC(C3)C1)C2 ; Cc1cc([S+](c2ccccc2)c2ccccc2)cc(C)c1OC(=O)C12CC3CC(CC(C3)C1)C2 ; Cc1cc([S+](c2ccccc2)c2ccccc2)cc(C)c1OC(=O)C12CCC(C)(C(=O)O1)C2(C)C]

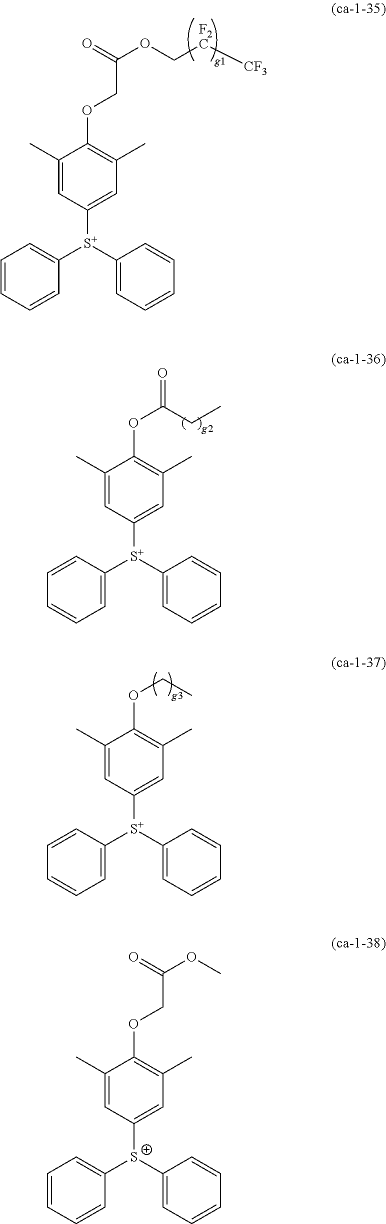

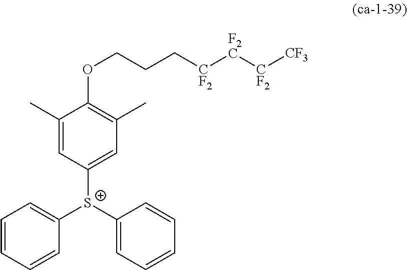 [SMILES: Cc1cc([S+](c2ccccc2)c2ccccc2)cc(C)c1OCCCC(F)(F)C(F)(F)C(F)(F)C(F)(F)F]

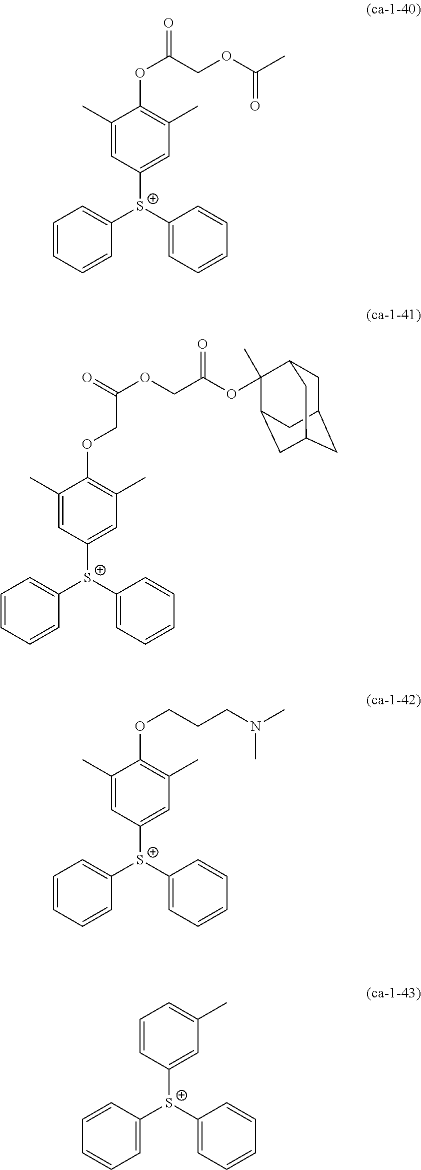 [SMILES: CC(=O)OCC(=O)Oc1c(C)cc([S+](c2ccccc2)c2ccccc2)cc1C ; Cc1cc([S+](c2ccccc2)c2ccccc2)cc(C)c1OCC(=O)OCC(=O)OC1(C)C2CC3CC(C2)CC1C3 ; Cc1cc([S+](c2ccccc2)c2ccccc2)cc(C)c1OCCCN(C)C ; Cc1cccc([S+](c2ccccc2)c2ccccc2)c1]

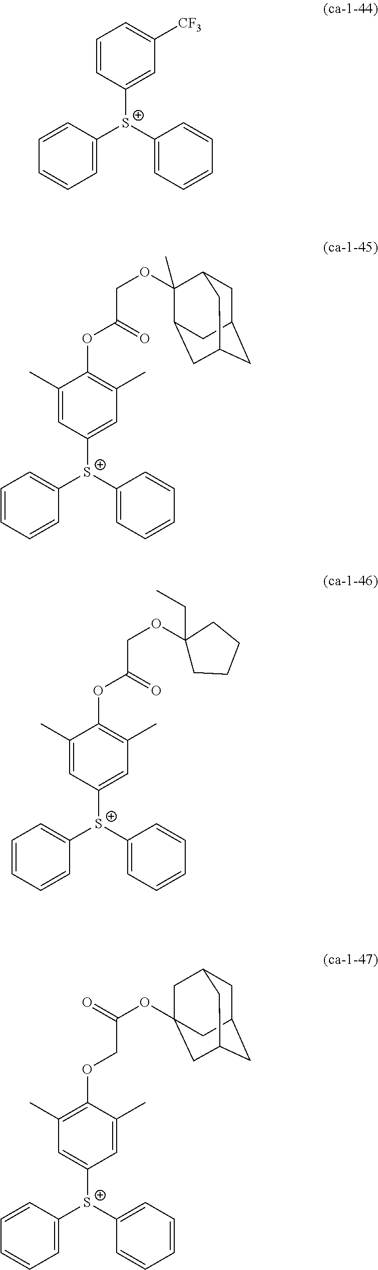 [SMILES: FC(F)(F)c1cccc([S+](c2ccccc2)c2ccccc2)c1 ; Cc1cc([S+](c2ccccc2)c2ccccc2)cc(C)c1OC(=O)COC1(C)C2CC3CC(C2)CC1C3 ; CCC1(OCC(=O)Oc2c(C)cc([S+](c3ccccc3)c3ccccc3)cc2C)CCCC1 ; Cc1cc([S+](c2ccccc2)c2ccccc2)cc(C)c1OCC(=O)OC12CC3CC(CC(C3)C1)C2]

[In the formulae, g1, g2, and g3 represent the number of repetitions, g1 is an integer of 1 to 5, g2 is an integer of 0 to 20, and g3 is an integer of 0 to 20.]

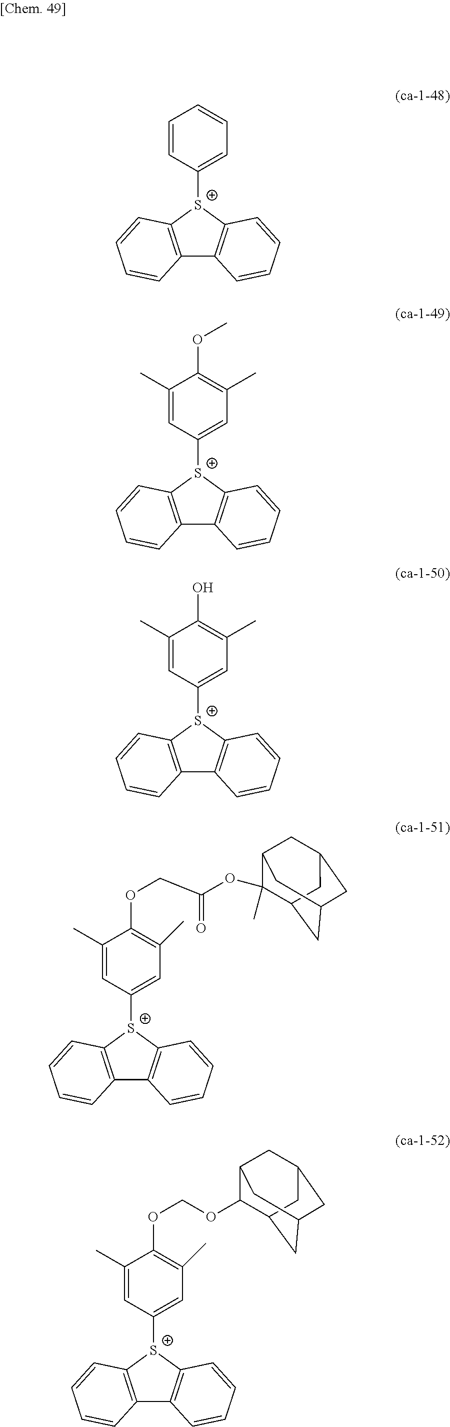 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; Cc1cc(-[s+]2c3ccccc3c3ccccc32)cc(C)c1OCC(=O)OC1(C)C2CC3CC(C2)CC1C3 ; Cc1cc(-[s+]2c3ccccc3c3ccccc32)cc(C)c1OCOC1C2CC3CC(C2)CC1C3]

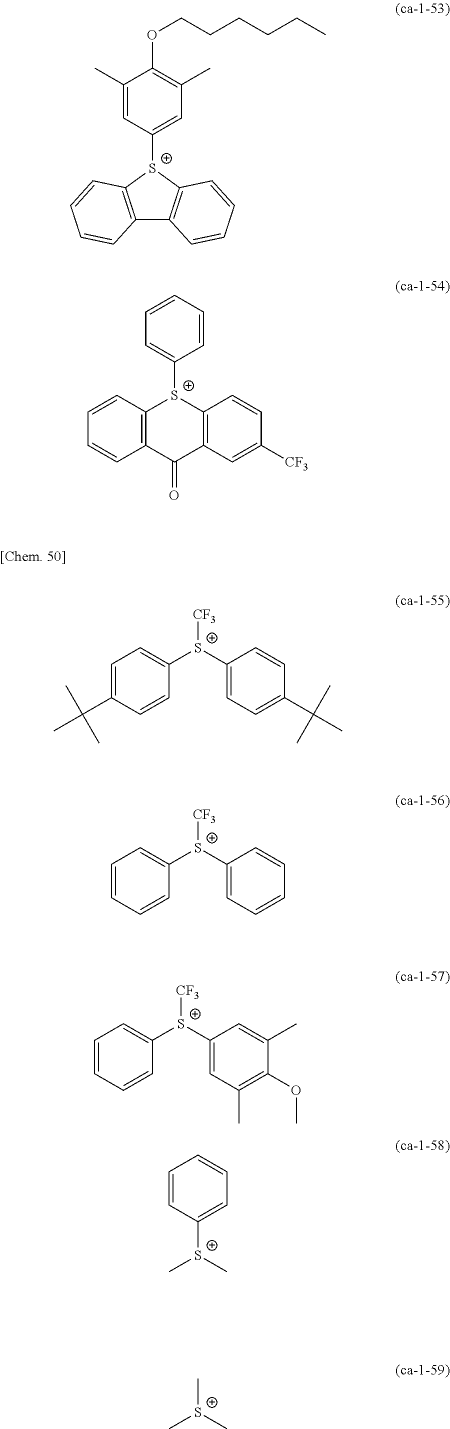

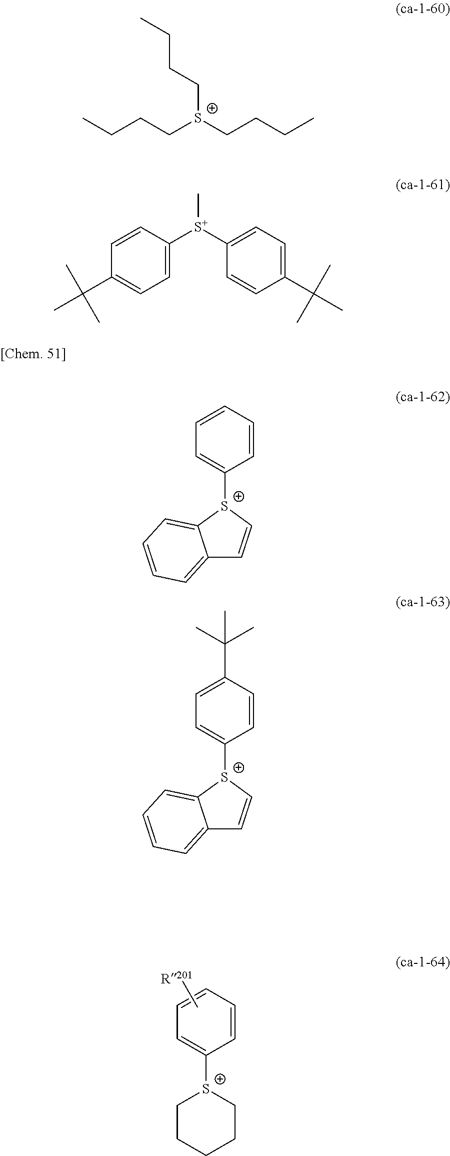

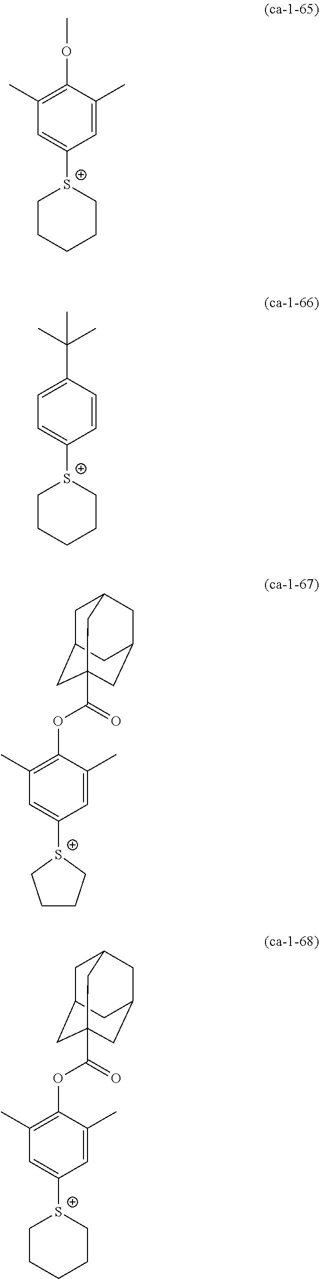

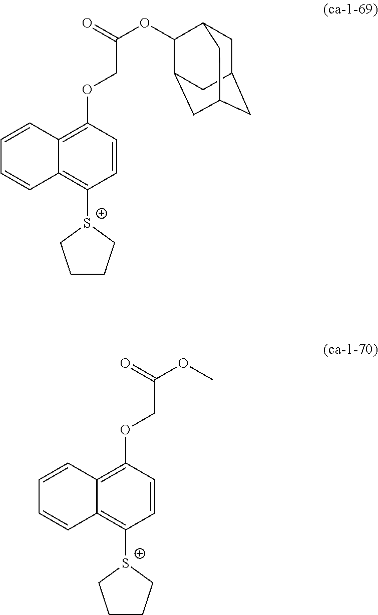 [SMILES: O=C(COc1ccc([S+]2CCCC2)c2ccccc12)OC1C2CC3CC(C2)CC1C3 ; COC(=O)COc1ccc([S+]2CCCC2)c2ccccc12]

[In the formulae, R″²⁰¹ represents a hydrogen atom or a substituent, and the substituent is the same as the substituent that R²⁰¹ to R²⁰⁷, and R²¹⁰ may have.]

Specific examples of the suitable cation represented by the formula (ca-2) include a diphenyliodonium cation, and a bis(4-tert-butylphenyl)iodonium cation.

Specific examples of the suitable cation represented by any one of the formula (ca-3) include a cation represented by any one of the following formulae (ca-3-1) to (ca-3-6).

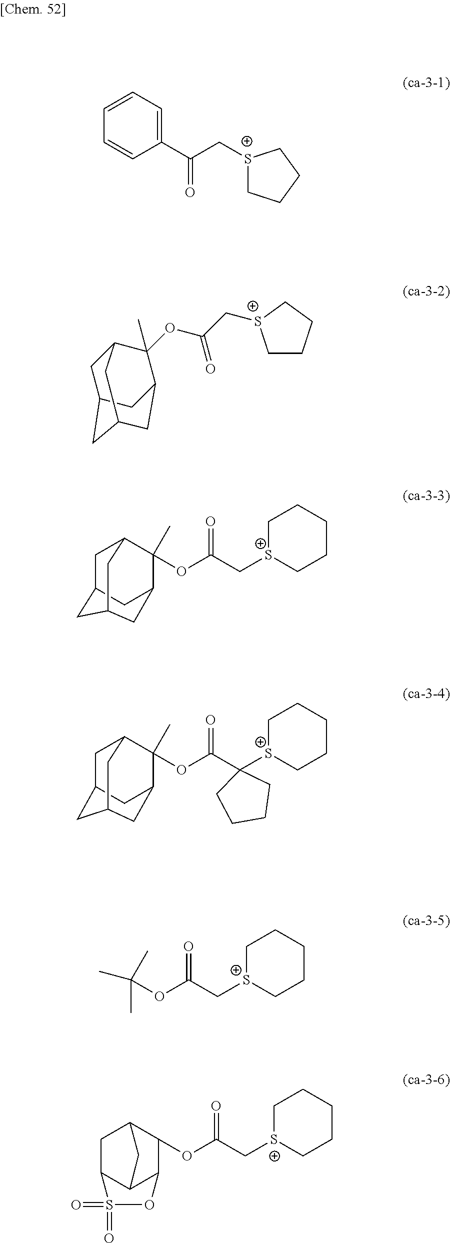 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

In the resist composition of the present embodiment, the component (B) may be used alone or in combination of two or more kinds thereof.

In the resist composition of the present embodiment, a content of the component (B) is preferably less than 40 parts by mass, more preferably 1 part by mass to 30 parts by mass, and still more preferably 3 parts by mass to 25 parts by mass, with respect to 100 parts by mass of the component (A).

When the content of the component (B) is within the above preferred range, pattern formation can be sufficiently performed. It is preferable that the content of the component (B) is within the above preferred range since a uniform solution is easily obtained when each component of the resist composition is dissolved in an organic solvent, and storage stability of the resist composition is improved.

### <First Acid Diffusion Control Component (D1) and Second Acid Diffusion Control Component (D2)>

The resist composition of the present embodiment contains, in addition to the component (A) and the component (B), a first acid diffusion control component (D1) and a second acid diffusion control component (D2). The first acid diffusion control component (D1) and the second acid diffusion control component (D2) have an effect of controlling diffusion of acid generated from the component (B) upon exposure.

The first acid diffusion control component (D1) (hereinafter, also referred to as component (D1)) contains a compound (d1-1) represented by the following general formula (d1-1), and the second acid diffusion control component (D2) (hereinafter, also referred to as component (D2)) contains a compound (d2-1) represented by the following general formula (d2-1).

In the resist composition of the present embodiment, the component (D1) and the component (D2) act as a quencher (an acid diffusion control agent) that traps acid generated upon exposure.

The component (D1) exhibits high acidity due to the presence of an alkylsulfonic acid moiety. Therefore, the component (D1) not only acts as an acid diffusion inhibitor in an unexposed portion, but also acts as an acid generating agent in an exposed portion. Accordingly, there is an effect of increasing sensitivity, enhancing deprotection reaction contrast between an exposed portion and an unexposed portion, and reducing variation of a pattern interface.

Further, by using the component (D1) in combination with the component (D2) having a specific structure in which a plurality of hydroxy groups are bonded, the solubility in a liquid developer is increased, and a high sensitivity can be achieved. Further, both high sensitivity of the resist composition and lithography properties such as resolution and improvement in roughness of a resist pattern formed using the resist composition can be achieved.

<<Compound (d1-1)>>

The compound (d1-1) is a compound represented by the following general formula (d1-1).

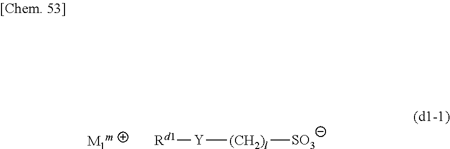

[In the general formula (d1-1), R^{d1} represents a cyclic group that may include a substituent or a chain alkyl group that may include a substituent, Y represents a single bond or a divalent linking group containing a heteroatom, 1 represents an integer of 1 or more, m represents an integer of 1 or more, and M₁^{m+} represents an m-valent organic cation.]

### {Anion Moiety}

In the above general formula (d1-1), R^{d1} represents a cyclic group that may include a substituent or a chain alkyl group that may include a substituent. Specifically, the chain alkyl group is a linear or branched alkyl group.

The linear or branched alkyl group in R^{d1} is preferably a linear or branched alkyl group having 1 to 20 carbon atoms, and more preferably a linear or branched alkyl group having 1 to 10 carbon atoms.

Specific examples of the linear or branched alkyl group include a methyl group, an ethyl group, a propyl group, an isopropyl group, a linear or branched butyl group, a linear or branched pentyl group, a linear or branched hexyl group, a linear or branched heptyl group, a linear or branched octyl group, a linear or branched nonyl group, and a linear or branched decyl group.

Among the above, the linear or branched alkyl group is preferably a linear alkyl group having 1 to 10 carbon atoms, and more preferably a linear alkyl group having 5 to 10 carbon atoms.

Specific examples of the cyclic group in R^{d1} include a monocyclic alicyclic group and a polycyclic alicyclic group.

As the monocyclic alicyclic hydrocarbon group, a group in which one hydrogen atom is removed from a monocycloalkane or monocycloalkene is preferred. The monocycloalkane preferably has 3 to 6 carbon atoms, and specific examples thereof include cyclopentane and cyclohexane.

The monocycloalkene preferably has 3 to 6 carbon atoms, and specific examples thereof include cyclopentene and cyclohexene.

The polycyclic alicyclic hydrocarbon group is preferably a group in which one or more hydrogen atoms are removed from a polycycloalkane, and the polycycloalkane preferably has 7 to 30 carbon atoms. Among them, the polycycloalkane is more preferably a polycycloalkane including a crosslinked ring polycyclic skeleton, such as adamantane, norbornane, isobornane, tricyclodecane, or tetracyclododecane; or a polycycloalkane including a fused ring polycyclic skeleton, such as a cyclic group including a steroid skeleton.

The cyclic group in R^{d1} may contain a heteroatom, similar to a heterocyclic ring. Specific examples thereof include a lactone-containing cyclic group represented by any one of the general formulae (a2-r-1) to (a2-r-7), a carbonate-containing cyclic group represented by any one of the general formulae (ax3-r-1) to (ax3-r-3), an —SO₂— containing cyclic group represented by any one of the general formulae (a5-r-1) to (a5-r-4), and a heterocyclic group represented by any one of the above chemical formulae (r-hr-7) to (r-hr-16). In each formula, * represents a bond to be bonded to Y in the general formula (d1-1).

The cyclic group represented by R^{d1} is preferably a polycyclic alicyclic hydrocarbon group, a lactone-containing cyclic group, a carbonate-containing cyclic group, or an —SO₂— containing cyclic group.

Examples of the substituent which the cyclic group and chain alkyl group in R^{d1} may have include an alkyl group, an alkoxy group, a halogen atom, a halogenated alkyl group, a hydroxy group, a nitro group, and an oxygen atom (═O).

The alkyl group as the substituent is preferably an alkyl group having 1 to 5 carbon atoms, and most preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom as the substituent include a fluorine atom, a chlorine atom, a bromine atom, and an iodine atom. A fluorine atom is preferred.

Examples of the halogenated alkyl group as the substituent include an alkyl group having 1 to 5 carbon atoms, for example, a group in which a part or all of hydrogen atoms of a methyl group, an ethyl group, a propyl group, an n-butyl group, a tert-butyl group, or the like are replaced by halogen atoms.

The expression “having an oxygen atom (═O) as a substituent” means that two hydrogen atoms bonded to one carbon atom constituting the cyclic group or the chain alkyl group are replaced by an oxygen atom (═O). It can also be said that the methylene group (—CH₂—) constituting the cyclic group or the chain alkyl group is replaced by a carbonyl group.

In the above general formula (d1-1), Y represents a single bond or a divalent linking group containing a heteroatom. In the general formula (d1-1), Y does not have a fluorine atom bonded thereto (is not replaced by fluorine). Accordingly, the anion of the component (d1-1) becomes an appropriate weak acid anion, and a quenching ability of the component (D1) is improved.

Examples of the divalent linking group containing a heteroatom in Y include those same as the divalent linking group containing a heteroatom described for the divalent linking group represented by Ya²¹ in the formula (a2-1). It is preferable that the divalent linking group containing a heteroatom in Y do not contain a fluorine atom.

In the general formula (d1-1), Y is preferably a single bond, —O—, —C(═O)—O—, —O—C(═O)—, —C(═O)—, or —O—C(═O)—O—, and more preferably a single bond, —C(═O)—O—, or —O—C(═O)—.

In the general formula (d1-1), l is an integer of 1 or more, preferably an integer of 1 to 8, more preferably an integer of 1 to 5, still more preferably an integer of 1 to 3, and particularly preferably 1 or 2.

### {Cation Moiety}

In the general formula (d1-1), m is an integer of 1 or more, and M₁^{m+} is an m-valent organic cation.

Suitable examples of the organic cation of M₁^{m+} include those same as a cation represented by any one of the general formulae (ca-1) to (ca-3), a cation represented by the general formula (ca-1) is more preferred, a cation represented by any one of the formulae (ca-1-1) to (ca-1-70) is still more preferred, a cation represented by any one of the formulae (ca-l-1) to (ca-1-8) is even more preferred, and a cation represented by the formula (ca-1-1) is particularly preferred.

Among the above, the compound (d1-1) is preferably a compound (d1-2) represented by the following general formula (d1-2) (hereinafter, also referred to as “component (D1-2)”).

That is, in the resist composition according to the embodiment of the present invention, the compound (d1-1) represented by the general formula (d1-1) is preferably a compound (d1-2) represented by the following general formula (d1-2).

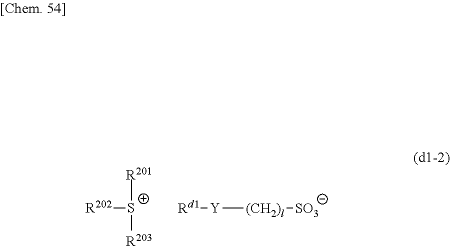

[In the general formula (d1-2), R^{d1} represents a cyclic group or a chain alkyl group that may include a substituent, Y represents a single bond or a divalent linking group containing a heteroatom, and 1 represents an integer of 1 or more. R²⁰¹ to R²⁰³ each independently represent an aryl group that may include a substituent, an alkyl group that may include a substituent, or an alkenyl group that may include a substituent. R²⁰¹ to R²⁰³ may be bonded to each other to form a ring together with the sulfur atom in the formula.]

In the general formula (d1-2), R^{d1}, Y, and 1 are the same as R^{d1}, Y, and 1 in the compound (d1-1), respectively, and the preferred ones are also the same.

In the general formula (d1-2), R²⁰¹ to R²⁰³ are the same as R²⁰¹ to R²⁰³ in the general formula (ca-1), respectively, and the preferred ones are also the same.

Preferred specific examples of the anion moiety in the general formulae (d1-1) and (d1-2) are shown below.

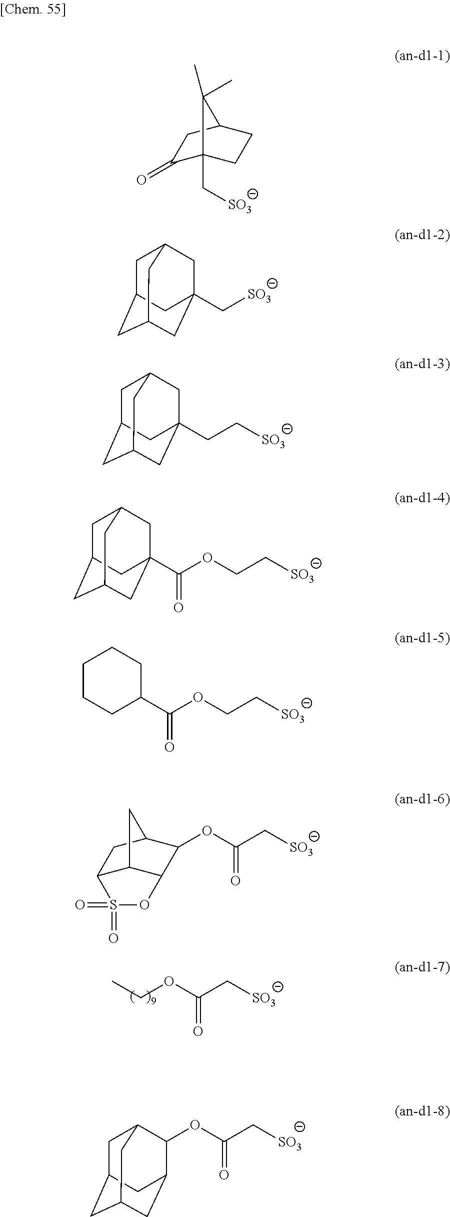

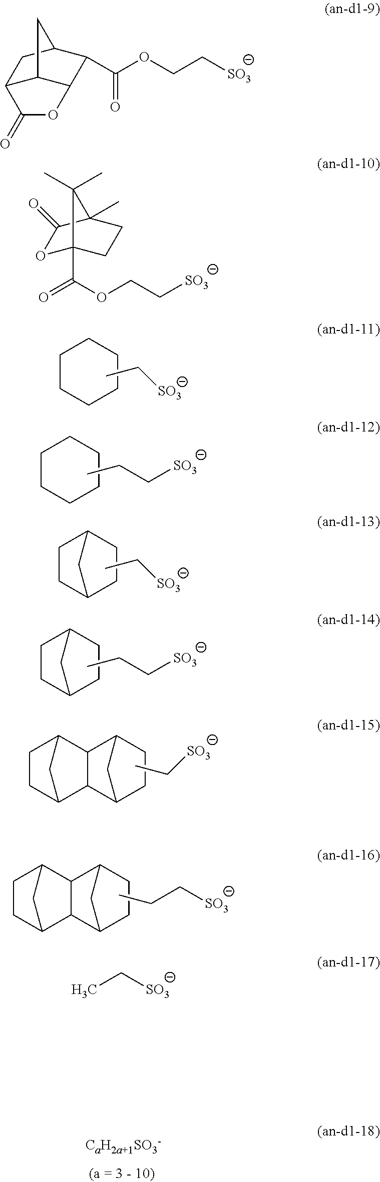

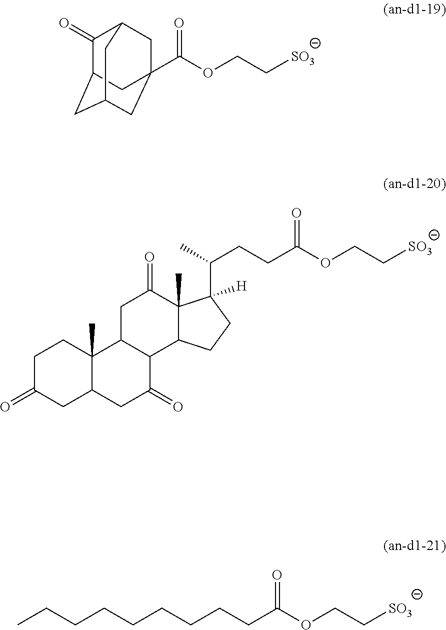

Among the above examples, the anion moiety in the component (D1) is more preferably an anion represented by any one of chemical formulae (an-d1-1) to (an-d1-10), and still more preferably an anion represented by any one of chemical formulae (an-d1-1), (an-d1-6) to (an-d1-8), and (an-d1-10).

In the resist composition of the present embodiment, the compound (d1-1) may be used alone or in combination of two or more kinds thereof.

In the resist composition of the present embodiment, a content of the compound (d1-1) is preferably 0.5 parts by mass to 30 parts by mass, more preferably 1 part by mass to 20 parts by mass, and still more preferably 2p arts by mass to 10p arts by mass, with respect to 100 parts by mass of the component (A).

When the content of the compound (d1-1) is equal to or larger than the preferred lower limit value, better lithography properties are easily obtained. On the other hand, when the content of the compound (d1-1) is equal to or less than the preferred upper limit value, the liquid developer solubility can be appropriately ensured, and thus the sensitivity can be better maintained and the effect of the present invention can be more easily obtained.

<<Compound (d2-1)>>

The compound (d2-1) is a compound represented by the following general formula (d2-1).

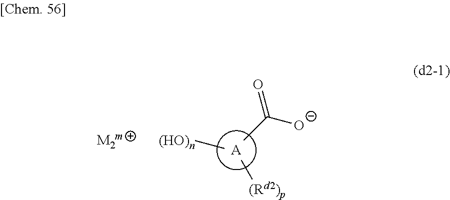

[n the general formula (d2-1), ring A represents a monocyclic aromatic hydrocarbon group or a polycyclic aromatic hydrocarbon group, R^{d2} represents a substituent other than a hydroxy group, p represents an integer of 0 to 3, a plurality of R^{d2}'s may be the same as or different from each other when p represents 2 or 3, n represents an integer of 2 or more, m represents an integer of 1 or more, and M₂^{m+} represents an m-valent organic cation.]

In the general formula (d2-1), ring A represents a monocyclic aromatic hydrocarbon group or a polycyclic aromatic hydrocarbon group.

In the general formula (d2-1), the monocyclic aromatic hydrocarbon group or polycyclic aromatic hydrocarbon group (hereinafter, referred to as aromatic hydrocarbon group) represented by ring A is a hydrocarbon group having at least one aromatic ring, and the aromatic ring is not particularly limited as long as it is a cyclic conjugated system having 4n+2 π electrons, and may be monocyclic or polycyclic. The number of carbon atoms of the aromatic hydrocarbon group is preferably 5 to 30, more preferably 5 to 20, still more preferably 6 to 15, and particularly preferably 6 to 12.

Specific examples of the aromatic hydrocarbon group represented by ring A include an aromatic hydrocarbon ring such as benzene, naphthalene, anthracene, and phenanthrene; and an aromatic heterocyclic ring in which a part of carbon atoms constituting the aromatic hydrocarbon ring is replaced by a heteroatom. Examples of the heteroatom in the aromatic heterocyclic ring include an oxygen atom, a sulfur atom, and a nitrogen atom. Specific examples of the aromatic heterocyclic ring include a pyridine ring and a thiophene ring.

Ring A is preferably an aromatic hydrocarbon ring, more preferably benzene, naphthalene, or anthracene, and particularly preferably benzene or naphthalene, since the effects of the present invention are further improved.

In the general formula (d2-1), R^{d2} represents a substituent other than a hydroxy group, and examples of the substituent include a hydrocarbon group, an alkoxy group, an acyl group, and a hydroxyalkyl group.

Examples of the hydrocarbon group as the substituent include a linear or branched alkyl group, an aliphatic cyclic hydrocarbon group, and an aromatic hydrocarbon group.

The linear or branched alkyl group is preferably a linear or branched alkyl group having 1 to 5 carbon atoms, and specific examples thereof include a methyl group, an ethyl group, a propyl group, an n-butyl group, a tert-butyl group, and a pentyl group.

The aliphatic cyclic hydrocarbon group is preferably an aliphatic cyclic hydrocarbon group having 3 to 6 carbon atoms, and specific examples thereof include a cyclopropyl group, a cyclobutyl group, a cyclopentyl group, and a cyclohexyl group.

The aromatic hydrocarbon group is preferably an aromatic hydrocarbon group having 6 to 30 carbon atoms, and specific examples thereof include a group in which one hydrogen atom is removed from an aromatic hydrocarbon ring such as benzene, biphenyl, fluorene, naphthalene, anthracene, or phenanthrene. Among them, a group in which one hydrogen atom is removed from benzene (phenyl group) is more preferred.

The alkoxy group as the substituent is preferably an alkoxy group having 1 to 5 carbon atoms, and specific examples thereof include a methoxy group, an ethoxy group, a propoxy group, an n-butoxy group, a tert-butoxy group, and a pentyloxy group. Among them, a methoxy group is more preferred.

The acyl group as the substituent is preferably an acyl group having 1 to 3 carbon atoms, and specific examples thereof include a formyl group, an acetyl group, and a propionyl group.

The hydroxyalkyl group as the substituent is preferably a hydroxyalkyl group having 1 to 5 carbon atoms, and specific examples thereof include a hydroxymethyl group, a hydroxyethyl group, a hydroxypropyl group, a hydroxybutyl group, and a hydroxypentyl group.

In the general formula (d2-1), p represents an integer of 0 to 3, and is preferably an integer of 0 to 2, more preferably 0 or 1, and still more preferably 0.

In the general formula (d2-1), n represents an integer of 2 or more, and is preferably an integer of 2 to 6, more preferably an integer of 2 to 4, still more preferably 2 or 3, and particularly preferably 2.

### {Cation Moiety}

In the general formula (d2-1), m is an integer of 1 or more, and M₂^{m+} is an m-valent organic cation.

Suitable examples of the organic cation of M₂^{m+} include those same as a cation represented by any one of the general formulae (ca-1) to (ca-3), and a cation represented by the general formula (ca-1) is more preferred, a cation represented by any one of the general formulae (ca-1-1) to (ca-1-70) is still more preferred, a cation represented by any one of the (ca-1-1) to (ca-1-8) is even more preferred, and a cation represented by the (ca-1-1) is even still more preferred.

Among the above, the compound (d2-1) is preferably a compound (d2-2) represented by the following general formula (d2-2) (hereinafter, also referred to as “component (D2-2)”).

That is, in the resist composition according to the embodiment of the present invention, the compound (d2-1) represented by the general formula (d2-1) is preferably the compound (d2-2) represented by the following general formula (d2-2).

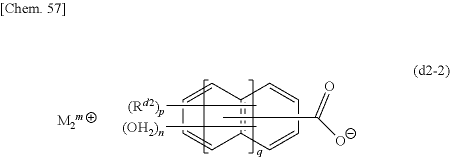

[In the general formula (d2-2), R^{d2} represents a substituent other than a hydroxy group, p represents an integer of 0 to 3, and a plurality of R^{d2}'s may be the same as or different from each other when p represents 2 or 3, q represents 0 or 1, n represents an integer of 2 or more, m represents an integer of 1 or more, M₂^{m+}. represents an m-valent organic cation. n+p≤(q×2)+5).]

In the general formula (d2-2), R^{d2}, p, n, M₂^{m+}, and m are the same as R^{d2}, p, n, M₂^{m+}, and m in the compound (d2-1), respectively, and the preferred ones are also the same.

In the general formula (d2-2), q represents 0 or 1. In the anion moiety in the formula (d2-1), when q is 0, the anion moiety is a benzene structure, and when q is 1, the anion moiety is a naphthalene structure.

### {Cation Moiety}

In the general formula (b2-2), M^{m+} represents an m-valent organic cation. The symbol m is an integer of 1 or more.

Suitable examples of the organic cation include those same as the cation described in the general formula (d2-1).

In the resist composition of the present embodiment, the compound (d2-2) is preferably a compound represented by the following general formula (d2-3), which is composed of an anion moiety and a cation moiety (hereinafter, also referred to as “component (D2-3)”).

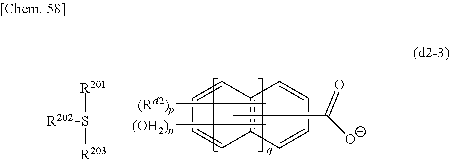

[In the general formula (d2-3), R^{d2} represents a substituent other than a hydroxy group, p represents an integer of 0 to 3, and a plurality of R^{d2}'s may be the same as or different from each other when p represents 2 or 3, q represents 0 or 1, and n represents an integer of 2 or more. R²⁰¹ to R²⁰³ each independently represent an aryl group that may include a substituent, an alkyl group that may include a substituent, or an alkenyl group that may include a substituent. R²⁰¹ to R²⁰³ may be bonded to each other to form a ring together with the sulfur atom in the formula. n+p≤(q×2)+5).]

In the general formula (d2-3), R^{d2}, p, q, and n are the same as R, p, q, and n in the compound (d2-2), respectively, and the preferred ones are also the same.

In the general formula (d2-3), R²⁰¹ to R²⁰³ are the same as R²⁰¹ to R²⁰³ in the general formula (ca-1), respectively, and the preferred ones are also the same.

Preferred specific examples of the anion moiety in the general formulae (d2-1) to (d2-3) are shown below.

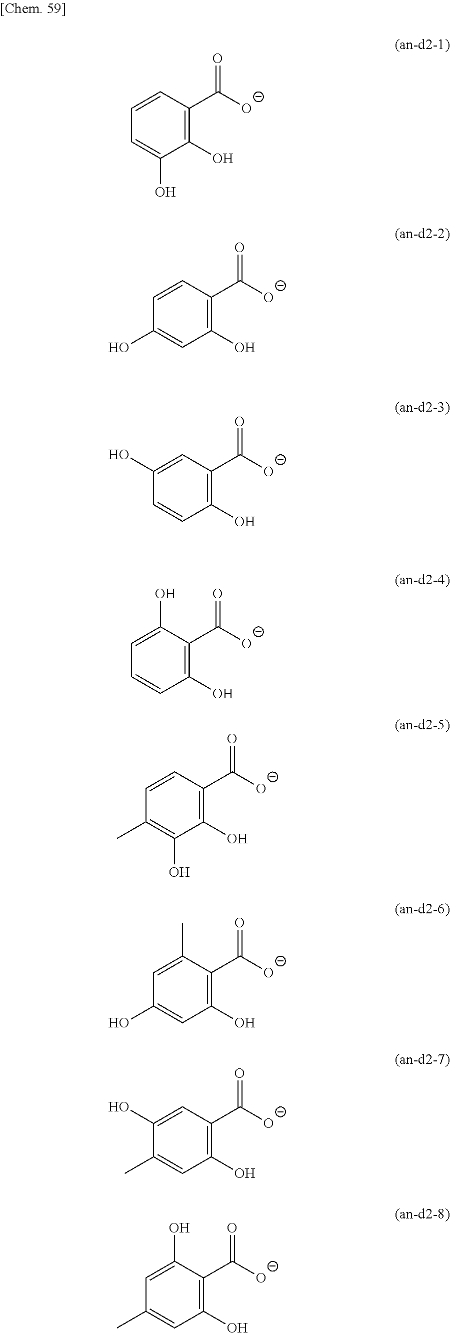

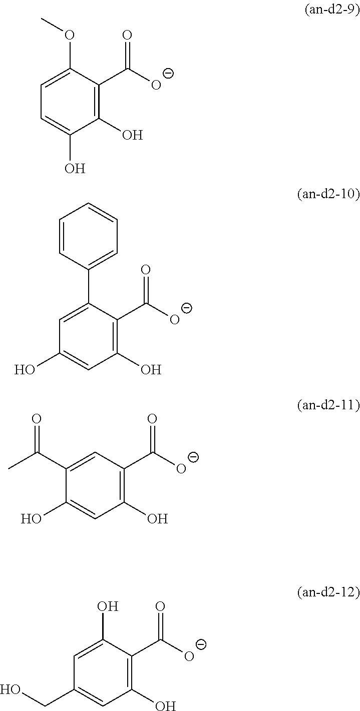

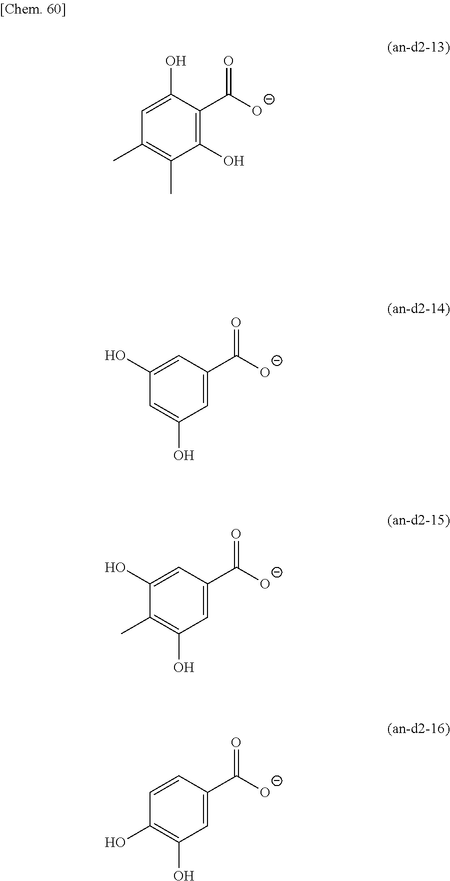

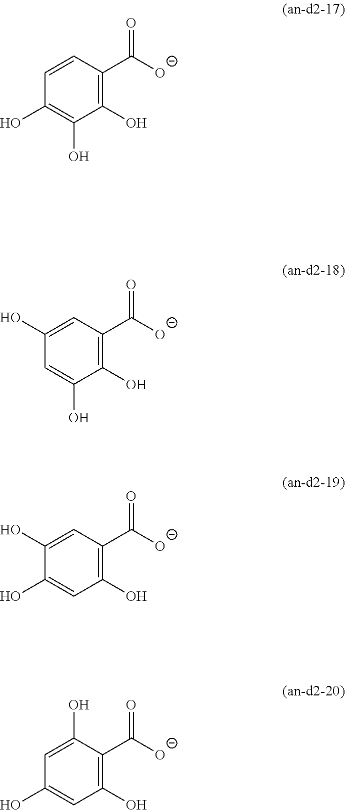

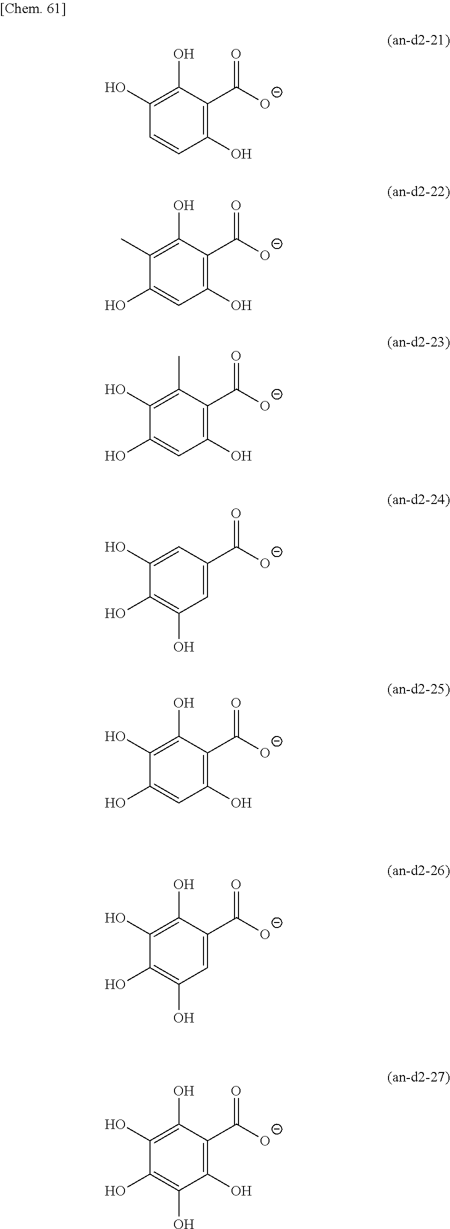

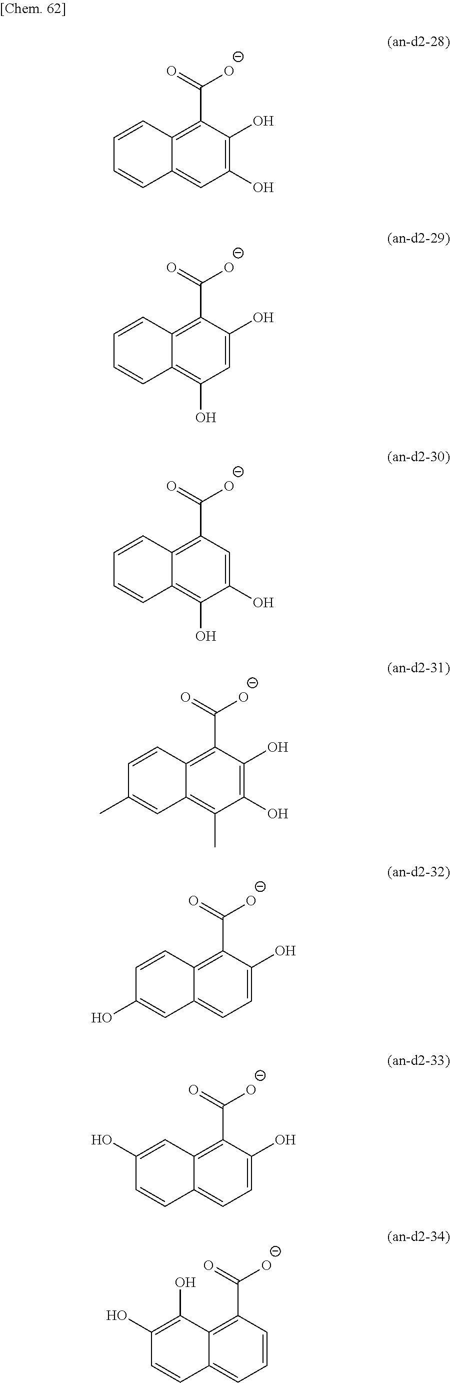

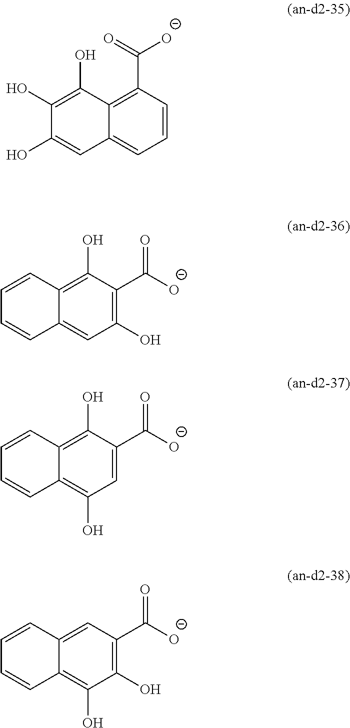

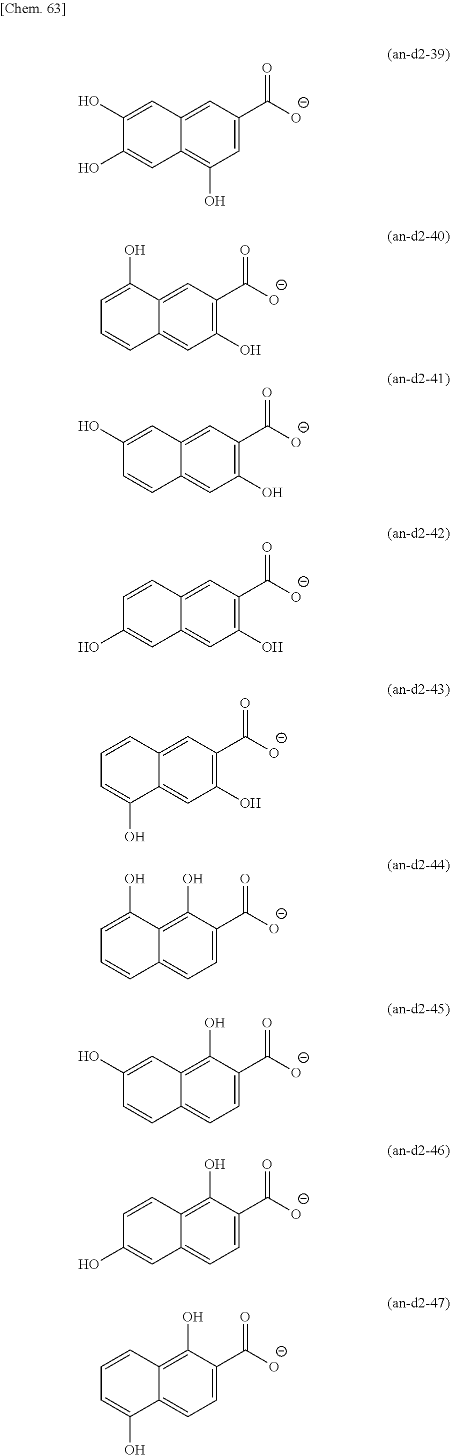

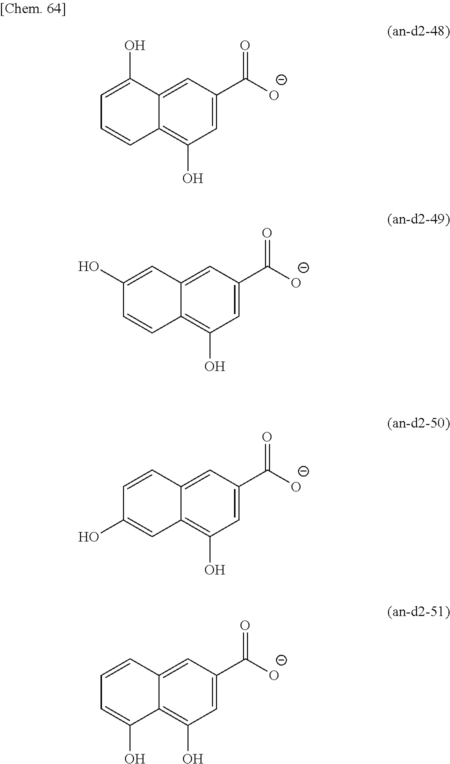

Among the above examples, the anion moiety in the component (D2) is more preferably an anion represented by any one of the chemical formulae (an-d2-1) to (an-d2-27) and (an-d2-36) to (an-d2-51), and still more preferably an anion represented by any one of the chemical formulae (an-d2-1) to (an-d2-20), (an-d2-36), (an-d2-37), and (an-d2-40).

In the resist composition of the present embodiment, the compound (d2-1) may be used alone or in combination of two or more kinds thereof.

In the resist composition of the present embodiment, a content of the compound (d2-1) is preferably 0.1 parts by mass to 15 parts by mass, more preferably 1 part by mass to 12 parts by mass, and still more preferably 2 parts by mass to 10 parts by mass, with respect to 100 parts by mass of the component (A).

When the content of the compound (d2-1) is equal to or larger than the preferred lower limit value, better lithography properties are easily obtained. On the other hand, when the content of the compound (d2-1) is equal to or less than the preferred upper limit value, the liquid developer solubility can be appropriately ensured, and thus the effect of the present invention can be more easily obtained.

In the resist composition of the present embodiment, a total content of the compound (d1-1) and the compound (d2-1) is preferably 1 part by mass to 40 parts by mass, more preferably 3 parts by mass to 30 parts by mass, and still more preferably 5 parts by mass to 25 parts by mass, with respect to 100 parts by mass of the component (A).

When the total content of the compound (d1-1) and the compound (d2-1) is equal to or larger than the preferred lower limit value, better lithography properties are easily obtained. On the other hand, when the total content of the compound (d1-1) and the compound (d2-1) is equal to or less than the preferred upper limit value, the sensitivity can be better maintained and the throughput can also be improved.

In the resist composition of the present embodiment, a mass ratio of the content of the compound (d1-1) to the content of the compound (d2-1) (compound (d1-1):compound (d2-1)) is preferably 1:3 to 3:1, and more preferably 1:2 to 2:1.

In the resist composition of the present embodiment, from the viewpoint of improving sensitivity, it is preferable that the content of the compound (d1-1) be greater than the content of the compound (d2-1). On the other hand, from the viewpoint of improving the roughness reduction property, it is preferable that the content of the compound (d2-1) be greater than the content of the compound (d1-1). More specifically, from the viewpoint of improving sensitivity, it is preferable that 1<(d1-1)/(d2-1)<4, and it is more preferable that 1<(d1-1)/(d2-1)<3. On the other hand, from the viewpoint of improving the roughness reduction property, it is preferable that 1<(d2-1)/(d1-1)<4, and it is more preferable that 1<(d2-1)/(d1-1)<3.

### <Other Components>

The resist composition of the present embodiment may further contain other components, in addition to the above component (A), component (B), component (D1), and component (D2). Examples of the other components include the following component (D3), component (D4), component (E), component (F), and component (S).

The component (D1), component (D2), component (D3), and component (D4) may be used as an acid generating agent in addition to the component (B) or in place of the component (B).

### <<Component (D3)>>

The resist composition of the present embodiment may further contain acid diffusion control components (the component (D3) and the component (D4)) other than the above component (D1) and component (D2).

The component (D3) is not particularly limited as long as it is decomposed upon exposure and loses acid diffusion controllability, and is preferably one or more compounds selected from the group consisting of a compound represented by the following general formula (d3-1) (hereinafter, referred to as “component (d3-1)”), a compound represented by the following general formula (d3-2) (hereinafter, referred to as “component (d3-2)”), and a compound represented by the following general formula (d3-3) (hereinafter, referred to as “component (d3-3)”).

The components (d3-1) to (d3-3) do not act as a quencher in an exposed portion of the resist film because they are decomposed and lose acid diffusion controllability (basicity), but act as a quencher in an unexposed portion of the resist film.

In the compound represented by the following general formula (d3-1) or general formula (d3-2), compounds corresponding to the compound (D1) and the compound (D2) described above are excluded.

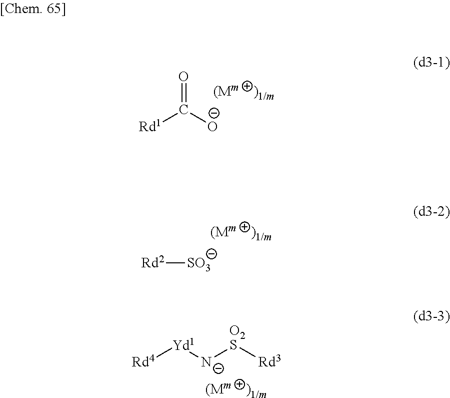

[In the formulae, Rd¹ to Rd⁴ represent a cyclic group that may include a substituent, a chain alkyl group that may include a substituent, or a chain alkenyl group that may include a substituent. In Rd² in the formula (d3-2), no fluorine atom is bonded to a carbon atom adjacent to an S atom, Yd¹ represents a single bond or a divalent linking group, m represents an integer of 1 or more, and M^{m+}'s each independently represent an m-valent organic cation.]

{Component (d3-1)}

### Anion Moiety

In the formula (d3-1), Rd¹ represents a cyclic group that may include a substituent, a chain alkyl group that may include a substituent, or a chain alkenyl group that may include a substituent, and examples thereof is the same as the examples of R′²⁰¹ described above.

Among them, as Rd¹, an aromatic hydrocarbon group that may include a substituent, an aliphatic cyclic group that may include a substituent, and a chain alkyl group that may include a substituent are preferred. Examples of the substituent which these groups may have include a hydroxy group, an oxo group, an alkyl group, an aryl group, a fluorine atom, a fluorinated alkyl group, a lactone-containing cyclic group represented by any one of the general formulae (a2-r-1) to (a2-r-7), an ether bond, an ester bond, or a combination thereof. When an ether bond or an ester bond is contained as the substituent, an alkylene group may be interposed, and as the substituent in this case, a linking group represented by any one of the formulae (y-al-1) to (y-al-5) is preferred. When the aromatic hydrocarbon group, aliphatic cyclic group, or chain alkyl group in R^{d1} has a linking group represented by any one of the general formulae (y-al-1) to (y-al-7) as the substituent, in the general formulae (y-al-1) to (y-al-7), V′¹⁰¹ in the general formulae (y-al-1) to (y-al-7) is bonded to a carbon atom constituting the aromatic hydrocarbon group, aliphatic cyclic group, or chain alkyl group in R^{d1} in the formula (d3-1).

Suitable examples of the aromatic hydrocarbon group include a phenyl group, a naphthyl group, and a polycyclic structure containing a bicyclooctane skeleton (a polycyclic structure consisting of a bicyclooctane skeleton and other ring structures).

The aliphatic cyclic group is more preferably a group in which one or more hydrogen atoms are removed from a polycycloalkane such as adamantane, norbornane, isobornane, tricyclodecane, or tetracyclododecane.

The chain alkyl group preferably has 1 to 10 carbon atoms. Specific examples thereof include a linear alkyl group such as a methyl group, an ethyl group, a propyl group, a butyl group, a pentyl group, a hexyl group, a heptyl group, an octyl group, a nonyl group, and a decyl group; and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

When the chain alkyl group is a fluorinated alkyl group having a fluorine atom or a fluorinated alkyl group as a substituent, the number of carbon atoms of the fluorinated alkyl group is preferably 1 to 11, more preferably 1 to 8, and still more preferably 1 to 4. The fluorinated alkyl group may contain an atom other than a fluorine atom. Examples of the atom other than a fluorine atom include an oxygen atom, a sulfur atom, and a nitrogen atom.

Preferred specific examples of the anion moiety of the component (d3-1) are shown below.

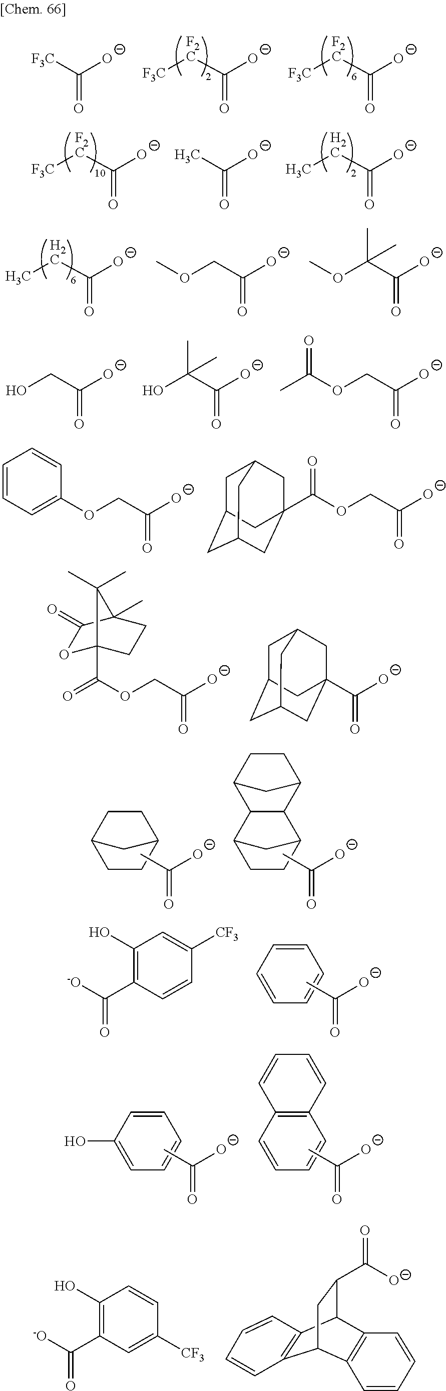

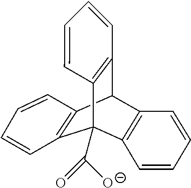 [SMILES: O=C([O-])C12c3ccccc3C(c3ccccc31)c1ccccc12]

### Cation Moiety

In the formula (d3-1), M^{m+} represents an m-valent organic cation.

Suitable examples of the organic cation of M^{m+} include those same as a cation represented by any one of the general formulae (ca-1) to (ca-3), and a cation represented by the general formula (ca-1) is more preferred, a cation represented by any one of the general formulae (ca-1-1) to (ca-1-70) is still more preferred, a cation represented by any one of the (ca-1-1) to (ca-1-8) is even more preferred, and a cation represented by the (ca-1-1) is even still more preferred.

The component (d3-1) may be used alone or in combination of two or more kinds thereof.

{Component (d3-2)}

### Anion Moiety

In the formula (d3-2), Rd² represents a cyclic group that may include a substituent, a chain alkyl group that may include a substituent, or a chain alkenyl group that may include a substituent, and examples thereof is the same as the examples of R′²⁰¹ described above.

In Rd², the carbon atom adjacent to the S atom does not have a fluorine atom bonded thereto (is not replaced by fluorine). Accordingly, the anion of the component (d3-2) becomes an appropriate weak acid anion, and a quenching ability is improved.

Rd² is preferably a chain alkyl group that may include a substituent, or an aliphatic cyclic group that may include a substituent. The chain alkyl group preferably has 1 to 10 carbon atoms, and more preferably has 3 to 10 carbon atoms. The aliphatic cyclic group is more preferably a group (that may include a substituent) in which one or more hydrogen atoms are removed from adamantane, norbornane, isobornane, tricyclodecane, tetracyclododecane, or the like; or a group in which one or more hydrogen atoms are removed from camphor, or the like.

The hydrocarbon group of Rd² may include a substituent, and examples of the substituent include those same as substituents which the hydrocarbon group (the aromatic hydrocarbon group, the aliphatic cyclic group, or the chained alkyl group) in Rd¹ in the formula (d3-1) may have.

Preferred specific examples of the anion moiety of the component (d3-2) are shown below.

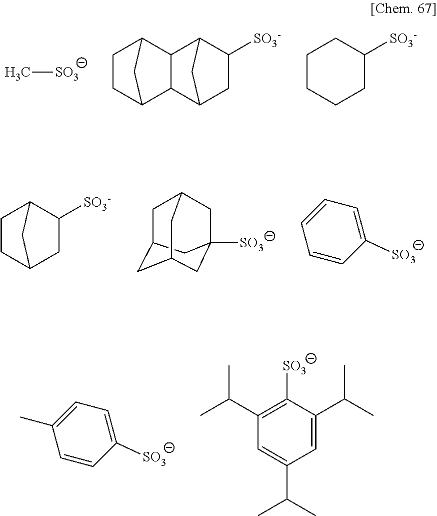

### Cation Moiety

In the formula (d3-2), M^{m+} represents an m-valent organic cation, and is the same as M^{m+} in the formula (d3-1).

The component (d3-2) may be used alone or in combination of two or more kinds thereof.

{Component (d3-3)}

### Anion Moiety

In the formula (d3-3), Rd³ represents a cyclic group that may include a substituent, a chain alkyl group that may include a substituent, or a chain alkenyl group that may include a substituent, examples thereof are the same as R′²⁰¹ described above, and a fluorine atom-containing cyclic group, a chain alkyl group, or a chain alkenyl group is preferred. Among them, a fluorinated alkyl group is preferred, and a fluorinated alkyl group same as those described above for Rd¹ is more preferred.

In the formula (d3-3), Rd⁴ represents a cyclic group that may include a substituent, a chain alkyl group that may include a substituent, or a chain alkenyl group that may include a substituent, and examples thereof are the same as the examples of R′²⁰¹ described above.

The alkyl group in Rd⁴ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. A part of hydrogen atoms of the alkyl group of Rd⁴ may be replaced by a hydroxy group, a cyano group, or the like.

Examples of the alkenyl group in Rd⁴ include those same as the alkenyl group in R′²⁰¹, and a vinyl group, a propenyl group (an allyl group), a 1-methylpropenyl group, and a 2-methylpropenyl group are preferred. These groups may further have an alkyl group having 1 to 5 carbon atoms or a halogenated alkyl group having 1 to 5 carbon atoms as a substituent.

Examples of the cyclic group in Rd⁴ include those same as the cyclic group in R′²⁰¹. The cyclic group in Rd⁴ is preferably an alicyclic group in which one or more hydrogen atoms are removed from a cycloalkane such as cyclopentane, cyclohexane, adamantane, norbornane, isobornane, tricyclodecane, or tetracyclododecane, or an aromatic group such as a phenyl group or a naphthyl group. When Rd⁴ is an alicyclic group, the resist composition has a good solubility in an organic solvent, and thus the lithography properties become excellent. When Rd⁴ is an aromatic group, the resist composition has an excellent light absorption efficiency, a good sensitivity, and good lithography properties in lithography using EUV or the like as a light source for exposure.

In the formula (d3-3), Yd¹ represents a single bond or a divalent linking group. The divalent linking group in Yd¹ is not particularly limited, and examples thereof include a divalent hydrocarbon group (an aliphatic hydrocarbon group, an aromatic hydrocarbon group) that may include a substituent, and a divalent linking group containing a heteroatom. Examples of these groups include those same as the divalent hydrocarbon group that may include a substituent and the divalent linking group containing a heteroatom, which are described in the description of the divalent linking group represented by Ya²¹ in the formula (a2-1).

Yd¹ is preferably a carbonyl group, an ester bond, an amide bond, an alkylene group, or a combination thereof. The alkylene group is more preferably a linear or branched alkylene group, and still more preferably a methylene group or an ethylene group.

Preferred specific examples of the anion moiety of the component (d3-3) are shown below.

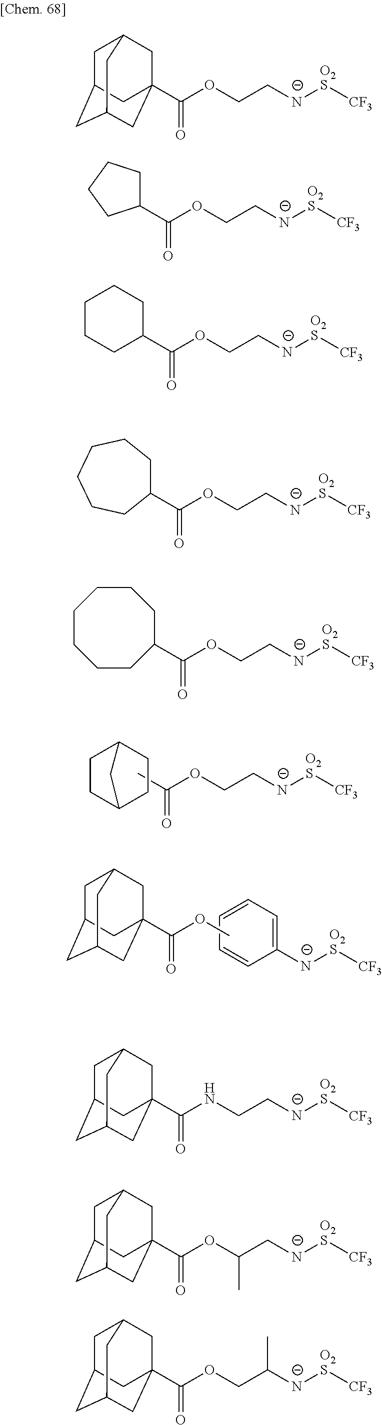

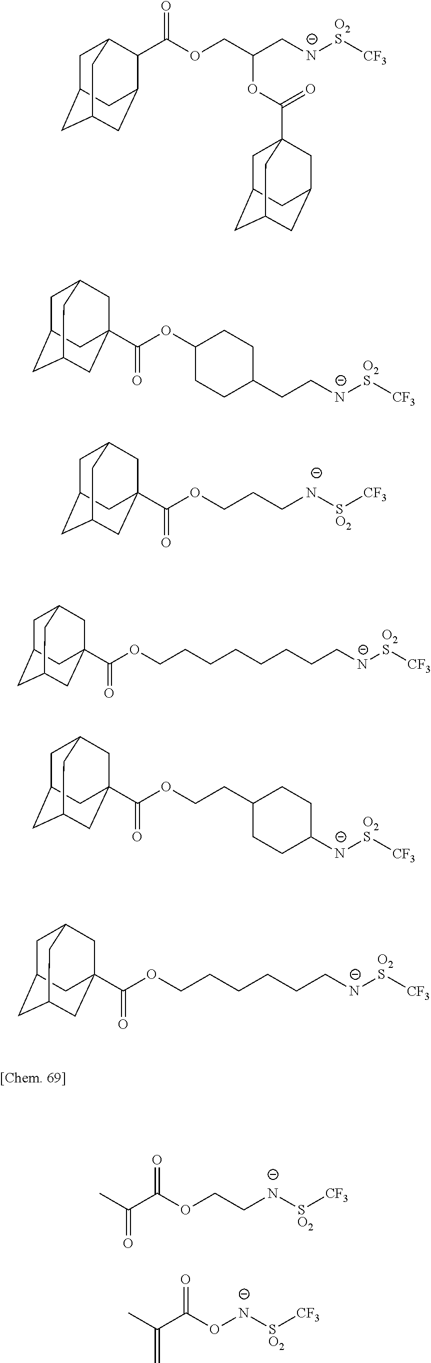

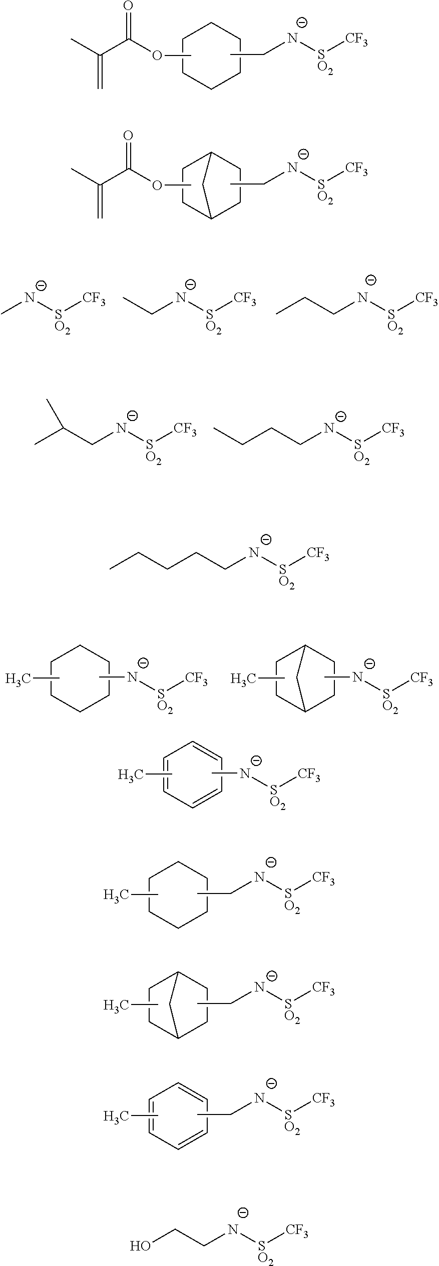

### Cation Moiety

In the formula (d3-3), M^{m+} represents an m-valent organic cation, and is the same as M^{m+} in the formula (d3-1).

The component (d3-3) may be used alone or in combination of two or more kinds thereof.

As the component (D3), only one kind of the components (d3-1) to (d3-3) may be used, or two or more kinds thereof may be used in combination.

When the resist composition contains the component (D3), a content of the component (D3) in the resist composition is preferably 0.1 parts by mass to 20 parts by mass, more preferably 0.5 parts by mass to 15 parts by mass, and still more preferably 1 part by mass to 10 parts by mass, with respect to 100 parts by mass of the component (A).

### Method for Producing Component (D3):

A method for producing the component (d3-1) and the component (d3-2) is not particularly limited, and the component (d3-1) and the component (d3-2) can be produced by known methods.

A method for producing the component (d3-3) is not particularly limited, and the component (d3-3) can be produced, for example, in the same manner as a method described in US2012-0149916.

### Regarding Component (D4)

The component (D4) may contain a nitrogen-containing organic compound component (hereinafter, referred to as “component (D4)”) that does not fall under the above components (D1) to (D3).

The component (D4) is not particularly limited as long as it acts as an acid diffusion control agent and does not fall under the above components (D1) to (D3), and any known compounds may be used. Among them, an aliphatic amine is preferred, and among them, a secondary aliphatic amine and a tertiary aliphatic amine are particularly preferred.

The aliphatic amine is an amine having one or more aliphatic groups, and the aliphatic group preferably has 1 to 12 carbon atoms.

Examples of the aliphatic amine include an amine in which at least one hydrogen atom of ammonia NH₃ is replaced by an alkyl group or a hydroxyalkyl group having 12 or less carbon atoms (an alkyl amine or an alkyl alcohol amine), and a cyclic amine.

Specific examples of the alkyl amine and the alkyl alcohol amine include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among them, trialkylamine having 5 to 10 carbon atoms is more preferred, and tri-n-pentyl amine or tri-n-octyl amine is particularly preferred.

Examples of the cyclic amine include a heterocyclic compound containing a nitrogen atom as a heteroatom. The heterocyclic compound may be a monocyclic compound (an aliphatic monocyclic amine) or a polycyclic compound (an aliphatic polycyclic amine).

Specific examples of the aliphatic monocyclic amine include piperidine and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine, and triethanolamine triacetate. Triethanolamine triacetate is preferred.

As the component (D4), an aromatic amine may be used.

Examples of the aromatic amine include 4-dimethylaminopyridine, pyrrole, indole, pyrazole, imidazole or derivatives thereof, tribenzylamine, 2,6-diisopropylaniline, and N-tert-butoxycarbonylpyrrolidine.

The component (D4) may be used alone or in combination of two or more kinds thereof.

When the resist composition contains the component (D4), a content of the component (D4) in the resist composition is generally in a range of 0.01 parts by mass to 5 parts by mass with respect to 100 parts by mass of the component (A). When the content is within the range, the resist pattern shape and the storage stability over time are improved.

<<At Least One Compound (E) Selected from Group Consisting of Organic Carboxylic Acid, and Phosphorus Oxoacid and Derivative Thereof>>

The resist composition of the present embodiment may contain at least one compound (E) (hereinafter, referred to as “component (E)”) selected from the group consisting of an organic carboxylic acid, and a phosphorus oxoacid and a derivative thereof as an optional component for the purpose of preventing deterioration in sensitivity, and improving the shape of a resist pattern, the storage stability over time, and the like.

Specific examples of the organic carboxylic acid include acetic acid, malonic acid, citric acid, malic acid, succinic acid, benzoic acid, and salicylic acid, and among them, salicylic acid is preferred.

Examples of the phosphorus oxoacid include phosphoric acid, phosphonic acid, and phosphinic acid. Among them, phosphonic acid is particularly preferred.

Examples of the derivative of phosphorus oxoacid include an ester in which a hydrogen atom of an oxo acid is replaced by a hydrocarbon group, and examples of the hydrocarbon group include an alkyl group having 1 to 5 carbon atoms and an aryl group having 6 to 15 carbon atoms.

Examples of the derivative of phosphoric acid include phosphate esters such as di-n-butyl phosphate and diphenyl phosphate.

Examples of the derivative of phosphonic acid include phosphonate esters such as dimethyl phosphonate, di-n-butyl phosphonate, phenyl phosphonic acid, diphenyl phosphonate, and dibenzyl phosphonate.

Examples of the derivative of phosphinic acid include phosphinate esters and phenylphosphinic acid.

In the resist composition of the present embodiment, the component (E) may be used alone or in combination of two or more kinds thereof.

When the resist composition contains the component (E), a content of the component (E) is preferably 0.01 parts by mass to 5 parts by mass, and more preferably 0.05 parts by mass to 3 parts by mass, with respect to 100 parts by mass of the component (A). When the content of the component (E) is within the above range, the sensitivity and lithography properties are improved.

### <<Fluorine Additive Component (F)>>

The resist composition of the present embodiment may contain a fluorine additive component (hereafter, referred to as “component (F)”) in order to impart water repellency to the resist film or to improve lithography properties.

As the component (F), for example, fluorinated high molecular weight compounds described in JP2010-002870A, JP2010-032994A, JP2010-277043A, JP2011-13569A, and JP2011-128226A can be used.

More specific examples of the component (F) include a polymer including a structural unit (f1) represented by the following general formula (f1-1). The polymer is preferably a polymer (a homopolymer) consisting only of the structural unit (f1) represented by the following formula (f1-1); a copolymer of the structural unit (f1) and the structural unit (a1); or a copolymer of the structural unit (f1), a structural unit derived from acrylic acid or methacrylic acid, and the structural unit (a1), and is more preferably a copolymer of the structural unit (f1) and the structural unit (a1). Here, the structural unit (a1) that is copolymerized with the structural unit (f1) is preferably a structural unit derived from 1-ethyl-1-cyclooctyl(meth)acrylate or a structural unit derived from 1-methyl-1-adamantyl(meth)acrylate, and more preferably a structural unit derived from 1-ethyl-1-cyclooctyl(meth)acrylate.

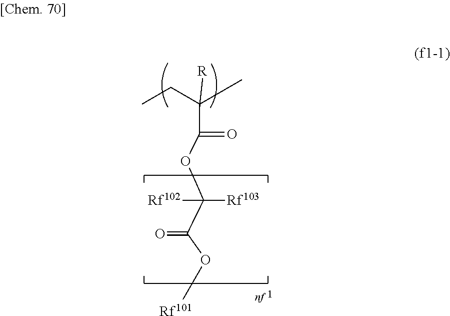

[In the formula, R is the same as described above, Rf¹⁰² and Rf¹⁰³ each independently represent a hydrogen atom, a halogen atom, an alkyl group having 1 to 5 carbon atoms, or a halogenated alkyl group having 1 to 5 carbon atoms. Rf¹⁰² and Rf¹⁰³ may be the same as or different from each other, nf¹ is an integer of 0 to 5, and Rf¹⁰¹ is an organic group containing a fluorine atom.]

In the formula (f1-1), R bonded to a carbon atom at the α-position is the same as defined above. R is preferably a hydrogen atom or a methyl group.

In the formula (f1-1), the halogen atom of Rf¹⁰² and Rf¹⁰³ is preferably a fluorine atom. Examples of the alkyl group having 1 to 5 carbon atoms of Rf¹⁰² and Rf¹⁰³ include those same as the alkyl group having 1 to 5 carbon atoms for the above R, and a methyl group or an ethyl group is preferred. Specific examples of the halogenated alkyl group having 1 to 5 carbon atoms for Rf¹⁰² and Rf¹⁰³ include a group in which a part or all of hydrogen atoms of the alkyl group having 1 to 5 carbon atoms are replaced by halogen atoms. The halogen atom is preferably a fluorine atom. Among them, as Rf¹⁰² and Rf¹⁰³, a hydrogen atom, a fluorine atom, or an alkyl group having 1 to 5 carbon atoms is preferred, a hydrogen atom, a fluorine atom, a methyl group, or an ethyl group is more preferred, and a hydrogen atom is still more preferred.

In the formula (f1-1), nf¹ represents an integer of 0 to 5, preferably an integer of 0 to 3, and more preferably 1 or 2.

In the formula (f1-1), Rf¹⁰¹ represents an organic group containing a fluorine atom, and is preferably a hydrocarbon group containing a fluorine atom.

The hydrocarbon group containing a fluorine atom may be any of a linear group, branched group, and cyclic group, and preferably has 1 to 20 carbon atoms, more preferably has 1 to 15 carbon atoms, and particularly preferably has 1 to 10 carbon atoms.

In the hydrocarbon group containing a fluorine atom, it is preferable that 25% or more of hydrogen atoms in the hydrocarbon group be fluorinated, it is more preferable that 50% or more of hydrogen atoms be fluorinated, and it is particularly preferable that 60% or more of hydrogen atoms be fluorinated, since hydrophobicity of the resist film during immersion exposure is enhanced.

Among them, Rf¹⁰¹ is more preferably a fluorinated hydrocarbon group having 1 to 6 carbon atoms, and particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

A weight average molecular weight (Mw) of the component (F) (in terms of polystyrene determined by gel permeation chromatography) is preferably 1000 to 50000, more preferably 5000 to 40000, and most preferably 10000 to 30000. When the weight average molecular weight (Mw) is equal to or less than the upper limit value of the range, sufficient solubility in a resist solvent for use as a resist is obtained. When the weight average molecular weight (Mw) is equal to or larger than the lower limit value of the range, the water repellency of the resist film is improved.

A dispersity (Mw/Mn) of the component (F) is preferably 1.0 to 5.0, more preferably 1.0 to 3.0, and most preferably 1.0 to 2.5.

In the resist composition of the present embodiment, the component (F) may be used alone or in combination of two or more kinds thereof.

When the resist composition contains the component (F), a content of the component (F) is preferably 0.5 parts by mass to 10 parts by mass, and more preferably 1 part by mass to 10 parts by mass, with respect to 100 parts by mass of the component (A).

### <Organic Solvent Component (S)>

The resist composition of the present embodiment can be produced by dissolving a resist material in an organic solvent component (hereinafter, referred to as “component (S)”).

As the component (S), those capable of dissolving components to be used to form a uniform solution may be used, and any one can be appropriately selected from those are known in the related art as a solvent for a chemically amplified resist composition.

Examples of the component (S) include lactones such as γ-butyrolactone; ketones such as acetone, methyl ethyl ketone, cyclohexanone, methyl n-pentyl ketone, methyl isopentyl ketone, and 2-heptanone; polyhydric alcohols such as ethylene glycol, diethylene glycol, propylene glycol, and dipropylene glycol; derivatives of polyhydric alcohols such as a compound having an ester bond such as ethylene glycol monoacetate, diethylene glycol monoacetate, propylene glycol monoacetate, or dipropylene glycol monoacetate, and a monoalkyl ether such as monomethyl ether, monoethyl ether, monopropyl ether, and monobutyl ether of the polyhydric alcohols or compounds having an ester bond, or compounds having an ether bond such as monophenyl ether [among them, propylene glycol monomethyl ether acetate (PGMEA), or propylene glycol monomethyl ether PGME is preferred]; cyclic ethers such as dioxane, esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, and mesitylene, and dimethyl sulfoxide (DMSO).

In the resist composition of the present embodiment, the component (S) may be used alone or as a mixed solvent of two or more kinds thereof. Among them, PGMEA, PGME, γ-butyrolactone, EL, and cyclohexanone are preferred.

As the component (S), a mixed solvent of PGMEA and a polar solvent is also preferred. A blending ratio (a mass ratio) thereof may be appropriately determined taking into consideration the compatibility between PGMEA and the polar solvent, and is preferably within a range of 1:9 to 9:1, and more preferably a range of 2:8 to 8:2.

More specifically, when EL or cyclohexanone is blended as the polar solvent, the mass ratio of PGMEA to EL or cyclohexanone is preferably 1:9 to 9:1, and more preferably 2:8 to 8:2. When PGME is blended as the polar solvent, the mass ratio of PGMEA to PGME is preferably 1:9 to 9:1, more preferably 2:8 to 8:2, and still more preferably 3:7 to 7:3. Further, a mixed solvent of PGMEA, PGME, and cyclohexanone is also preferred.

As the component (S), a mixed solvent of γ-butyrolactone and at least one selected from PGMEA and EL is also preferred. In this case, as the mixing proportion, the mass ratio of the former to the latter is preferably 70:30 to 95:5.

An amount of the component (S) to be used is not particularly limited, and is appropriately set according to a coating film thickness at a concentration such that the component (S) can be applied to a substrate or the like. Generally, the component (S) is used such that a solid content concentration of the resist composition is in a range of 0.1 mass % to 20 mass %, and preferably 0.2 mass % to 15 mass %.

The resist composition of the present embodiment may further contain, if desired, compatible additives such as an additional resin, a dissolution inhibitor, a plasticizer, a stabilizer, a colorant, an antihalation agent, or a dye for improving the performance of the resist film.

For the resist composition of the present embodiment, after the resist material is dissolved in the component (S), impurities and the like may be removed using a polyimide porous film, a polyamideimide porous film, or the like. For example, the resist composition may be filtered using a filter made of a polyimide porous film, a filter made of a polyamideimide porous film, or a filter made of a polyimide porous film and a polyamideimide porous film. Examples of the polyimide porous film and the polyamideimide porous film include those described in JP2016-155121A.

The resist composition of the present embodiment described above contains the above compound (D1) and compound (D2).

Since the compound (D2) has a high quenching ability in the unexposed portion of the resist film, the roughness of the resist pattern to be formed can be reduced, but the sensitivity tends to decrease.

On the other hand, since the compound (D1) has a quenching ability in the unexposed portion of the resist film and the anion moiety thereof is sulfonic acid, the compound (D1) generates an acid stronger than that of the compound (D2) in the exposed portion of the resist film, and can promote the deprotection reaction of the component (A) performed by the strong acid generated from the component (B).

By combining the compound (D1) with the compound (D2), for example, the sensitivity can be increased compared to the case of combining a photodegradable base having a carboxylic acid in the anion moiety. In addition, the roughness reduction property is also improved due to the synergistic effect of the compound (D1) and the compound (D2).

As described above, according to the resist composition of the present embodiment, both the sensitivity and the roughness reduction property can be improved.

### (Method for Forming Resist Pattern)

A method for forming a resist pattern according to a second aspect of the present invention is a method including: a step of forming a resist film on a support using the resist composition according to the embodiment of the present invention; a step of exposing the resist film; and a step of developing the resist film to form a resist pattern.

One embodiment of the method for forming a resist pattern includes, for example, a method for forming a resist pattern performed as follows.

First, the resist composition of the embodiment is applied onto a support using a spinner or the like, and a baking treatment (a post apply bake (PAB)) is performed, for example, for 40 seconds to 120 seconds, preferably 50 seconds to 90 seconds under a temperature condition of 80° C. to 150° C. to form a resist film.

Next, the resist film is selectively exposed through a mask (a mask pattern) on which a predetermined pattern is formed, or by direct irradiation with an electron beam without a mask pattern using an exposure apparatus such as an electron beam drawing device or an EUV exposure apparatus, and then a baking treatment (a post-exposure bake (PEB)) is performed, for example, for 40 seconds to 120 seconds, preferably 50 seconds to 90 seconds under a temperature condition of 80° C. to 150° C.

Next, the resist film is subjected to a developing treatment. The developing treatment is performed using an alkaline liquid developer in the case of an alkaline developing process, and using a liquid developer containing an organic solvent (an organic liquid developer) in the case of a solvent developing process.

After the developing treatment, a rinsing treatment is preferably performed. As the rinsing treatment, water rinsing using pure water is preferred in the case of the alkaline developing process, and a rinsing liquid containing an organic solvent is preferably used in the case of the solvent developing process.

In the case of the solvent developing process, after the developing treatment or the rinsing treatment, a process of removing a liquid developer or a rinsing liquid attached to the pattern by a supercritical fluid may be performed.

After the developing treatment or the rinsing treatment, drying is performed. In some cases, a baking treatment (a post bake) may be performed after the developing treatment.

The support is not particularly limited, and any related-art known supports can be used. Examples thereof include a substrate for electronic components or a substrate having a predetermined wiring pattern formed thereon. More specifically, a silicon wafer, a substrate made of a metal such as copper, chromium, iron, or aluminum, a glass substrate, or the like may be used. As a material of the wiring pattern, for example, copper, aluminum, nickel, or gold can be used.

A wavelength used for exposure is not particularly limited, and an ArF excimer laser, a KrF excimer laser, an F₂ excimer laser, extreme ultraviolet (EUV), vacuum ultraviolet (VUV), electron beam (EB), and radiation rays such as X-rays and soft X-rays can be used.

A resist film exposure method may be general exposure (dry exposure) performed in an inert gas such as air or nitrogen, or may be liquid immersion lithography, and liquid immersion lithography is preferred.

The liquid immersion lithography is an exposure method in which a space between a resist film and a lowermost lens of an exposure apparatus is filled with a solvent (a liquid immersion medium) having a refractive index greater than that of air, and exposure (immersion exposure) is then performed in that state.

As the liquid immersion medium, a solvent having a refractive index larger than that of air and smaller than that of a resist film to be exposed is preferred. The refractive index of such a solvent is not particularly limited as long as it is within the range.

Examples of the solvent having a refractive index larger than that of air and smaller than that of the resist film include water, a fluorine inert liquid, a silicon solvent, and a hydrocarbon solvent.

Water is preferably used as the liquid immersion medium.

Examples of the alkaline liquid developer used in the developing treatment in the alkaline developing process include a 0.1 mass % to 10 mass % aqueous solution of tetramethylammonium hydroxide (TMAH).

The organic solvent contained in the organic liquid developer used in the developing treatment in the solvent developing process may be any solvents capable of dissolving the component (A) (the component (A) before exposure), and may be appropriately selected from known organic solvents. Specific examples thereof include polar solvents such as a ketone solvent, an ester solvent, an alcohol solvent, a nitrile solvent, an amide solvent, and an ether solvent, and hydrocarbon solvents.

The ketone solvent is an organic solvent containing C—C(═O)—C or C—C(═O)—H in a structure thereof. The ester solvent is an organic solvent containing C—C(═O)—O—C or H—C(═O)—O—C in a structure thereof. The alcohol solvent is an organic solvent containing an alcoholic hydroxy group in a structure thereof. The term “alcoholic hydroxy group” refers to a hydroxy group bonded to a carbon atom of an aliphatic hydrocarbon group. The nitrile solvent is an organic solvent containing a nitrile group in a structure thereof. The amide solvent is an organic solvent containing an amide group in a structure thereof. The ether solvent is an organic solvent containing C—O—C in a structure thereof.

Among the organic solvents, there is an organic solvent containing a plurality of kinds of functional groups characterizing each of the solvents in the structure, and in this case, the organic solvent corresponds to any kind of solvent containing the functional group of the organic solvent. For example, diethylene glycol monomethyl ether corresponds to both the alcohol solvent and the ether solvent in the classification.

The hydrocarbon solvent is a hydrocarbon solvent composed of a hydrocarbon that may be halogenated and having no substituent other than a halogen atom. Examples of the halogen atom include a chlorine atom, a bromine atom, and an iodine atom, and a fluorine atom is preferred.

Among the solvents described above, the organic solvent contained in the organic liquid developer is preferably the polar solvent, and is preferably the ketone solvent, the ester solvent, the nitrile solvent, or the like.

Examples of the ester solvent include methyl acetate, ethyl acetate, and butyl acetate.

Examples of the nitrile solvent include acetonitrile, propionitrile, valeronitrile, and butyronitrile.

If necessary, known additives may be added to the organic liquid developer. Examples of the additive include a surfactant. The surfactant is not particularly limited, and for example, ionic or nonionic fluorine and/or silicon surfactants can be used.

The developing treatment can be performed by a known developing method, and examples thereof include a method in which a support is immersed with respect to a liquid developer for a certain period of time (a dip method), a method in which a liquid developer is piled up on a surface of a support by surface tension and left standing for a certain period of time (a paddle method), a method in which a liquid developer is sprayed onto a surface of a support (a spray method), a method in which a liquid developer is continuously dispensed by scanning a liquid developer dispense nozzle at a constant speed onto a support that is rotating at a constant speed (a dynamic dispense method).

As the organic solvent contained in the rinsing liquid used in the rinsing treatment after the developing treatment in the solvent developing process, for example, an organic solvent which hardly dissolves the resist pattern can be appropriately selected and used among the organic solvents described above as the organic solvent used in the organic liquid developer. Generally, at least one solvent selected from a hydrocarbon solvent, a ketone solvent, an ester solvent, an alcohol solvent, an amide solvent, and an ether solvent is used.

These organic solvents may be used alone or in combination of two or more kinds thereof. In addition, an organic solvent other than those described above or water may be mixed and used.

The rinsing treatment (a washing treatment) using the rinsing liquid can be performed by a known rinsing method. Examples of the method of the rinsing treatment include a method in which a rinsing liquid is continuously dispensed onto a support that is rotating at a constant speed (a spin dispensing method), a method in which a support is immersed in a rinsing liquid for a certain period of time (a dip method), and a method in which a rinsing liquid is sprayed onto a surface of a support (a spray method).

Various materials used in the resist composition of the embodiment and the method for forming a pattern of the embodiment (for example, a resist solvent, a liquid developer, a rinsing liquid, a composition for forming an antireflection film, a composition for forming a top coat, and the like) preferably does not contain impurities such as a metal, a metal salt containing a halogen, an acid, an alkali, and a component containing a sulfur atom or a phosphorus atom. Here, examples of the impurity containing a metal atom include Na, K, Ca, Fe, Cu, Mn, Mg, Al, Cr, Ni, Zn, Ag, Sn, Pb, Li, and salts thereof. A content of the impurities contained in these materials is preferably 200 ppb or less, more preferably 1 ppb or less, still more preferably 100 ppt (parts per trillion) or less, and particularly preferably 10 ppt or less, and it is most preferable that the impurity be not substantially contained (equal to or less than a detection limit of a measuring device).

According to the method for forming a resist pattern of the present embodiment described above, since the resist composition described above is used, a resist pattern capable of achieving a high sensitivity and having good roughness reduction property can be formed.

### Example 1

The present invention will be described in more detail below with reference to Examples, but the present invention is not limited to these Examples.

### <Production of High Molecular Weight Compound>

A high molecular weight compound (A-1) used in the present Example was obtained by radical polymerization using a monomer for deriving a structural unit constituting a high molecular weight compound (A-1) at a predetermined molar ratio.

A weight average molecular weight (Mw) and a molecular weight dispersity (Mw/Mn) of the obtained high molecular weight compound (A-1) were determined by GPC measurement (in terms of standard polystyrene).

A copolymer composition ratio (a proportion (molar ratio) of each structural unit in the structural formula) of the obtained high molecular weight compound (A-1) was determined by carbon-13 nuclear magnetic resonance spectroscopy (600 MHz_¹³C-NMR).

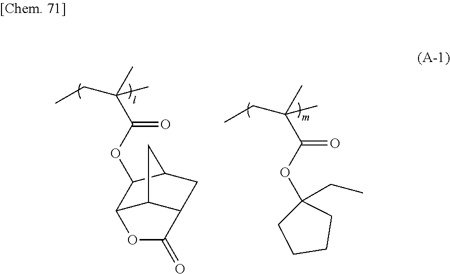

High molecular weight compound (A-1): weight average molecular weight (Mw) 7000, molecular weight dispersion (Mw/Mn) 1.60, l/m=50/50.

### <Preparation of Resist Compositions>

### Examples 1 to 15 and Comparative Examples 1 to 4

The components shown in Table 1 were mixed and dissolved to prepare resist compositions of the respective Examples.

TABLE 1

| | | | Component (B) | | Component (D1) | | Component (D2) | |
|---|---|---|---|---|---|---|---|---|
| | Component (A) | | Acid | | Acid | | Acid | |
| | | Part by | generating | Part by | diffusion | Part by | diffusion | Part by |
| | Resin | mass | agent | mass | inhibitor | mass | inhibitor | mass |
| Example 1 | (A-1) | 100 | (B-1) | 15 | (D1-1) | 4 | (D2-1) | 5 |
| Example 2 | (A-1) | 100 | (B-1) | 15 | (D1-1) | 4 | (D2-2) | 5 |
| Example 3 | (A-1) | 100 | (B-1) | 15 | (D1-1) | 4 | (D2-3) | 5 |
| Example 4 | (A-1) | 100 | (B-1) | 15 | (D1-1) | 4 | (D2-4) | 5 |
| Example 5 | (A-1) | 100 | (B-1) | 15 | (D1-1) | 4 | (D2-5) | 5 |
| Example 6 | (A-1) | 100 | (B-1) | 15 | (D1-1) | 4 | (D2-6) | 5 |
| Example 7 | (A-1) | 100 | (B-1) | 15 | (D1-1) | 4 | (D2-7) | 5 |
| Example 8 | (A-1) | 100 | (B-1) | 15 | (D1-1) | 4 | (D2-8) | 5 |
| Example 9 | (A-1) | 100 | (B-1) | 15 | (D1-1) | 4 | (D2-9) | 5 |
| Example 10 | (A-1) | 100 | (B-1) | 15 | (D1-1) | 4 | (D2-10) | 5 |
| Example 11 | (A-1) | 100 | (B-1) | 15 | (D1-1) | 4 | (D2-11) | 5 |
| Example 12 | (A-1) | 100 | (B-1) | 15 | (D1-2) | 4 | (D2-1) | 5 |
| Example 13 | (A-1) | 100 | (B-1) | 15 | (D1-3) | 4 | (D2-1) | 5 |
| Example 14 | (A-1) | 100 | (B-1) | 15 | (D1-4) | 4 | (D2-1) | 5 |
| Example 15 | (A-1) | 100 | (B-1) | 15 | (D1-5) | 4 | (D2-1) | 5 |
| Comparative | (A-1) | 100 | (B-1) | 15 | (D1-1) | 9 | — | — |
| Example 1 | | | | | | | | |
| Comparative | (A-1) | 100 | (B-1) | 15 | — | — | (D2-1) | 9 |
| Example 2 | | | | | | | | |
| Comparative | (A-1) | 100 | (B-1) | 15 | (D0-1) | 4 | (D2-1) | 5 |
| Example 3 | | | | | | | | |
| Comparative | (A-1) | 100 | (B-1) | 15 | (D1-1) | 4 | (D0-2) | 5 |
| Example 4 | | | | | | | | |

| | Component (F) | | Component (S) | | | |
|---|---|---|---|---|---|---|
| | Hydrophobic | Part by | | Part by | Sensitivity | LWR |
| | resin | mass | Solvent | mass | [mJ/cm²] | [nm] |
| Example 1 | (F-1) | 4 | (S-1) | 3600 | 26.3 | 2.5 |
| Example 2 | (F-1) | 4 | (S-1) | 3600 | 26.5 | 2.5 |
| Example 3 | (F-1) | 4 | (S-1) | 3600 | 26.4 | 2.5 |
| Example 4 | (F-1) | 4 | (S-1) | 3600 | 26.8 | 2.5 |
| Example 5 | (F-1) | 4 | (S-1) | 3600 | 27.2 | 2.6 |
| Example 6 | (F-1) | 4 | (S-1) | 3600 | 27.3 | 2.6 |
| Example 7 | (F-1) | 4 | (S-1) | 3600 | 26.1 | 2.7 |
| Example 8 | (F-1) | 4 | (S-1) | 3600 | 26 | 2.7 |
| Example 9 | (F-1) | 4 | (S-1) | 3600 | 27.3 | 2.5 |
| Example 10 | (F-1) | 4 | (S-1) | 3600 | 27.5 | 2.5 |
| Example 11 | (F-1) | 4 | (S-1) | 3600 | 27.9 | 2.5 |
| Example 12 | (F-1) | 4 | (S-1) | 3600 | 25.4 | 2.5 |
| Example 13 | (F-1) | 4 | (S-1) | 3600 | 23.7 | 2.7 |
| Example 14 | (F-1) | 4 | (S-1) | 3600 | 25.1 | 2.6 |
| Example 15 | (F-1) | 4 | (S-1) | 3600 | 24.8 | 2.7 |
| Comparative | (F-1) | 4 | (S-1) | 3600 | 22.5 | 3.6 |
| Example 1 | | | | | | |
| Comparative | (F-1) | 4 | (S-1) | 3600 | 35 | 2.9 |
| Example 2 | | | | | | |
| Comparative | (F-1) | 4 | (S-1) | 3600 | 23.2 | 3.5 |
| Example 3 | | | | | | |
| Comparative | (F-1) | 4 | (S-1) | 3600 | 28.5 | 2.8 |
| Example 4 | | | | | | |

In Table 1, the abbreviations have the following meanings.

(A-1): The above high molecular weight compound (A-1).

(B-1): An acid generating agent composed of a compound represented by the following chemical formula (B-1).

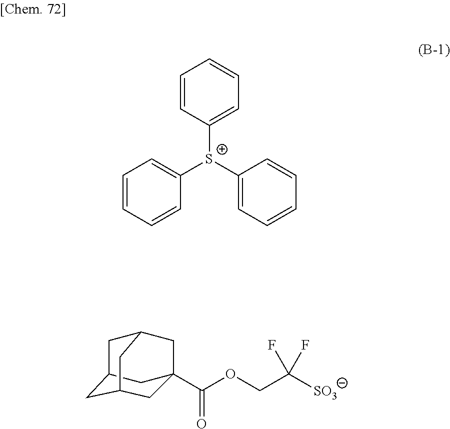

(D1-1) to (D1-5): An acid diffusion control agent having an anion moiety composed of a compound represented by any one of the following chemical formulae (D1-1) to (D1-5) and a cation moiety composed of a compound represented by the following chemical formula (ca-1-1).

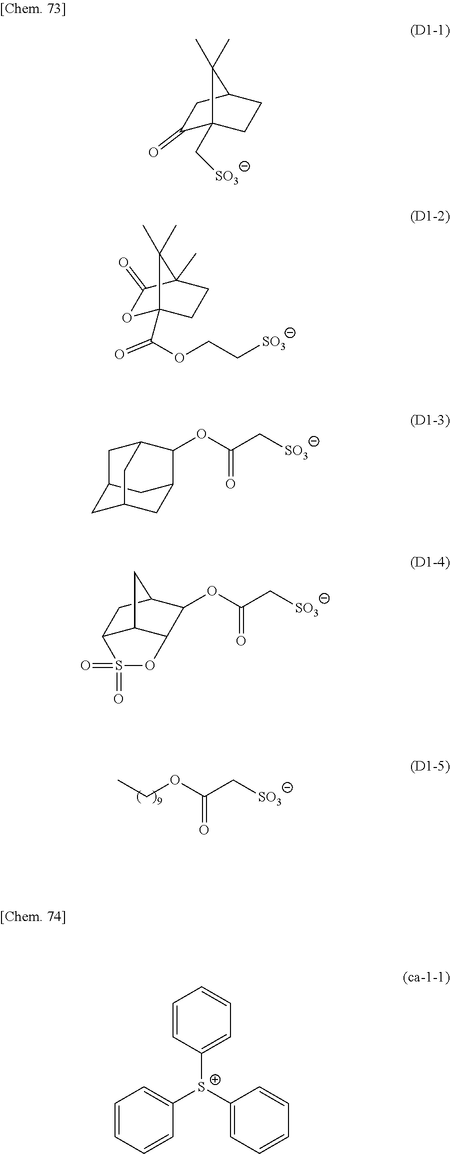

(D2-1) to (D2-11): An acid diffusion control agent having an anion moiety composed of a compound represented by any one of the following chemical formulae (D2-1) to (D2-11) and a cation moiety composed of a compound represented by the following chemical formula (ca-1-1).

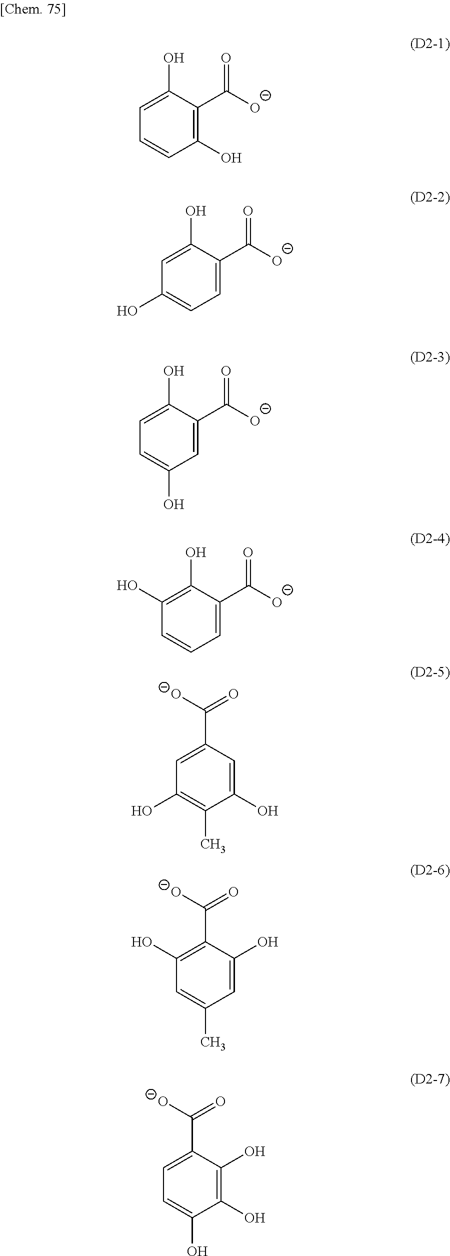

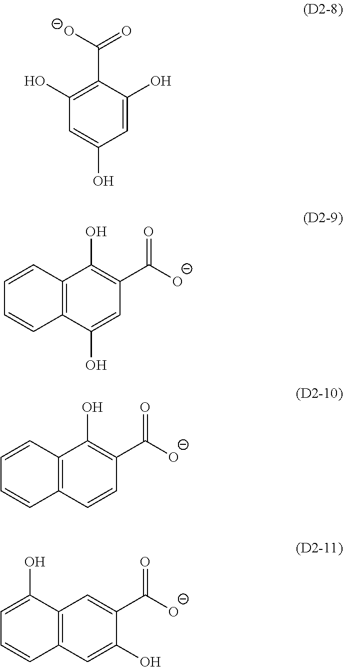 [SMILES: O=C([O-])c1c(O)cc(O)cc1O ; O=C([O-])c1cc(O)c2ccccc2c1O ; O=C([O-])c1ccc2ccccc2c1O ; O=C([O-])c1cc2c(O)cccc2cc1O]

(D0-1) and (D0-2): An acid diffusion control agent composed of a compound represented by any one of the following chemical formulae (D0-1) and (D0-2).

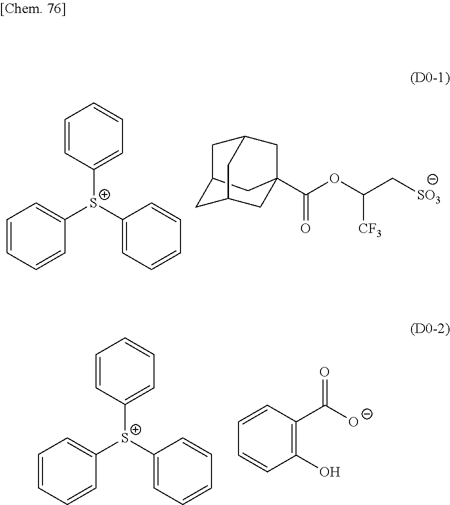

(F-1): A high molecular weight compound represented by the following chemical formula (F-1). A weight average molecular weight (Mw) in terms of standard polystyrene determined by GPC measurement was 25,000, and a molecular weight dispersity (Mw/Mn) in terms of standard polystyrene determined by GPC measurement was 1.50. A copolymer composition ratio (a proportion (a molar ratio) of each structural unit in the structural formula) determined by ¹³C-NMR was l/m=80/20.

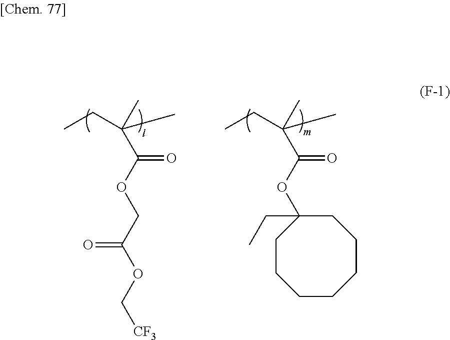

(S-1): A mixed solvent of propylene glycol monomethyl ether acetate (PGMEA):propylene glycol monomethyl ether (PGME)=70:30 (mass ratio).

### <Formation of Resist Pattern>

An organic antireflection film composition “ARC29A” (manufactured by Brewer Science, Inc.) was applied onto a 12-inch silicon wafer using a spinner, and the composition was then baked and dried on a hot plate at 205° C. for 60 seconds to form an organic antireflection film having a film thickness of 98 nm.

The resist composition was applied onto the antireflection film using a spinner, and was then prebaked (PAB) on a hot plate at 100° C. for 60 seconds and dried to form a resist film having a film thickness of 100 nm.

Using an ArF exposure apparatus for liquid immersion XT1900Gi [manufactured by ASML; NA (numerical aperture)=1.35, annular (in/out=0.78/0.97) with Polano, immersion medium: ultrapure water], an ArF excimer laser (193 nm) was selectively irradiated through a photomask (6% halftone). Thereafter, a PEB treatment was performed at 100° C. for 60 seconds. Next, an alkali development was performed at 23° C. for 15 seconds using a 2.38 mass % TMAH aqueous solution (product name: NMD-3, manufactured by Tokyo Ohka Kogyo Co., Ltd.), and then water rinsing was performed for 30 seconds using pure water, followed by shaking and drying. As a result, in each Example, a 1:1 line-and-space (LS) pattern having a line width of 50 nm and a pitch of 100 nm was formed.

The sensitivity at which the 50 nm LS pattern was formed was determined as an optimal exposure amount Eop (mJ/cm²). This is shown in Table 1 as “Eop (mJ/cm²)”.

### [Evaluation of Line Width Roughness (LWR)]

In the LS pattern formed in the above <Formation of Resist Pattern> with an optimal exposure amount Eop (mJ/cm²) and a line width of 50 nm and a pitch of 100 nm, the line width was measured at 400 points in a longitudinal direction of a line using a length measuring SEM (scanning electron microscope, product surface: CG-6300, manufactured by Hitachi High-Technologies Corporation), and a triple value (3σ) (unit: nm) of the standard deviation (σ) obtained from the measurements was shown in Table 1 as “LWR (nm)”. The smaller the 3σ value, the less rough the line sidewall, meaning that an LS pattern with a more uniform width was obtained.

As shown in Table 1, it was confirmed that the resist compositions in Examples were superior in both sensitivity and roughness reduction property to the resist compositions in Comparative Examples.

The resist composition in Comparative Example 1 did not contain the component (D2) and contained only the component (D1) as the acid diffusion control agent, and therefore was superior in sensitivity to the resist composition in related art, but inferior in roughness reduction property.

The resist composition in Comparative Example 2 did not contain the component (D1) and contained only the component (D2) as the acid diffusion control agent, and therefore was superior in roughness reduction property to the resist compositions in Examples, but inferior in sensitivity.

The resist composition in Comparative Example 3 contained, instead of the component (D1), the compound (D0-1) that does not have an anion moiety of a specific structure and the component (D2) as the acid diffusion control agent, and therefore was superior in sensitivity to the resist compositions in Examples, but inferior in roughness reduction property.

The resist composition in Comparative Example 4 contained, instead of the component (D2), the compound (D0-2) that does not have an anion moiety of a specific structure and the component (D1) as the acid diffusion control agent, and therefore was inferior in both sensitivity and roughness reduction property to the resist compositions in Examples.

### INDUSTRIAL APPLICABILITY

According to the present invention, a resist composition capable of forming a resist pattern that achieves both high sensitivity and lithography properties and a method for forming a resist pattern can be provided.

Although the present invention has been described in detail with reference to specific embodiments, it is apparent to those skilled in the art that various changes and modifications can be made without departing from the spirit and scope of the present invention.

The present application is based on a Japanese patent application (JP2022-144181) filed on Sep. 9, 2022, the disclosure of which is hereby incorporated by reference herein in its entirety.

What is claimed is:

1. A resist composition that generates an acid upon exposure and whose solubility with respect to a liquid developer changes by an action of the acid, the resist composition comprising:
a base material component (A) whose solubility with respect to a liquid developer changes by an action of an acid;
an acid generating agent component (B) that generates an acid upon exposure;
a first acid diffusion control component (D1); and
a second acid diffusion control component (D2), wherein
the first acid diffusion control component (D1) comprises a compound (d1-1) represented by the following general formula (d1-1), and
the second acid diffusion control component (D2) comprises a compound (d2-1) represented by the following general formula (d2-1), 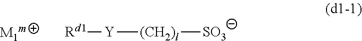
wherein in the general formula (d1-1), R^{d1} represents a cyclic group that may include a substituent or a chain alkyl group that may include a substituent, Y represents a single bond or a divalent linking group containing a heteroatom, 1 represents an integer of 1 or more, m represents an integer of 1 or more, and M₁^{m+} represents an m-valent organic cation, 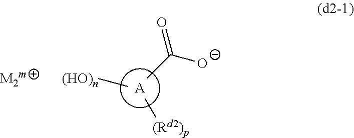
and wherein in the general formula (d2-1), ring A represents a monocyclic aromatic hydrocarbon group or a polycyclic aromatic hydrocarbon group, R^{d2} represents a substituent other than a hydroxy group, p represents an integer of 0 to 3, a plurality of R^{d2}'s may be the same as or different from each other when p represents 2 or 3, n represents an integer of 2 or more, m represents an integer of 1 or more, and M₂^{m+} represents an m-valent organic cation.

2. The resist composition according to claim 1, wherein the cyclic group represented by R^{d1} in the general formula (d1-1) is a polycyclic alicyclic hydrocarbon group, a lactone-containing cyclic group, a carbonate-containing cyclic group, or an SO₂— containing cyclic group.

3. The resist composition according to claim 1, wherein the compound (d2-1) represented by the general formula (d2-1) is a compound (d2-2) represented by the following general formula (d2-2), 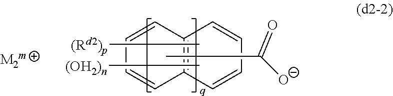
wherein in the general formula (d2-2), R^{d2} represents a substituent other than a hydroxy group, p represents an integer of 0 to 3, a plurality of R^{d2}'s may be the same as or different from each other when p represents 2 or 3, q represents 0 or 1, n represents an integer of 2 or more, m represents an integer of 1 or more, M₂^{m+} represents an m-valent organic cation, and n+p≤(q×2)+5.

4. A method for forming a resist pattern, the method comprising:
forming a resist film on a support using the resist composition according to claim 1;
exposing the resist film; and
developing the resist film to form a resist pattern.
